(19) United States
(12) Patent Application Publication
(10) Pub. No.: US 2025/0220878 A1
(43) Pub. Date: Jul. 3, 2025

(54) SEMICONDUCTOR DEVICE AND METHOD FOR FABRICATING THE SAME

(71) Applicant: SK hynix Inc., Gyeonggi-do (KR)

(72) Inventors: Seung Hwan KIM, Gyeonggi-do (KR); Jun Ha KWAK, Gyeonggi-do (KR)

(21) Appl. No.: 18/739,338

(22) Filed: Jun. 11, 2024

(30) Foreign Application Priority Data
Dec. 29, 2023 (KR) 10-2023-0197651

(51) Int. Cl. H10B 12/00

(52) U.S. Cl. CPC H10B 12/30; H10B 12/03; H10B 12/05

(57) ABSTRACT

A method for fabricating a semiconductor device includes forming a stack body including a first region and a second region by sequentially forming a first stack, a recess target layer, and a second stack over a lower structure; forming sacrificial isolation layers in the first region; forming a plurality of vertical openings in the first region; forming a plurality of pad isolation openings in the second region; removing the first stack and the second stack from the first region and the second region through the vertical openings and the pad isolation openings; and forming a preliminary horizontal layer in each of the first region and the second region by recessing the recess target layer of the stack body.

### CROSS-REFERENCE TO RELATED APPLICATIONS

The present application claims priority under 35 U.S.C 119(a) to Korean Patent Application No. 10-2023-0197651, filed on Dec. 29, 2023, which is incorporated herein by reference in its entirety.

### BACKGROUND

### 1. Field

Various embodiments of the present disclosure relate generally to a semiconductor device, and more particularly, to a semiconductor device including three-dimensional memory cells, and a method for fabricating the semiconductor device.

### 2. Description of the Related Art

Recently, in order to cope with the demands for large capacity and miniaturization of memory devices, a three-dimensional (3D) memory device including a plurality of memory cells that are stacked in three dimensions is proposed. The 3D memory devices are generally new and further improvements are needed.

### SUMMARY

Embodiments of the present disclosure are directed to a 3D semiconductor device (hereinafter referred to simply as semiconductor device) including highly integrated memory cells, and a method for fabricating the semiconductor device.

In accordance with an embodiment of the present disclosure, a method for fabricating a semiconductor device includes forming a stack body including a first region and a second region by sequentially forming a first stack, a recess target layer, and a second stack over a lower structure; forming sacrificial isolation layers in the first region; forming a plurality of vertical openings in the first region; forming a plurality of pad isolation openings in the second region; removing the first stack and the second stack from the first region and the second region through the vertical openings and the pad isolation openings; and forming a preliminary horizontal layer in each of the first region and the second region by recessing the recess target layer of the stack body.

In accordance with another embodiment of the present disclosure, a semiconductor device includes: a lower structure; a vertical stack including horizontal conductive lines that are stacked vertically from the lower structure; a staircase stack extending horizontally from the vertical stack and including edge portions of the horizontal conductive lines; line-shaped pad isolation slits formed on both sidewall surfaces of the staircase stack; and a hole-shaped pad isolation slit penetrating the staircase stack and extending vertically in a direction that the horizontal conductive lines are stacked.

In accordance with another embodiment of the present disclosure, a semiconductor device includes: a substrate including a connection region and a memory cell region; vertical bit lines extending in a first direction which is perpendicular to the top surface of the substrate and disposed spaced apart from each other in the memory cell region; horizontal layers stacked over the substrate to be spaced apart from each other, extending in a second direction intersecting with the first direction, and electrically connected to the vertical bit lines; word lines overlapping with the horizontal layers and extending in a third direction, and providing staircase-shaped pad areas in the connection region; and data storage elements electrically connected to the horizontal layers.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell shown in FIG. 1A.

FIG. 1C is a plan view illustrating of a switching element shown in FIG. 1A.

FIG. 1D is a schematic cross-sectional view illustrating a memory cell in accordance with another embodiment of the present disclosure.

FIGS. 2A and 2B are schematic plan views illustrating a semiconductor device in accordance with an embodiment of the present disclosure.

FIG. 3A is a cross-sectional view taken along a line A-A′ shown in FIGS. 2A and 2B.

FIG. 3B is a cross-sectional view taken along a line B-B′ shown in FIGS. 2A and 2B.

FIG. 3C is a cross-sectional view taken along a line C-C′ shown in FIGS. 2A and 2B.

FIGS. 4A to 22C illustrate a method for fabricating a semiconductor device in accordance with an embodiment of the present disclosure.

FIGS. 23A to 23F are cross-sectional views illustrating a method for fabricating a semiconductor device in accordance with another embodiment of the present disclosure.

FIGS. 24A to 24C are cross-sectional views illustrating a method for fabricating a semiconductor device in accordance with another embodiment of the present disclosure.

FIGS. 25 to 27 are perspective views illustrating memory cell arrays in accordance with other embodiments of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The following embodiments of the present disclosure described below relate to three-dimensional memory cells (also referred to hereinafter simply as memory cells). The density of the memory cells is increased while the parasitic capacitance of the memory cells is reduced by vertically stacking the memory cells.

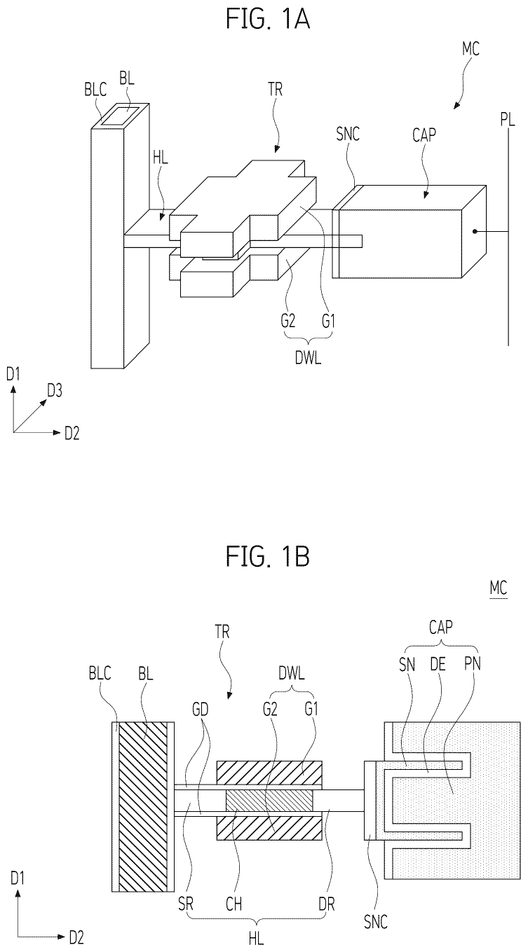

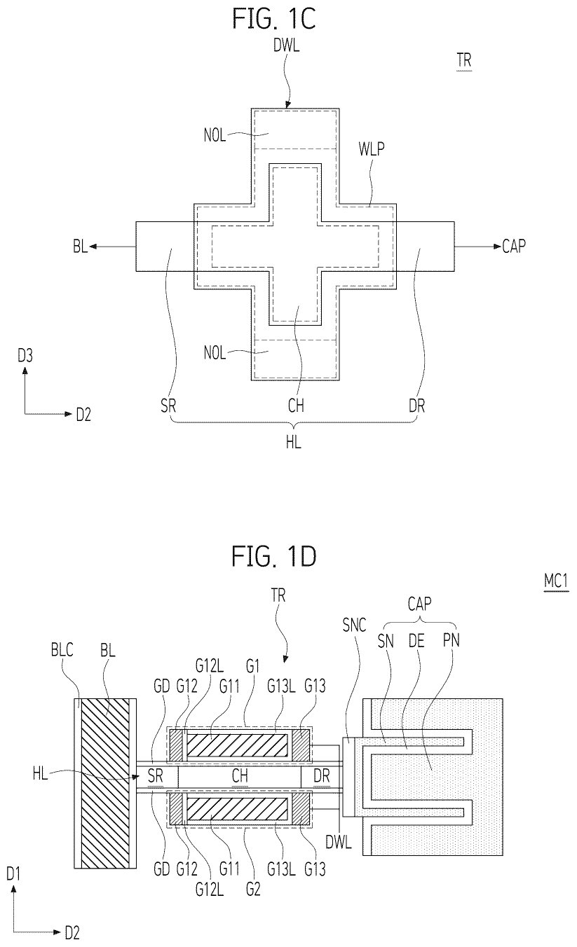

FIG. 1A is a schematic perspective view illustrating a memory cell in accordance with an embodiment of the present disclosure. FIG. 1B is a schematic cross-sectional view of the memory cell shown in FIG. 1A, and FIG. 1C is a plan view of a switching element shown in FIG. 1A.

Referring to FIGS. 1A to 1C, a memory cell MC may include a first conductive line BL, a switching element TR, and a data storage element CAP arranged adjacent to each other along a horizontal direction.

The first conductive line BL may have a line shape and may be oriented in a first direction D1. The first direction D1 may be a vertical direction. The first conductive line BL may be, for example, a bit line. The first conductive line BL may be referred to as a vertical conductive line, a vertically-oriented bit line, a vertically-extended bit line, or a pillar-shaped bit line. The first conductive line BL may include a conductive material. The first conductive line BL may include, for example, a silicon-based material, a metal-based material, or a combination thereof. The first conductive line BL may include, for example, polysilicon, a metal, a metal nitride, a metal silicide, or a combination thereof. The first conductive line BL may include, for example, polysilicon, titanium nitride, tungsten, or a combination thereof. For example, the first conductive line BL may include a stack (TIN/W) of titanium nitride and tungsten.

The switching element TR may be spaced apart from the conductive line BL along the second direction D2. In a data write operation and a data read operation performed onto the data storage element CAP, the switching element TR may control the voltage (or current) supply to the data storage element CAP. The switching element TR may include a horizontal layer HL, an inter-level dielectric layer GD, and a second conductive line DWL. The second conductive line DWL may include a horizontal conductive line. The second conductive line may be a horizontal word line. The horizontal layer HL may include an active layer. The switching element TR may be, for example, a transistor, and in this case, i.e., when the switching element TR is a transistor, the second conductive line DWL may function as a gate electrode. The switching element TR may also be referred to as a cell transistor, an access element, or a selection element. The second conductive line DWL may be referred to as a horizontal gate electrode or a horizontal word line.

The horizontal layer HL may extend in the second direction D2 that intersects with the first direction D1. The second conductive line DWL may extend in a third direction D3 that intersects with the first direction D1 and the second direction D2. The first direction D1 may be a vertical direction, and the second direction D2 may be a first horizontal direction, and the third direction D3 may be a second horizontal direction. The horizontal layer HL may extend in the first horizontal direction (i.e., the second direction D2), and the second conductive line DWL may extend in the second horizontal direction (i.e., the third direction D3). The horizontal layer HL and the second conductive line DWL may intersect with each other. The horizontal layer HL and the second conductive line DWL may be perpendicular to each other.

The horizontal layer HL may be horizontally oriented in the second direction D2 from the first conductive line BL. Hence, a first end of the horizontal layer HL may be in contact with the first conductive line BL. The second conductive line DWL may have a double structure. For example, the second conductive line DWL may include an upper horizontal line G1 and a lower horizontal line G2 that are facing each other with the horizontal layer HL interposed therebetween. An inter-level dielectric layer GD may be formed on the top and bottom surfaces of the horizontal layer HL. The upper horizontal line G1 may be disposed over the horizontal layer HL, and the lower horizontal line G2 may be disposed below the horizontal layer HL. The upper and lower horizontal lines G1 and G2 may have the same structure. The second conductive line DWL may include a pair of an upper horizontal line G1 and a lower horizontal line G2. In the second conductive line DWL, the same driving voltage may be applied to the upper and lower horizontal lines G1 and G2. For example, the upper and lower horizontal lines G1 and G2 may form a pair coupled to a single memory cell MC. According to another embodiment of the present disclosure, different driving voltages may be applied to the upper and lower horizontal lines G1 and G2. In this case, one horizontal line between the upper and lower horizontal lines G1 and G2 may function as a back gate or a shield gate.

The horizontal layer HL may include a semiconductor material. For example, the horizontal layer HL may include polysilicon, mono crystalline silicon, germanium, or silicon-germanium. According to another embodiment of the present disclosure, the horizontal layer HL may include an oxide semiconductor material. For example, the oxide semiconductor material may include Indium Gallium Zinc Oxide (IGZO). According to another embodiment of the present disclosure, the horizontal layer HL may include a conductive metal oxide.

According to another embodiment of the present disclosure, the horizontal layer HL may include two-dimensional material. For example, the two-dimensional material may include MoS₂, MoSe₂, MoTe₂, WS₂, WSe₂, or WTe₂.

The top and bottom surfaces of the horizontal layer HL may have a flat surface. The top and bottom surfaces of the horizontal layer HL may be parallel to each other in the second direction D2.

The horizontal layer HL may include a channel CH, a first doped region SR between the channel CH and the first conductive line BL, and a second doped region DR between the channel CH and the data storage element CAP. When the horizontal layer HL is formed of an oxide semiconductor material, the channel CH may be formed of an oxide semiconductor material, and the first and second doped regions SR and DR may be omitted. The horizontal layer HL may also be referred to as an active layer or a thin-body layer.

In each of the upper and lower horizontal lines G1 and G2, the width in the second direction D2, for example, the width of an overlapping portion that overlaps with the horizontal layer HL, may be greater than the width of a portion that does not overlap with the horizontal layer HL. Due to this difference in the widths, the second conductive line DWL may have a notch-shaped sidewall. Referring back to FIG. 1C, the second conductive line DWL may include a channel overlapping portion WLP and a channel non-overlapping portion NOL. The channel overlapping portion WLP may refer to the portion that overlaps with the channel CH of the horizontal layer HL, and the channel non-overlapping portion NOL may refer to the portion that does not overlap with the horizontal layer HL. The channel overlapping portion WLP may have a cross shape or a rhombus shape.

From the perspective of a top view, the horizontal layer HL may have a cross shape or a rhombus shape. According to another embodiment of the present disclosure, the side surfaces of the horizontal layer HL may have a bent shape or a round shape.

The channel CH and the channel overlapping portion WLP of the second conductive line DWL may overlap with each other. The channel CH may have a cross shape or a rhombus shape. The size of the channel overlapping portion WLP of the second conductive line DWL may be greater than that of the channel CH. The channel overlapping portion WLP of the second conductive line DWL may fully overlap with the channel CH.

The first and second doped regions SR, and DR may be doped with impurities of the same conductivity type. The first and second doped regions SR, and DR may be doped with an N-type conductive impurity or a P-type conductive impurity. The first and second doped regions SR, and DR may include at least one impurity selected among arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may be referred to as first and second source/drain regions.

The second conductive line DWL may include a metal-based material, a semiconductor material, or a combination thereof. The second conductive line DWL may include titanium nitride, tungsten, polysilicon, or a combination thereof. For example, the second conductive line DWL may include a TiN/W stack in which titanium nitride and tungsten are sequentially stacked. The second conductive line DWL may include an N-type work function material or a P-type work function material. The N-type work function material may have a low work function of approximately 4.5 eV or less, and the P-type work function material may have a high work function of approximately 4.5 eV or more. The second conductive line DWL may include a stack of a low work function material and a high work function material.

The inter-level dielectric layer GD may be disposed between the horizontal layer HL and the second conductive line DWL. The inter-level dielectric layer GD may be referred to as a gate dielectric layer. The inter-level dielectric layer GD may be referred to as a horizontal layer-side dielectric layer. The inter-level dielectric layer GD may include, for example, silicon oxide, silicon nitride, a metal oxide, a metal oxynitride, a metal silicate, a high-k material, a ferroelectric material, an anti-ferroelectric material or a combination thereof. The inter-level dielectric layer GD may include, for example, silicon SiO₂, Si₃N₄, HfO₂, Al₂O₃, ZrO₂, AlON, HfON, HfSiO, HfSION, HfZrO, or a combination thereof. The inter-level dielectric layer GD may be formed by thermal oxidation of a semiconductor material.

The data storage element CAP may include a memory element such as a capacitor. The data storage element CAP may be disposed horizontally in the second direction D2 from the switching element TR. The data storage element CAP may include a first electrode SN extending horizontally from the horizontal layer HL in the second direction D2. The data storage element CAP may further include a second electrode PN over the first electrode SN, and a dielectric layer DE between the first and second electrodes SN and PN. The first electrode SN, the dielectric layer DE, and the second electrode PN may be horizontally disposed in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may extend vertically in the first direction D1, and the horizontal outer surfaces of the first electrode SN may extend horizontally in the second direction D2 or the third direction D3. The inner space of the first electrode SN may be a three-dimensional space. The dielectric layer DE may conformally cover the inner and outer surfaces of the first electrode SN. The second electrode PN may be disposed in the inner space of the first electrode SN over the dielectric layer DE. Some of the outer surfaces of the first electrode SN may be electrically connected to the second doped region DR of the horizontal layer HL. The second electrode PN of the data storage element CAP may be coupled to a common plate PL.

The data storage element CAP may be a three-dimensional structure. The first electrode SN may have a three-dimensional structure. The first electrode SN of the three-dimensional structure may have a horizontal three-dimensional structure oriented in the second direction D2. For example, the first electrode SN may have a cylindrical shape including a cylindrical inner surface and a cylindrical outer surface. A portion of the cylindrical outer surfaces of the first electrode SN which is oriented in the third direction D3 may be electrically connected to the second doped region DR of the horizontal layer HL via a second contact node SNC. The dielectric layer DE and the second electrode PN may be disposed over the cylindrical inner surfaces of the first electrode SN. The dielectric layer DE and the second electrode PN may be disposed also over the horizontally oriented outer surfaces of the first electrode SN.

According to another embodiment of the present disclosure, the first electrode SN may have a pillar shape or a pylinder shape. The pylinder shape refers to a structure in which first electrode includes a first portion that has a pillar shape and a second portion that has a cylindrical shape which are merged, i.e., combined. Pylinder shape electrodes are known in the art, hence, it is not necessary to describe them in more detail.

The first and second electrodes SN and PN may include a metal, a noble metal, a metal nitride, a conductive metal oxide, a conductive noble metal oxide, a metal carbide, a metal silicide, or a combination thereof. For example, the first and second electrodes SN and PN may include titanium (Ti), titanium nitride (TIN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode PN may include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inside of the first electrode SN, and titanium nitride (TIN) may serve as the second electrode PN of the capacitor CAP, and tungsten nitride may be a low-resistance material.

The dielectric layer DE may be referred to as a capacitor dielectric layer or a memory layer. The dielectric layer DE may include, for example, silicon oxide, silicon nitride, a high-k material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present disclosure, the dielectric layer DE may be formed of a composite layer including two or more layers of the aforementioned high-k materials.

The dielectric layer DE may be formed of zirconium (Zr)-based oxide. The dielectric layer DE may have a stacked structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present disclosure, the dielectric layer DE may be formed of hafnium (Hf)-based oxide. The dielectric layer DE may have a stacked structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater bandgap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap energy than the high-k material. The dielectric layer DE may include, for example, silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material. According to another embodiment of the present disclosure, the dielectric layer DE may include a stacked structure in which a high-k material and a high-bandgap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above stacked structure, aluminum oxide (Al₂O₃) may be thinner than zirconium oxide (ZrO₂) and hafnium oxide (HfO₂).

According to another embodiment of the present disclosure, the dielectric layer DE may include a high-k material and a high bandgap material, and may have a laminated structure in which a plurality of high-k materials and a plurality of high bandgap materials are stacked, or a mixed structure in which a high-k material and a high bandgap material are intermixed.

According to another embodiment of the present disclosure, the dielectric layer DE may include a ferroelectric material, an anti-ferroelectric material, or a combination thereof. For example, the dielectric layer DE may include hafnium zirconium oxide (HfZrO).

According to another embodiment of the present disclosure, the dielectric layer DE may include a combination of a high-k material and a ferroelectric material, a combination of a high-k material and an anti-ferroelectric material, a high-k material, or a combination of a ferroelectric material and an anti-ferroelectric material.

According to another embodiment of the present disclosure, the dielectric layer DE may include a perovskite dielectric material. The perovskite dielectric material may include SrTiO₃, (Ba,Sr) TiO₃, BaTiO₃, PbTiO₃, PZT, PLZT, or PbTiO₃.

According to another embodiment of the present disclosure, an interface control layer (not shown) may be further formed between the first electrode SN and the dielectric layer DE to reduce leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor.

The data storage element CAP may be replaced with other data storage materials. For example, the data storage material may be a thyristor, a phase change material, a magnetic tunnel junction (MTJ), or a variable resistance material. For example, the memory cell MC may include a thyristor, and the first conductive line BL may be a cathode line, and the data storage element CAP may be replaced with an anode line. Accordingly, the horizontal layer HL may include four semiconductor layers that are stacked in the second direction D2. The thyristor may include a first diode and a second diode that are coupled serially. When a forward bias of the same voltage is applied to the thyristor, the thyristor may have a high conductance state in which a large amount of current flows, or a low conductance state in which a small amount of current flows or no current flows. The memory cell MC in accordance with this embodiment of the present disclosure may have a ‘1’ state and a ‘0’ state according to the high conductance state and the low conductance state of the thyristor, respectively.

Referring back to FIGS. 1A and 1B, the memory cell MC may further include a first contact node BLC and a second contact node SNC. The first contact node BLC may surround the outer wall of the first conductive line BL. The first contact node BLC may be electrically connected to the first conductive line BL and the horizontal layer HL. The second contact node SNC may be disposed between the horizontal layer HL and the first electrode SN. The second contact node SNC may be electrically connected to the horizontal layer HL and the first electrode SN. The first and second contact nodes BLC and SNC may include a metal-based material or a semiconductor material. For example, the first and second contact nodes BLC and SNC may include titanium, titanium nitride, tungsten, or a combination thereof. According to another embodiment of the present disclosure, the first and second contact nodes BLC and SNC may include doped polysilicon. The first and second doped regions SR, and DR may include impurities diffused from the first and second contact nodes BLC and SNC.

FIG. 1D is a schematic cross-sectional view illustrating a memory cell in accordance with another embodiment of the present disclosure. The memory cell MC1 of FIG. 1D may be similar to the memory cell MC of FIGS. 1A to 1C. Hereinafter, detailed description on the constituent elements also appearing in FIGS. 1A to 1C will be omitted herein.

The memory cell MC1 may include a first conductive line BL, a switching element TR, and a data storage element CAP. The switching element TR may include a horizontal layer HL, an inter-level dielectric layer GD, and a second conductive line DWL. The horizontal layer HL may include a first doped region SR, a second doped region DR, and a channel CH. The data storage element CAP may include a first electrode SN, a second electrode PN, and a dielectric layer DE.

The memory cell MC1 may further include a first contact node BLC between the first conductive line BL and the horizontal layer HL and a second contact node SNC between the horizontal layer HL and the data storage element CAP.

The second conductive line DWL may include an upper horizontal line G1 and a lower horizontal line G2. Each of the upper and lower horizontal lines G1 and G2 may include a first work function electrode G11, a second work function electrode G12, and a third work function electrode G13. The first, second, and third work function electrodes G11, G12, and G13 may be horizontally disposed in the second direction D2. The first, second, and third work function electrodes G11, G12, and G13 may directly contact each other. The second work function electrode G12 may be disposed adjacent to the first conductive line BL, and the third work function electrode G13 may be disposed adjacent to the data storage element CAP. The first work function electrode G11 may be disposed between the second and third work function electrodes G12, and G13. The horizontal layer HL may have a thinner thickness than the first, second, and third work function electrodes G11, G12, and G13.

The first, second, and third work function electrodes G11, G12, and G13 may be formed of different work function materials. The first work function electrode G11 may have a higher work function than the second and third work function electrodes G12 and G13. The first work function electrode G11 may include a high work function material. The first work function electrode G11 may have a work function which is higher than the mid-gap work function of silicon. The second and third work function electrodes G12 and G13 may include a low work function material. The second and third work function electrodes G12 and G13 may have a work function which is lower than that of the mid-gap work function of silicon. For example, the high work function material may have a work function which is higher than approximately 4.5 eV, and the low work function material may have a work function which is lower than approximately 4.5 eV. In an embodiment, the first work function electrode G11 may include a metal-based material, and the second and third work function electrodes G12 and G13 may include a semiconductor material.

The second and third work function electrodes G12 and G13 may include polysilicon doped with an N-type dopant. The first work function electrode G11 may include a metal, a metal nitride, or a combination thereof. The first work function electrode G11 may include tungsten, titanium nitride, or a combination thereof. A barrier material may be further formed between the second and third work function electrodes G12 and G13 and the first work function electrode G11.

According to this embodiment of the present disclosure, each of the upper and lower horizontal lines G1 and G2 of the second conductive line DWL may be disposed horizontally in the order of the second work function electrode G12—the first work function electrode G11—the third work function electrode G13 in the second direction D2. For example, the first work function electrode G11 may include a metal, and the second work function electrode G12 and the third work function electrode G13 may include polysilicon.

Each of the upper and lower horizontal lines G1 and G2 of the second conductive line DWL may have a PMP (Poly Si-Metal-Poly Si) structure in which polysilicon, a metal, and polysilicon are arranged horizontally in the second direction D2. In the PMP structure, the first work function electrode G11 may be a metal-based material, and the second and third work function electrodes G12 and G13 may be doped polysilicon which is doped with an N-type dopant. The N-type dopant may include phosphorus or arsenic.

A first barrier layer G12L may be disposed between the first work function electrode G11 and the second work function electrode G12. A second barrier layer G13L may be disposed between the first work function electrode G11 and the third work function electrode G13. The first and second barrier layers G12L and G13L may include titanium nitride, tantalum nitride, tungsten nitride, or molybdenum nitride. The second barrier layer G13L may cover the top surface, bottom surface, and the side of the first work function electrode G11 that is adjacent to the third work function electrode G13.

The first work function electrode G11 may have a greater volume than the second and third work function electrodes G12 and G13, and accordingly, the second conductive line DWL may have a low resistance. The first work function electrodes G11 of the upper and lower horizontal lines G1 and G2 may vertically overlap with each other in the first direction D1 with the horizontal layer HL interposed therebetween. The second and third work function electrodes G12 and G13 of the upper and lower horizontal lines G1 and G2 may vertically overlap with each other in the first direction D1 with the horizontal layer HL interposed therebetween. The overlapping area between the first work function electrode G11 and the horizontal layer HL may be greater than the overlapping area between the second and third work function electrodes G12 and G13 and the horizontal layer HL. The first work function electrode G11 may extend in the third direction D3, and the second and third work function electrodes G12 and G13 may have an independent structure that overlaps with the horizontal layer HL. For example, the first work function electrode G11 may include a channel overlapping portion WLP and a channel non-overlapping portion NOL, and the second and third work function electrodes G12 and G13 may become a portion of the channel overlapping portion WLP. The second and third work function electrodes G12 and G13 and the first work function electrode G11 may directly contact each other.

As described above, each of the upper and lower horizontal lines G1 and G2 may have a triple-work function electrode structure including first, second and third work function electrodes G11, G12, and G13. The second conductive line DWL may include a pair of first work function electrodes G11, a pair of second work function electrodes G12, and a pair of third work function electrodes G13 extending in the third direction D3 that intersects with the horizontal layer HL with the horizontal layer HL interposed therebetween. The first work function electrodes G11, the second work function electrodes G12, and the third work function electrodes G13 may overlap with the channel CH vertically.

Each of the second conductive lines DWL may include a channel overlapping portion WLP and a channel non-overlapping portion NOL as illustrated in FIG. 1C. The channel overlapping portions WLP may have a cross shape or a rhombus shape. The channel overlapping portions WLP may fully overlap with the channel CH. The second conductive line DWL extending in the third direction D3 may have notch-shaped sidewall surfaces by the channel overlapping portions WLP and the channel non-overlapping portions NOL. From the perspective of a top view, the notch-shaped sidewall surfaces may be provided by the protruding portions formed by the channel overlapping portions WLP and the recessed portions formed by the channel non-overlapping portions NOL. The channel overlapping portions WLP may include the first work function electrodes G11, the second work function electrodes G12, and the third work function electrodes G13, and the first work function electrodes G11, the second work function electrodes G12, and the third work function electrodes G13 may overlap with the channel CH vertically.

In the second direction D2, the first work function electrode G11 of a high work function may be disposed at the center of the second conductive line DWL, and the second and third work function electrodes G12 and G13 of a low work function may be disposed at both ends of the second conductive line DWL, reducing leakage current, such as Gate Induced Drain Leakage (GIDL).

As the first work function electrode G11 of a high work function is disposed at the center of the second conductive line DWL, the threshold voltage of the switching element TR may be increased. Since the second work function electrode G12 of the second conductive line DWL has a low work function, a low electric field may be formed between the first conductive line BL and the second conductive line DWL. Since the third work function electrode G13 of the second conductive line DWL has a low work function, a low electric field may be formed between the data storage element CAP and the second conductive line DWL.

As described above, the memory cell MC1 may include a second conductive line DWL having a triple work function electrode structure. Each of the upper and lower horizontal lines G1 and G2 of the second conductive line DWL may include a first work function electrode G11, a second work function electrode G12, and a third work function electrode G13. The first work function electrode G11 may overlap with the channel CH. The second work function electrode G12 may be disposed adjacent to the first conductive line BL and the first doped region SR. The third work function electrode G13 may be disposed adjacent to the data storage element CAP and the second doped region DR. Due to the low work function of the second work function electrode G12, a low electric field may be formed between the second conductive line DWL and the first conductive line BL, thereby improving leakage current. Due to the low work function of the third work function electrode G13, a low electric field may be formed between the second conductive line DWL and the data storage element CAP, thereby improving the leakage current. Due to the high work function of the first work function electrode G11, the threshold voltage of the switching element TR may be increased. Also, due to the high work function of the first work function electrode G11, the height of the memory cell MC1 may be decreased, which is advantageous in terms of integration.

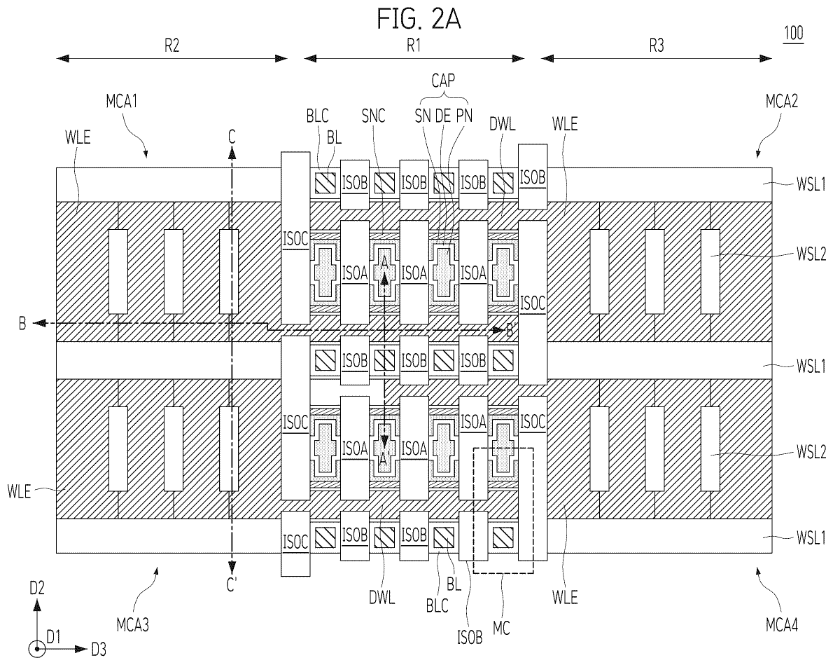

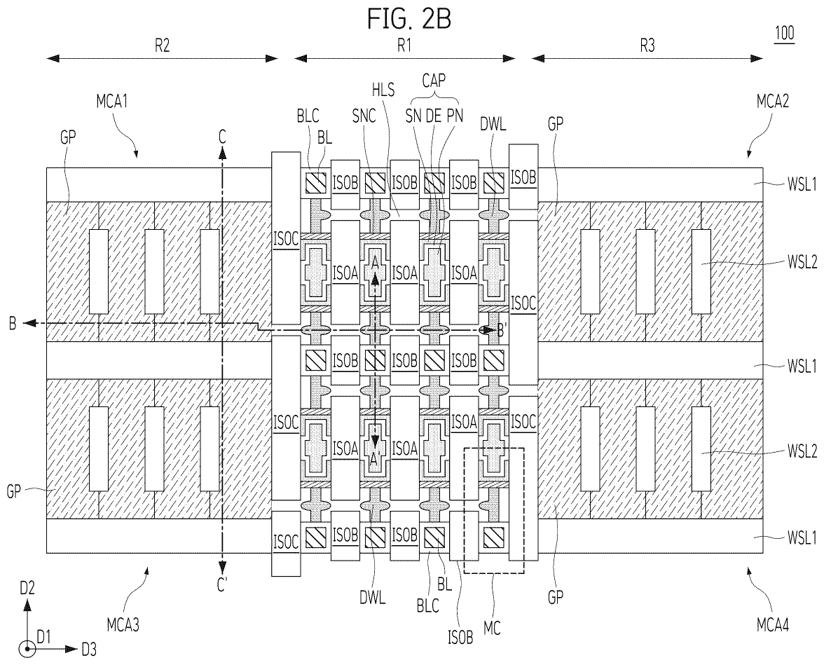

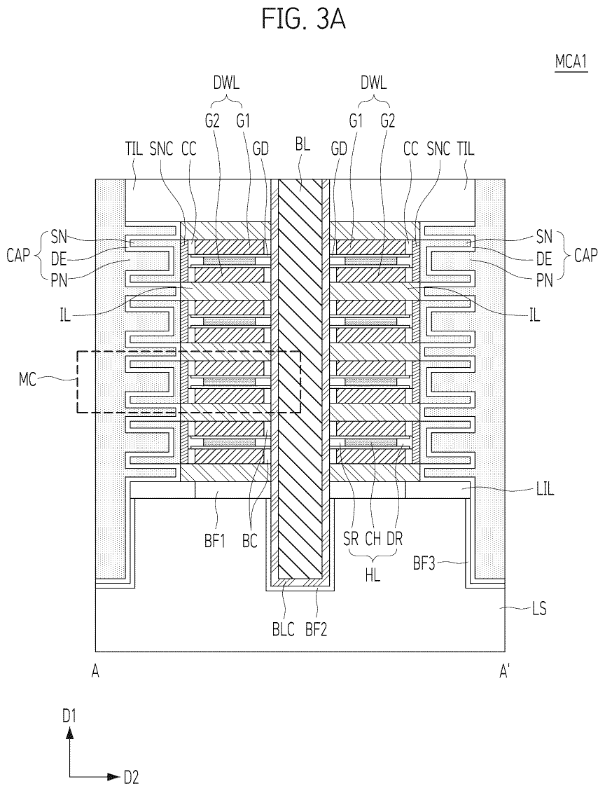

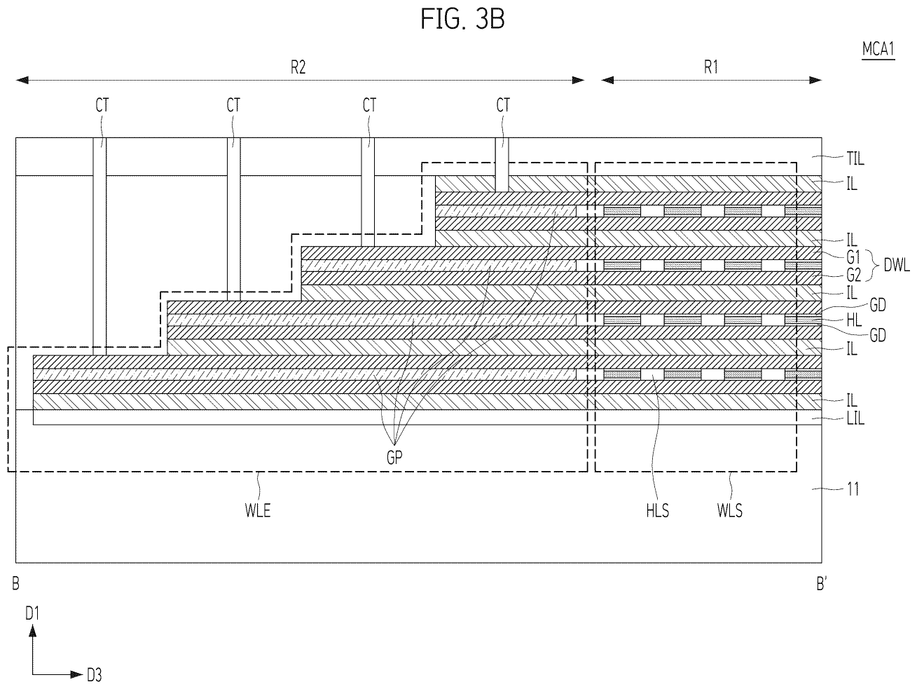

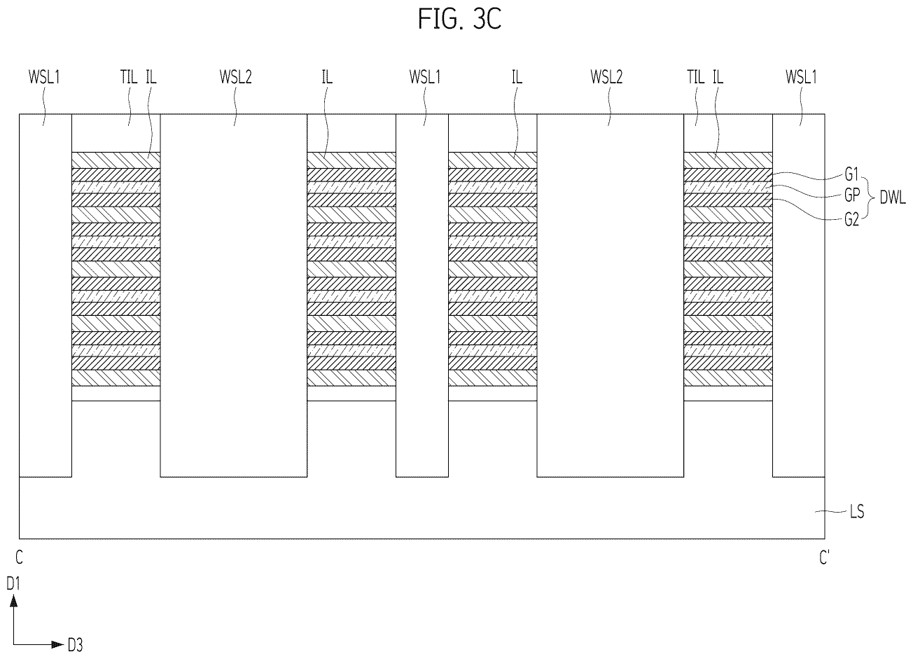

FIGS. 2A and 2B are schematic plan views illustrating a semiconductor device 100 in accordance with an embodiment of the present disclosure. FIG. 3A is a cross-sectional view taken along a line A-A′ shown in FIGS. 2A and 2B. FIG. 3B is a cross-sectional view taken along a line B-B′ shown in FIGS. 2A and 2B, and FIG. 3C is a cross-sectional view taken along a line C-C′ shown in FIGS. 2A and 2B. FIG. 2A is a plan view at the level of the second conductive line, and FIG. 2B is a plan view at the level of the horizontal layer. FIGS. 3A to 3C illustrate a memory cell array MCA1.

Referring to FIGS. 2A, 2B, 3A, 3B, and 3C, the semiconductor device 100 may include a plurality of memory cell arrays MCA1, MCA2, MCA3, and MCA4. Each of the memory cell arrays MCA1, MCA2, MCA3, and MCA4 may include a plurality of memory cells MC. As for the detailed description of the individual memory cells MC, FIGS. 1A to 1C may be referred to. Each memory cell MC may include a first conductive line BL, a switching element TR, and a data storage element CAP.

The semiconductor device 100 may include a three-dimensional array of memory cells MC. The three-dimensional array of memory cells MC may include a column array of memory cells MC and a row array of memory cells MC. The column array of memory cells MC may include a plurality of memory cells MC that are stacked in a first direction D1, and the row array of memory cells MC may include a plurality of memory cells MC horizontally arranged disposed in a second direction D2 and a third direction D3. Each of the memory cell arrays MCA1, MCA2, MCA3, and MCA4 may include a column array of memory cells MC.

The semiconductor device 100 may include a plurality of sub-memory cell arrays. For example, the semiconductor device 100 may include first to fourth sub-memory cell arrays. The first sub-memory cell array may include a row array of memory cells MC that are disposed adjacent to each other in the second direction D2, and the first sub-memory cell array may have a mirror-type structure in which the neighboring memory cells MC share the first conductive line BL. The second sub-memory cell array may include two memory cells MC that are disposed adjacent to each other in the second direction D2, and the second sub-memory cell array may have a mirror-type structure in which the neighboring memory cells MC share the second electrode PN of the data storage elements CAP. In the third sub-memory cell array, the memory cells MC may be vertically stacked in the first direction D1. The fourth sub-memory cell array may include a plurality of memory cells MC that are disposed horizontally in the third direction D3. By a combination of the first sub-memory cell array and the second sub-memory cell array, a data storage element CAP, a switching element TR, a first conductive line BL, and a switching element TR may be alternately disposed in the second direction D2 in the mentioned order.

Inter-cell dielectric layers IL may be disposed between the memory cells MC that are stacked in the first direction D1. The inter-cell dielectric layers IL may include, for example, silicon oxide, silicon carbon oxide (SiCO), silicon nitride, or a combination thereof. The inter-cell dielectric layers IL may be referred to as horizontal inter-cell dielectric layers. A top dielectric layer TIL may be disposed over the uppermost-level inter-cell dielectric layer IL.

Cell isolation layers ISOA and ISOB may be disposed between the memory cells MC that are disposed adjacent to each other in the third direction D3 (See FIG. 2A). The cell isolation layers ISOA and ISOB may be referred to as vertical inter-cell dielectric layers. The cell isolation layers ISOA and ISOB may include, for example, silicon oxide, silicon carbon oxide (SiCO), silicon nitride, or a combination thereof. The cell isolation layers ISOA and ISOB may include first cell isolation layers ISOA and second cell isolation layers ISOB. The first and second cell isolation layers ISOA and ISOB may extend vertically in the first direction D1. The first and second cell isolation layers ISOA and ISOB may have a pillar structure extending vertically in the first direction D1. The first and second cell isolation layers ISOA and ISOB may be alternately disposed in the second direction D2. The first cell isolation layers ISOA may be disposed between the data storage elements CAP in the third direction D3. The second cell isolation layers ISOB may be disposed between the first conductive lines BL in the third direction D3. The second conductive lines DWL may be disposed between the first and second cell isolation layers ISOA and ISOB in the second direction D2.

The memory cell arrays MCA1, MCA2, MCA3, and MCA4 may be disposed over a lower structure LS.

Each of the memory cell arrays MCA1, MCA2, MCA3, and MCA4 may include a plurality of second conductive lines DWL that are vertically stacked in the first direction D1. Each of the memory cell arrays MCA1, MCA2, MCA3, and MCA4 may include a plurality of horizontal layers HL that are stacked vertically in the first direction D1. Each of the memory cell arrays MCA1, MCA2, MCA3, and MCA4 may include a plurality of data storage elements CAP that are vertically stacked in the first direction D1. Each of the memory cell arrays MCA1, MCA2, MCA3, and MCA4 may include a plurality of first conductive lines BL extending vertically in the first direction D1.

Each of the second conductive lines DWL may include a channel overlapping portion WLP and a channel non-overlapping portion NOL as illustrated in FIG. 1C. The channel overlapping portion WLP may have a cross-shape or a rhombus shape. The channel overlapping portion WLP may fully overlap with the channel CH. The second conductive line DWL extending in the third direction D3 may include a plurality of channel overlapping portions WLP. As the channel overlapping portions WLP and the channel non-overlapping portions NOL are alternately repeated in the third direction D3, the second conductive line DWL may have a notch-shaped sidewall.

A plurality of first passivation layers BF1 may be disposed between the lowermost second conductive line DWL among the second conductive lines DWL and the lower structure LS. A second passivation layer BF2 may be disposed between the first conductive line BL and the lower structure LS. Third passivation layers BF3 may be disposed between the data storage element CAP and the lower structure LS. The first to third passivation layers BF1, BF2, and BF3 may include a dielectric material. The first to third passivation layers BF1, BF2, and BF3 may include, for example, silicon oxide. The first conductive line BL, the second conductive lines DWL, and the data storage elements CAP may be electrically disconnected from the lower structure LS by the first to third passivation layers BF1, BF2, and BF3. The first to third passivation layers BF1, BF2, and BF3 may be referred to as bottom dielectric layers or bottom passivation layers. A lowermost-level inter-cell dielectric layer LIL may be disposed between the first passivation layers BF1 and the data storage element CAP.

The first conductive lines BL may extend vertically in the first direction D1 from the upper portion of the lower structure LS. The horizontal layers HL may extend in the second direction D2 that intersects with the first direction D1. The second conductive lines DWL may extend in the third direction D3 that intersects with the first direction D1 and the second direction D2. The first direction D1 may be a vertical direction, and the second direction D2 may be a first horizontal direction. The third direction D3 may be a second horizontal direction. The horizontal layer HL may extend in the first horizontal direction (i.e., the second direction D2), and the second conductive line DWL may extend in the second horizontal direction (i.e., the third direction D3).

From the perspective of a top view, the horizontal layers HL may have a cross-shape or a rhombus shape. According to another embodiment of the present disclosure, the side surfaces of the horizontal layer HL may have a bended shape or a rounded shape. As illustrated in FIG. 1B, the horizontal layer HL may include a channel CH, a first doped region SR between the channel CH and the first conductive line BL, and a second doped region DR between the channel CH and the data storage element CAP.

The inter-level dielectric layer GD may be formed on a first surface (or top surface) and a second surface (or bottom surface) of the horizontal layer HL, individually.

A horizontal layer-level spacer HLS may be formed on the sidewall of the horizontal layer HL. The horizontal layer-level spacer HLS may include a dielectric material. The horizontal layer-level spacer HLS may include, for example, silicon oxide. The horizontal layer-level spacer HLS may directly contact the cell isolation layers ISOA and ISOB. The horizontal layers HL that are disposed adjacent to each other in the third direction D3 may be separated from each other by the horizontal layer-level spacers HLS.

A first capping layer BC may be disposed between the second conductive line DWL and the first conductive line BL. A second capping layer CC may be disposed between the second conductive line DWL and a first electrode SN of the data storage element. The first capping layer BC may be disposed between an upper horizontal line G1 and the first conductive line BL. Also, the first capping layer BC may be disposed between a lower horizontal line G2 and the first conductive line BL. The second capping layer CC may be disposed between the upper horizontal line G1 and the first electrode SN of the data storage element CAP. Also, the second capping layer CC may be disposed between the lower horizontal line G2 and the first electrode SN of the data storage element CAP. One memory cell MC may include a pair of first capping layers BC and a pair of second capping layers CC.

The first and second capping layers BC and CC may include a dielectric material. The first and second capping layers BC and CC may include, for example, silicon oxide, silicon nitride, silicon carbon oxide, an air gap, or a combination thereof. The first capping layer BC may include, for example, silicon oxide, and the second capping layer CC may include a stack of silicon oxide and silicon nitride.

The memory cells MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon. The first and second doped regions SR, and DR may include impurities diffused from the first and second contact nodes BLC and SNC, respectively.

The horizontal layers HL of the switching elements TR disposed horizontally in the third direction D3 may share one second conductive line DWL. The horizontal layers HL of the switching elements TR disposed horizontally in the third direction D3 may be coupled to different first conductive lines BL. The switching elements TR stacked in the first direction D1 may share one first conductive line BL. The switching elements TR disposed horizontally in the third direction D3 may share a second conductive line DWL.

The first cell isolation layers ISOA may be disposed between the first electrodes SN of the data storage elements CAP in the third direction D3. The first electrodes SN may be separated from each other by the first cell isolation layers ISOA. The second electrodes PN of the data storage elements CAP may be coupled to a common plate PL.

The lower structure LS may include a semiconductor substrate, a metal interconnection structure, a dielectric structure, a conductive structure, a bonding pad structure, another memory or a peripheral circuit portion.

For example, the lower structure LS may include a structure in which a peripheral circuit portion, a metal interconnection structure, and a bonding pad structure are stacked in the mentioned order. The memory cell arrays MCA1, MCA2, MCA3, and MCA4 and the peripheral circuit portion of the lower structure LS may be joined by wafer bonding.

The peripheral circuit portion of the lower structure LS may be disposed at a lower level than the memory cell arrays MCA1, MCA2, MCA3, and MCA4. This may be referred to as COP (Cell over PERI) structure. The peripheral circuit portion may include at least one control circuit for driving the memory cell arrays MCA1, MCA2, MCA3, and MCA4. The at least one control circuit of the peripheral circuit portion may include an N-channel transistor, a P-channel transistor, a CMOS circuit, or a combination thereof. The at least one control circuit of the peripheral circuit portion may include an address decoder circuit, a read circuit, a write circuit, and the like. The at least one control circuit of the peripheral circuit portion may include a planar channel transistor, a recess channel transistor, a buried gate transistor, a fin channel transistor (FinFET), and the like.

For example, the peripheral circuit portion may include sub-word line drivers and a sense amplifier. The first conductive lines BL may be coupled to the sense amplifier, and the second conductive lines DWL may be coupled to the sub-word line drivers.

According to another embodiment of the present disclosure, the peripheral circuit portion may be disposed at a higher level than the memory cell arrays MCA1, MCA2, MCA3, and MCA4. This may be referred to as POC (PERI over Cell) structure.

According to another embodiment of the present disclosure, the memory cell arrays MCA1, MCA2, MCA3, and MCA4 may include a Dynamic Random Access Memory (DRAM), an embedded DRAM, a NAND, a ferroelectric RAM (FeRAM), a Spin Transfer Torque RAM (STTRAM), a phase-change RAM (PCRAM), or a resistive RAM (ReRAM).

According to another embodiment of the present disclosure, each memory cell MC may be replaced with the memory cell MC1 shown in FIG. 1D.

The semiconductor device 100 may include a first region R1, a second region R2, and a third region R3. The first region R1 may be a memory cell region where memory cells MC are formed, and the second and third regions R2 and R3 may be a connection region. The second and third regions R2 and R3 may be an area where the edge portions of the second conductive lines DWL of the memory cells MC are formed. The memory cells MC of the memory cell arrays MCA1, MCA2, MCA3, and MCA4 may be disposed in the first region R1. The edge portions of the second conductive lines DWL of the memory cell arrays MCA1 and MCA3 may be disposed in the second region R2. The edge portions of the second conductive lines DWL of the memory cell arrays MCA2 and MCA4 may be disposed in the third region R3. A plurality of third cell isolation layers ISOC may be formed between the first region R1 and the second region R2. A plurality of third cell isolation layers ISOC may be formed between the first region R1 and the third region R3. The third cell isolation layers ISOC may be formed of the same material as those of the first and second cell isolation layers ISOA and ISOB.

The edge portions of the second conductive lines DWL may include a staircase structure. Hereinafter, the structure including the edge portions of the second conductive lines DWL may be simply referred to as a ‘staircase stack WLE.’ The staircase stacks WLE may be disposed in the second and third regions R2 and R3.

First pad isolation slits WSL1 and second pad isolation slits WSL2 may be formed in the second and third regions R2 and R3.

Second pad isolation slits WSL2 may be disposed between the first pad isolation slits WSL1. The length of the second pad isolation slits WSL2 in the second direction D2 may be greater than the length in the third direction D3. The second pad isolation slits WSL2 may extend in the second direction D2. The second pad isolation slits WSL2 may include a dielectric material. The first pad isolation slits WSL1 may be referred to as line-shaped pad isolation slits, and the second pad isolation slits WSL2 may be referred to as hole-shaped pad isolation slits or pillar-shaped pad isolation slits. The first pad isolation slits WSL1 may be formed on both side surfaces of the staircase stack WLE. The second pad isolation slits WSL2 may penetrate the staircase stack WLE.

The first pad isolation slits WSL1 and the second pad isolation slits WSL2 may include the same material. For example, the first pad isolation slits WSL1 and the second pad isolation slits WSL2 may include, for example, silicon oxide, silicon nitride, silicon carbon oxide, or a combination thereof.

The staircase stacks WLE may be supported by the first and second pad isolation slits WSL1 and WSL2. The first and second pad isolation slits WSL1 and WSL2 may be referred to as ‘supporter slits.’ The second pad isolation slits WSL2 may be referred to as ‘pillar-shaped isolation slits’. The second pad isolation slits WSL2 may suppress the bending of the staircase stacks WLE. As a result, the second pad isolation slits WSL2 may increase the structural strength of the staircase stack WLE.

The first pad isolation slits WSL1 may be disposed between the memory cell arrays MCA1 and MCA3 in the second region R2. The staircase stacks WLE of the memory cell arrays MCA1 and MCA3 may be spaced apart from each other by the first pad isolation slits WSL1. The first pad isolation slits WSL1 may be disposed between the memory cell arrays MCA2 and MCA4 in the third region R3. The staircase stacks WLE of the memory cell arrays MCA2 and MCA4 may be spaced apart from each other by the first pad isolation slits WSL1.

Referring back to FIGS. 3A to 3C, the memory cell array MCA1 may include a vertical stack WLS extending from the first region R1 to the second region R2. A portion of the vertical stack WLS disposed in the second region R2 may be simply referred to as a staircase stack WLE. The other memory cell arrays MCA2, MCA3, and MCA4 may also include a vertical stack WLS and a staircase stack WLE.

The vertical stack WLS may include a plurality of second conductive lines DWL and inter-cell dielectric layers IL that are stacked in the first direction D1. Each of the second conductive lines DWL of the vertical stack WLS may have a double structure including an upper horizontal line G1 and a lower horizontal line G2. The vertical stack WLS may further include horizontal layers HL, inter-level dielectric layers GD, and horizontal layer-level spacers HLS. The horizontal layer-level spacers HLS may be disposed horizontally between the horizontal layers HL. The inter-level dielectric layers GD may be disposed on the top and bottom surfaces of the horizontal layers HL, respectively.

The staircase stack WLE may include a plurality of second conductive lines DWL and inter-cell dielectric layers IL that are stacked in the first direction D1. Each of the second conductive lines DWL of the staircase stack WLE may have a double structure including an upper horizontal line G1 and a lower horizontal line G2. The staircase stack WLE may further include pad portions GP between the upper and lower horizontal lines G1 and G2. The pad portions GP may electrically connect the upper and lower horizontal lines G1 and G2 to each other. The upper horizontal lines G1, the lower horizontal lines G2, and the pad portions GP may include the same material. For example, the upper horizontal lines G1, the lower horizontal lines G2, and the pad portions GP may include a metal-based material. The staircase stack WLE may include a plurality of staircases (or stair steps) whose length gradually decreases in the stacked direction (i.e., the first direction D1). The length of the pad portions GP may gradually decrease in the stacked direction (i.e., the first direction D1). The horizontal lengths of the pad portions GP in the third direction D3 may be different for each level. For example, the horizontal length of the lowermost-level pad portion GP may be the largest, and the horizontal length of the uppermost-level pad portion GP may be the smallest.

The second conductive lines DWL of the staircase stack WLE may be respectively coupled to the contact plugs CT.

As described above, the memory cell array MCA1 of the semiconductor device 100 may include a vertical stack WLS including the second conductive lines DWL that are alternately stacked vertically from the upper portion of the lower structure LS with the first pad isolation slit WSL1 interposed therebetween over the lower structure LS, a staircase stack WLE extending from the second conductive lines DWL, and a second pad isolation slit WSL2 extending vertically in a direction that the second conductive lines DWL are stacked while penetrating the staircase stack WLE.

According to the above-described embodiment of the present disclosure, the second pad isolation slits WSL2 may prevent the bridge between the second conductive lines DWL in the second region R2. Also, the second pad isolation slits WSL2 may serve as a wet barrier when a pad portion GP is formed, thereby further preventing the bridge between the vertically stacked second conductive lines DWL. In particular, when the second pad isolation slits WSL2 include silicon carbon oxide, they may serve as a wet barrier when the pad portion GP is formed, and accordingly, the bridge between the vertically stacked second conductive lines DWL may be further prevented.

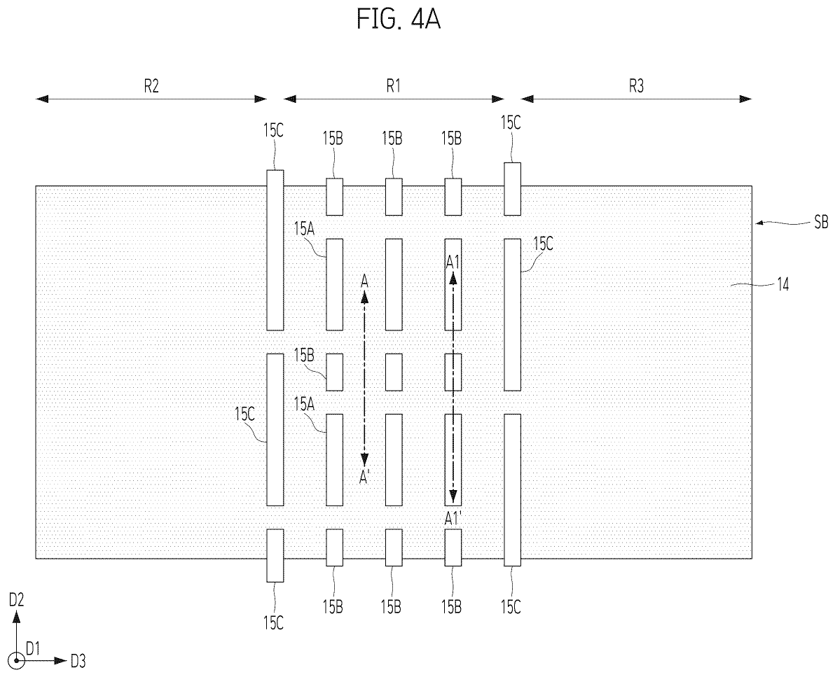

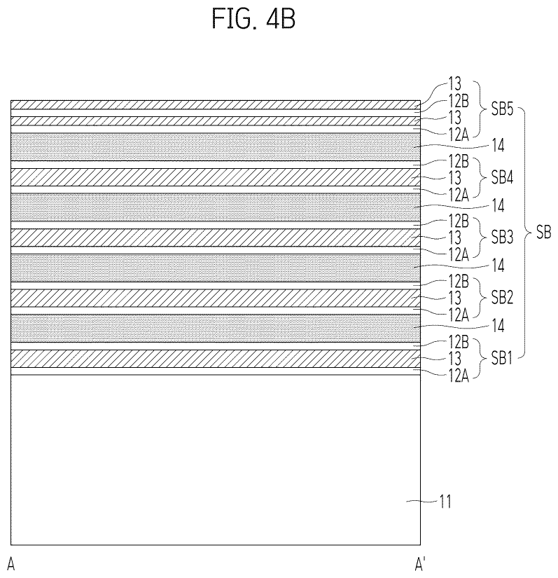

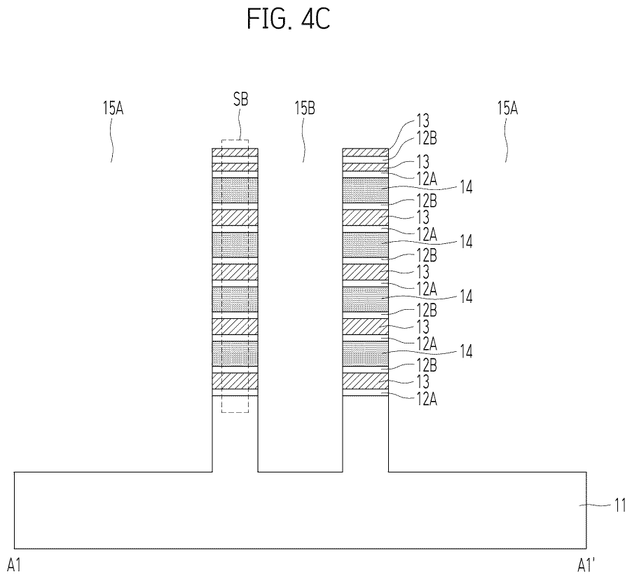

FIGS. 4A to 22C illustrate a method for fabricating a semiconductor device in accordance with embodiments of the present disclosure.

FIG. 4A is a plan view at the level of a fourth layer 14 illustrating a method for forming a stack body SB and sacrificial isolation openings 15A, 15B, and 15C, and FIG. 4B is a plan view taken along a line A-A′ shown in FIG. 4A. FIG. 4C is a cross-sectional view taken along a line A1-A1′ shown in FIG. 4A.

Referring to FIGS. 4A to 4C, a stack body SB may be formed over the lower structure 11. The lower structure 11 may be a material suitable for semiconductor processing including at least one from among a conductive material, a dielectric material, and a semiconductive material. Diverse materials may be formed over the lower structure 11. The lower structure 11 may include a semiconductor substrate. The lower structure 11 may include a material containing silicon. The lower structure 11 may include silicon, mono crystalline silicon, polysilicon, amorphous silicon, silicon germanium, mono crystalline silicon germanium, polycrystalline silicon germanium, carbon-doped silicon, a combination thereof, or a multi-layer thereof. The lower structure 11 may also include other semiconductor materials such as germanium. The lower structure 11 may include a group-III/V semiconductor substrate, for example, a compound semiconductor substrate such as gallium arsenide (GaAs). The lower structure 11 may include, for example, a silicon-on-insulator (SOI) substrate.

The stack body SB may include a plurality of sub-stacks that are alternately stacked. Each of the sub-stacks may include a first layer 12A, a second layer 13, a third layer 12B, and a fourth layer 14 that are stacked in the mentioned order. The first layers 12A and the third layers 12B may be formed of the same material and may include silicon germanium or mono crystalline silicon germanium. The second layers 13 and the fourth layers 14 may be formed of the same material and may include mono crystalline silicon. The first layers 12A, the second layers 13, the third layers 12B, and the fourth layers 14 may be formed by an epitaxial growth process. The lowermost-level first layer 12A may serve as a seed layer during the epitaxial growth process. The first layers 12A may be thinner than the second layers 13, and the fourth layers 14 may be thicker than the second layers 13.

According to this embodiment of the present disclosure, the stack body SB may include a plurality of fourth layers 14, a first stack SB1, a second stack SB2, a third stack SB3, and a fourth stack SB4. The stack body SB may include a first stack SB1, a fourth layer 14, a second stack SB2, a fourth layer 14, a third stack SB3, a fourth layer 14, and a fourth stack SB4 that are stacked in the mentioned order. The stack body SB may further include a fifth stack SB5 disposed at the uppermost level. Each of the first stack SB1, the second stack SB2, the third stack SB3, and the fourth stack SB4 may include a three-layer stack of the first layer 12A/second layer 13/third layer 12B. For example, when the first layers 12A and the third layers 12B include a silicon germanium layer and the second layers 13 include a mono crystalline silicon layer, the first stack SB1, the second stack SB2, the third stack SB3, and the fourth stack SB4 may include a stack (SiGe/Si/SiGe) of first silicon germanium/mono crystalline silicon/second silicon germanium. The fifth stack SB5 may further include a second layer 13 over the three-layer stack of the first layer 12A/second layer 13/third layer 12B.

The second layers 13 may include a first mono crystalline silicon layer, and the fourth layers 14 may include a second mono crystalline silicon layer. The second mono crystalline silicon layers may be thicker than the first mono crystalline silicon layers. For example, the second mono crystalline silicon layer may be disposed between the first stack SB1 and the second stack SB2. Each of the first to fourth stacks SB1 to SB4 may include a stack of a first silicon germanium layer/first mono crystalline silicon layer/second silicon germanium layer, and the second mono crystalline silicon layers may be thicker than the first mono crystalline silicon layers.

The first layers 12A, the second layers 13, and the third layers 12B may be referred to as ‘sacrificial layers,’ and the fourth layers 14 may be referred to as recess target layers. The stack body SB may be referred to as a vertical stack. The stack body SB may be formed by alternating a plurality of sacrificial layers and the recess target layers. The sacrificial layers may include first to fourth stacks SB1 to SB4, and each of the first to fourth stacks SB1 to SB4 may include a three-layer stack of the first layer 12A/second layer 13/third layer 12B. The recess target layers may include the fourth layers 14. Each of the sacrificial layers may include a three-layer stack of the first silicon germanium layer/first mono crystalline silicon layer/second silicon germanium layer, and each of the recess target layers may include a single layer of the second mono crystalline silicon layer, and the second mono crystalline silicon layers may be thicker than the first mono crystalline silicon layers.

Referring to FIGS. 2 to 3C described above, when the memory cells MC are vertically stacked, the first stack SB1, the fourth layer 14, the second stack SB2, the fourth layer 14, the third stack SB3, the fourth layer 14, and the fourth stack SBR may be alternately stacked in the mentioned order several times.

The stack body SB may include the first region R1, the second region R2, and the third region R3. The first region R1 may be an area where memory cells are to be formed, and the second and third regions R2 and R3 may be areas where pad portions are to be formed. The first region R1 may be disposed between the second and third regions R2 and R3.

Subsequently, portions of the stack body SB may be etched to form a plurality of sacrificial isolation openings 15A, 15B, and 15C. The sacrificial isolation openings 15A and 15B may be initial openings for cell isolation and may include the first sacrificial isolation openings 15A and the second sacrificial isolation openings 15B. The first sacrificial isolation openings 15A and the second sacrificial isolation openings 15B may be formed in the first region R1. While the first sacrificial isolation openings 15A and the second sacrificial isolation openings 15B are formed, the third sacrificial isolation openings 15C may be formed at the boundary portion between the first region R1 and the second region R2 and at the boundary portion between the first region R1 and the third region R3. The size of the first sacrificial isolation openings 15A may be greater than the second sacrificial isolation openings 15B. The third sacrificial isolation openings 15C may be greater than the first sacrificial isolation openings 15A and the second sacrificial isolation openings 15B. Portions of the third sacrificial isolation openings 15C may be greater than the second sacrificial isolation openings 15B and smaller than the first sacrificial isolation openings 15A. From the perspective of a top view, the first sacrificial isolation openings 15A, the second sacrificial isolation openings 15B, and the third sacrificial isolation openings 15C may have a rectangular shape. According to another embodiment of the present disclosure, the first sacrificial isolation openings 15A, the second sacrificial isolation openings 15B, and the third sacrificial isolation openings 15C may have a circular shape or an elliptical shape.

According to another embodiment of the present disclosure, the sacrificial isolation openings 15A, 15B and 15C may be referred to as the sacrificial isolation trenches.

The first sacrificial isolation openings 15A, the second sacrificial isolation openings 15B, and the third sacrificial isolation openings 15C may extend vertically in the first direction D1. In the first region R1, the first sacrificial isolation openings 15A and the second sacrificial isolation openings 15B may be alternately disposed in the second direction D2. A plurality of the first sacrificial isolation openings 15A may be disposed in the third direction D3. A plurality of the second sacrificial isolation openings 15B may be disposed in the third direction D3. The first sacrificial isolation openings 15A, the second sacrificial isolation openings 15B, and the third sacrificial isolation openings 15C may penetrate the stack body SB in the first direction D1.

After the sacrificial isolation openings 15A, 15B, and 15C are formed, portions of the lower structure 11 exposed below the sacrificial isolation openings 15A, 15B, and 15C may be etched. Accordingly, the bottom surfaces of the sacrificial isolation openings 15A, 15B, and 15C may extend into the lower structure 11. The bottom surface of the sacrificial isolation openings 15A, 15B and 15C may include a U-shaped profile. The fourth layers 14 may have a mesh-shaped pattern due to the sacrificial isolation openings 15A, 15B, and 15C.

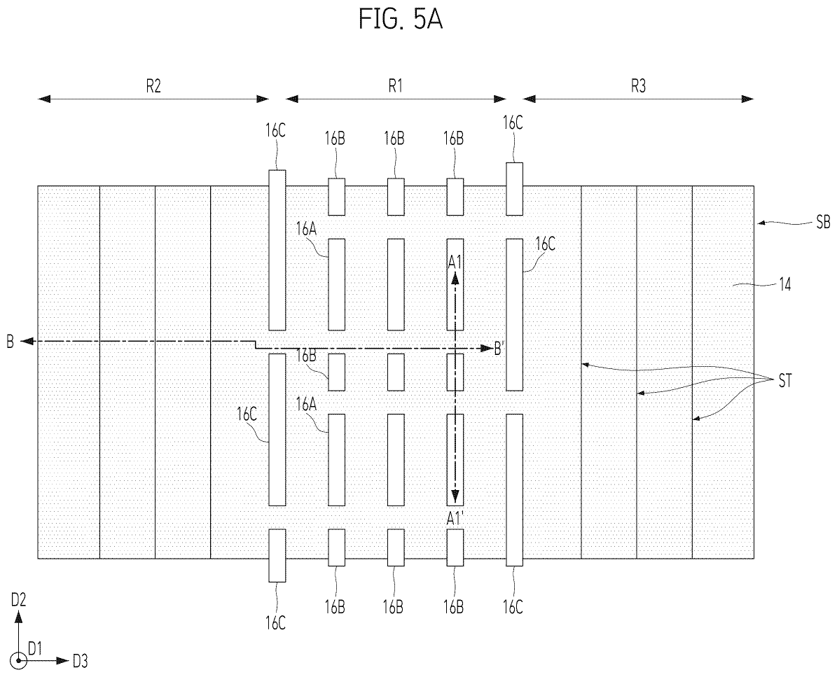

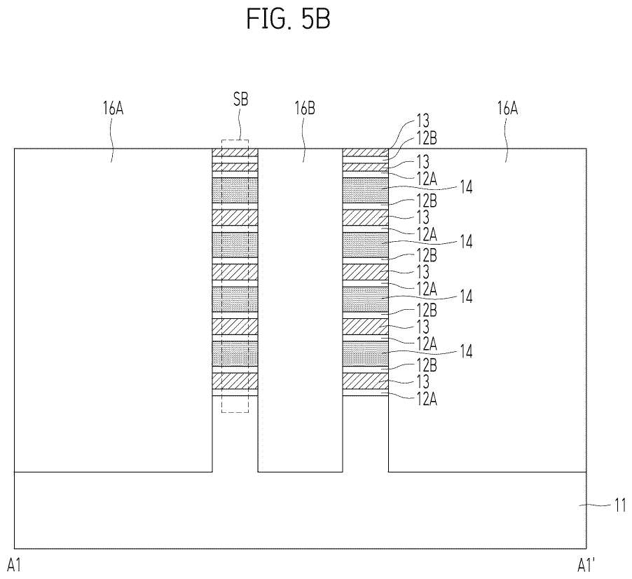

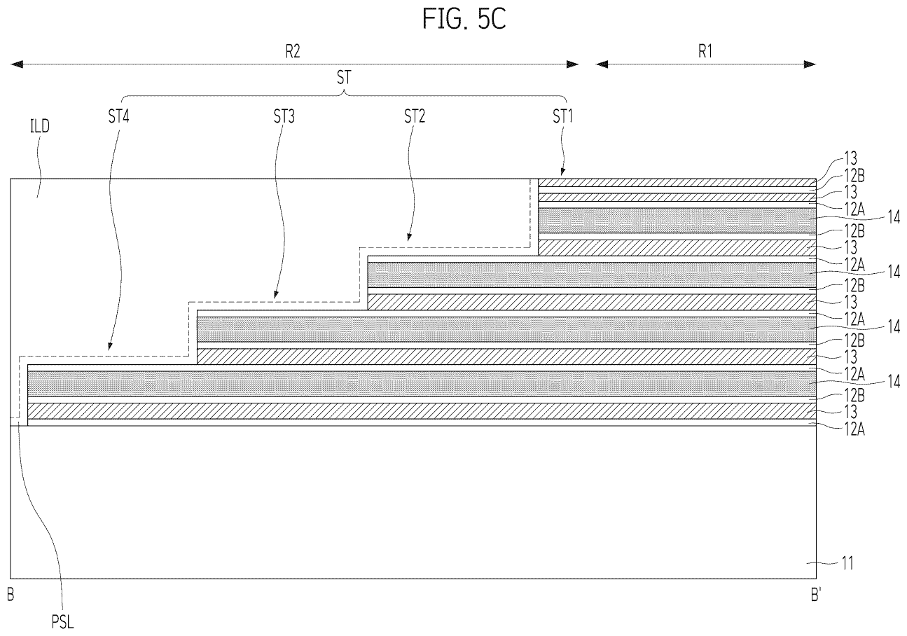

FIG. 5A is a plan view at the level of the fourth layer 14 illustrating a method for forming sacrificial isolation layers 16A, 16B, and 16C, and FIG. 5B is a cross-sectional view taken along a line A1-A1′ shown in FIG. 5A. FIG. 5C is a cross-sectional view taken along a line B-B′ shown in FIG. 5A.

Referring to FIGS. 5A to 5C, sacrificial isolation layers 16A, 16B, and 16C may be formed to fill the sacrificial isolation openings 15A, 15B, and 15C. The sacrificial isolation layers 16A, 16B, and 16C may include first sacrificial isolation layers 16A, second sacrificial isolation layers 16B, and third sacrificial isolation layers 16C. The first sacrificial isolation layers 16A may fill the first sacrificial isolation openings 15A, and the second sacrificial isolation layers 16B may fill the second sacrificial isolation openings 15B. The third sacrificial isolation layers 16C may fill the third sacrificial isolation openings 15C.

The first, second, and third sacrificial isolation layers 16A, 16B, and 16C may include the same material. The first, second, and third sacrificial isolation layers 16A, 16B, and 16C may be formed of a dielectric material. For example, the first, second, and third sacrificial isolation layers 16A, 16B, and 16C may include silicon oxide, silicon nitride, silicon carbon oxide, silicon carbon nitride, or a combination thereof. Forming the first, second, and third sacrificial isolation layers 16A, 16B, and 16C may include forming sacrificial isolation materials over the stack body SB to fill the sacrificial isolation openings 15A, 15B, and 15C, and planarizing the sacrificial isolation materials to expose the uppermost layer of the stack body SB. The first, second, and third sacrificial isolation layers 16A, 16B, and 16C may have different sizes or different volumes. For example, the size (or volume) of the first sacrificial isolation layers 16A may be greater than the second sacrificial isolation layers 16B. The first sacrificial isolation layers 16A and the second sacrificial isolation layers 16B may have the same length in the third direction D3, and may have different lengths in the second direction D2. The length of the first sacrificial isolation layers 16A in the second direction D2 may be greater than that of the second sacrificial isolation layers 16B. The size (or volume) of the third sacrificial isolation layers 16C may be greater than the first and second sacrificial isolation layers 16A and 16B.

The first, second, and third sacrificial isolation layers 16A, 16B, and 16C may extend vertically in the first direction D1. The first sacrificial isolation layers 16A and the second sacrificial isolation layers 16B may be alternately disposed in the second direction D2 in the first region R1. A plurality of first sacrificial isolation layers 16A may be disposed in the third direction D3. A plurality of second sacrificial isolation layers 16B may be disposed in the third direction D3. The first, second, and third sacrificial isolation layers 16A, 16B, and 16C may penetrate the stack body SB in the first direction D1.

Each of the first, second, and third sacrificial isolation layers 16A, 16B, and 16C may include a stack of a sacrificial liner layer and a sacrificial gap-fill layer. The sacrificial liner layers and the sacrificial gap-fill layers may include, for example, silicon oxide, silicon nitride, silicon carbon oxide, amorphous carbon, or a combination thereof. The sacrificial liner layer may serve as a blocking layer to prevent loss of the sacrificial gap-fill layers during the subsequent recess process of the fourth layers 14.

After the first, second, and third sacrificial isolation layers 16A, 16B, and 16C are formed, a staircase structure ST may be formed in each of the second and third regions R2 and R3 by etching the stack body SB.

To form the staircase structure ST shown in FIG. 5C, a plurality of slimming mask layers may be formed and a plurality of slimming etches may be performed. The slimming mask layers may include a photoresist pattern, and the slimming etches may be processes that sequentially etch the stack body SB from the uppermost-level stack. For example, a first etching process including a first slimming mask layer and a first slimming etch, a second etching process including a second slimming mask layer and a second slimming etch, a third etching process including a third slimming mask layer and a third slimming etch, and a fourth etching process including a fourth slimming mask layer and a fourth slimming etch may be sequentially performed. The first etching process may include etching the fifth stack SB5, the fourth layer 14 between the fifth stack SB5 and the fourth stack SBR, and the third layer 12B and the second layer 13 of the fourth stack SB4 to stop at the first layer 12A of the fourth stack SB4. In the second etching process, the second slimming mask layer may be formed by slimming the first slimming mask layer, and the second slimming etch may include etching the fifth stack SB5, the fourth layer 14 between the fifth stack SB5 and the fourth stack SBR, and the third layer 12B and the second layer 13 of the fourth stack SB4 to stop at the first layer 12A of the fourth stack SB4, and etching the first layer 12A of the fourth stack SB4, the fourth layer 14 between the fourth stack SB4 and the third stack SB3, and the third layer 12B and the second layer 13 of the third stack SB3 to stop at the first layer 12A of the third stack SB3. In the third etching process, the third slimming mask layer may be formed by slimming the second slimming mask layer, and the third slimming etch may include etching the stack SB5, the fourth layer 14 between the fifth stack SB5 and the fourth stack SBR, and the third layer 12B and the second layer 13 of the fourth stack SB4 to stop at the first layer 12A of the fourth stack SB4, etching the first layer 12A of the fourth stack SB4, the fourth layer 14 between the fourth stack SB4 and the third stack SB3, and the third layer 12B and the second layer 13 of the third stack SB3 to stop at the first layer 12A of the third stack SB3, etching the first layer 12A of the third stack SB3, the fourth layer 14 between the third stack SB3 and the second stack SB2, and the third layer 12B and the second layer 13 of the second stack SB2 to stop at the first layer 12A of the second stack SB2. In the fourth etching process, the fourth slimming mask layer may be formed by slimming the third slimming mask layer, and the third slimming etch may include etching the fifth stack SB5, the fourth layer 14 between the fifth stack SB5 and the fourth stack SBR, and the third layer 12B and the second layer 13 of the fourth stack SB4 to stop at the first layer 12A of the fourth stack SB4, etching the first layer 12A of the fourth stack SB4, the fourth layer 14 between the fourth stack SB4 and the third stack SB3, and the third layer 12B and the second layer 13 of the third stack SB3 to stop at the first layer 12A of the third stack SB3, etching the first layer 12A of the third stack SB3, the fourth layer 14 between the third stack SB3 and the second stack SB2, and the third layer 12B and the second layer 13 of the second stack SB2 to stop at the first layer 12A of the second stack SB2. The slimming process for forming the slimming mask layers may refer to a process of horizontally decreasing the widths of the slimming mask layers.

A plurality of staircases ST1 to ST4 may be formed in the second and third regions R2 and R3, individually, by using the slimming mask layers and the slimming etches, which are described above. The staircases ST1 to ST4 may not be formed in the first region. Among the staircases ST1 to ST4, the second staircase ST2 and the third staircase ST3 may have a four-layer structure of the second layer 13, the third layer 12B, the fourth layer 14, and the first layer 12A that are stacked in the mentioned order. Among the staircases ST1 to ST4, the first staircase ST1 may have a seven-layer structure of the second layer 13, the third layer 12B, the fourth layer 14, the first layer 12A, the second layer 13, the third layer 12B and the second layer 13 that are stacked in the mentioned order. Among the staircases ST1 to ST4, the fourth staircase ST4 may have a five-layer structure of the first layer 12A, the second layer 13, the third layer 12B, the fourth layer 14, and the first layer 12A that are stacked in the mentioned order.

After the staircases ST1 to ST4 are formed, an inter-layer dielectric layer ILD covering the staircases ST1 to ST4 may be formed, as illustrated in FIG. 5C. According to another embodiment of the present disclosure, before the inter-layer dielectric layer ILD is formed, a staircase passivation layer PSL covering the profile of the staircases ST1 to ST4 may be formed. The staircase passivation layer PSL and the inter-layer dielectric layer ILD may include, for example, silicon oxide, silicon nitride, or a combination thereof.

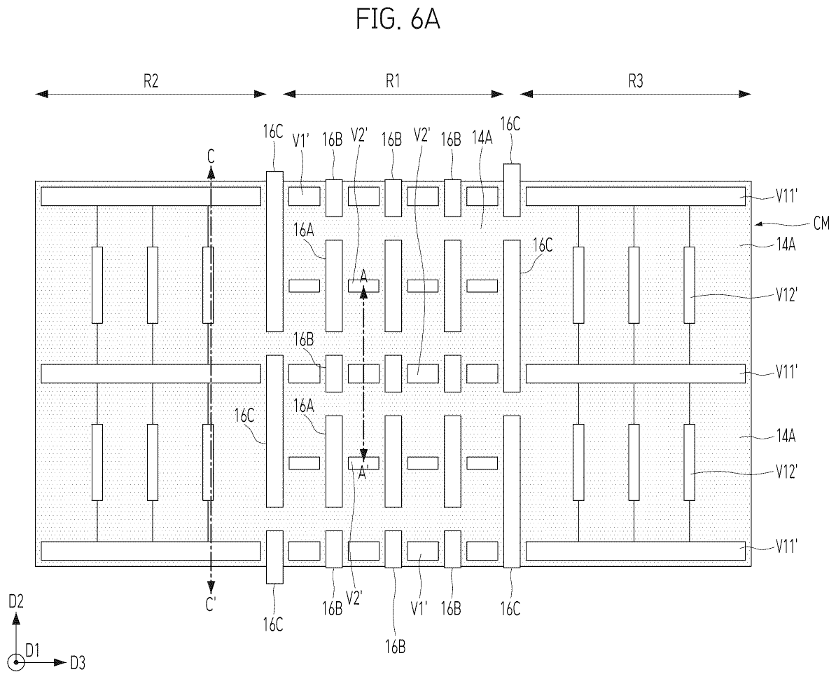

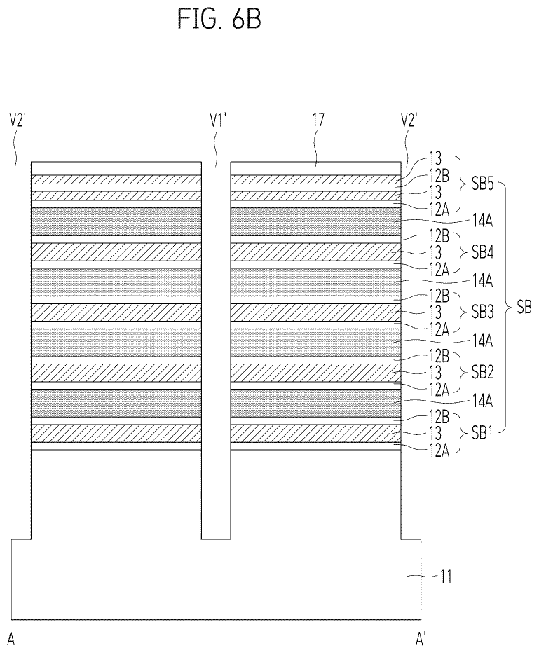

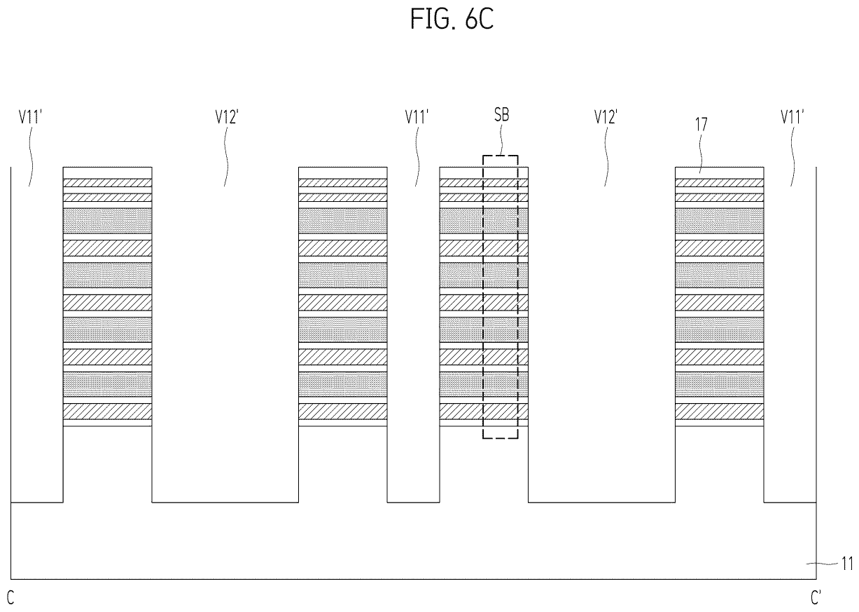

FIG. 6A is a plan view at the level of the fourth layer 14 illustrating a method for forming the sacrificial vertical openings V1′ and V2′, and FIG. 6B is a cross-sectional view taken along a line A-A′ shown in FIG. 6A. FIG. 6C is a cross-sectional view taken along a line C-C′ shown in FIG. 6A.

Referring to FIGS. 6A to 6C, a hard mask layer pattern 17 may be formed over the stack body SB, the first, second, and third sacrificial isolation layers 16A, 16B, and 16C. The hard mask layer pattern 17 may include silicon nitride. The hard mask layer pattern 17 may be formed by an etching process using a mask layer. The hard mask layer pattern 17 may have a plurality of hole-shaped openings defined therein.

Portions of the stack body SB may be etched in the first region R1 by using the hard mask layer pattern 17 as an etch barrier. As a result, a plurality of sacrificial vertical openings V1′ and V2′ may be formed in the stack body SB. The sacrificial vertical openings V1′ and V2′ may include first sacrificial vertical openings V1′ and second sacrificial vertical openings V2′. From the perspective of a top view, the first sacrificial vertical openings V1′ and the second sacrificial vertical openings V2′ may be hole-shaped openings. The first sacrificial vertical openings V1′ and the second sacrificial vertical openings V2′ may extend vertically in the first direction D1. The first sacrificial vertical openings V1′ and the second sacrificial vertical openings V2′ may be formed by etching the stack body SB between the first and second sacrificial isolation layers 16A and 16B. The first sacrificial vertical openings V1′ may be formed by etching the stack body SB between the second sacrificial isolation layers 16B. The second sacrificial vertical openings V2′ may be formed by etching the stack body SB between the first sacrificial isolation layers 16A. The first sacrificial vertical openings V1′ may be disposed between the second sacrificial isolation layers 16B in the third direction D3. The second sacrificial vertical openings V2′ may be disposed between the first sacrificial isolation layers 16A in the third direction D3. From the perspective of a top view, the cross-sections of the first and second sacrificial vertical openings V1′ and V2′ may have a square shape, a circular shape or an elliptical shape.

While the first and second sacrificial vertical openings V1′ and V2′ are formed, a plurality of pads isolation openings V11′ and V12′ penetrating the stack body SB in the second and third regions R2 and R3 may be formed simultaneously. The pad isolation openings V11′ and V12′ may include a line-shaped pad isolation opening V11′ and a hole-shaped pad isolation opening V12′. The hole-shaped pad isolation opening V12′ may be disposed between the line-shaped pad isolation openings V11′.

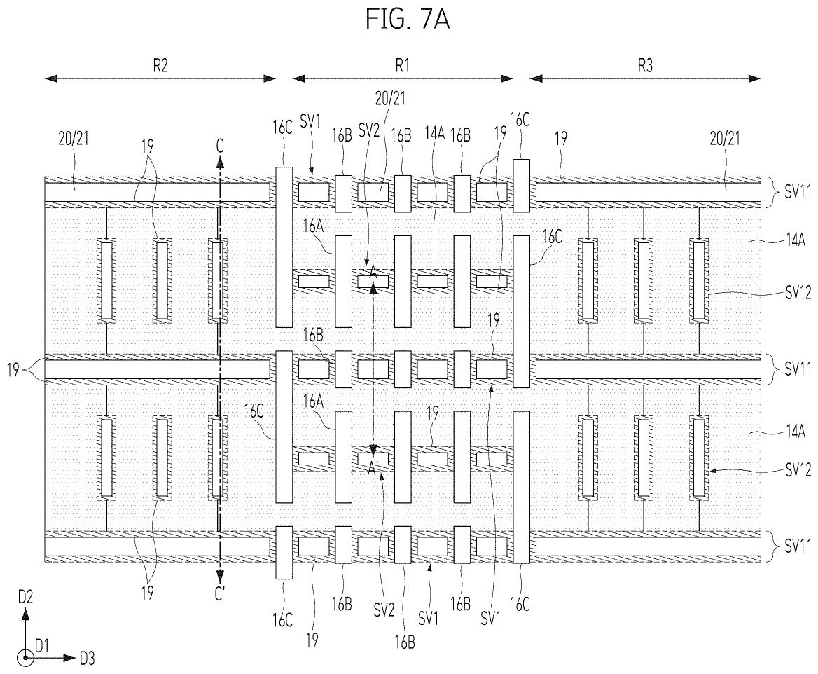

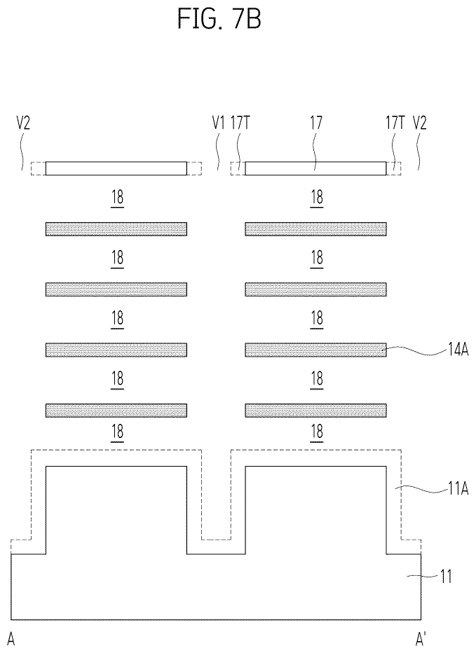

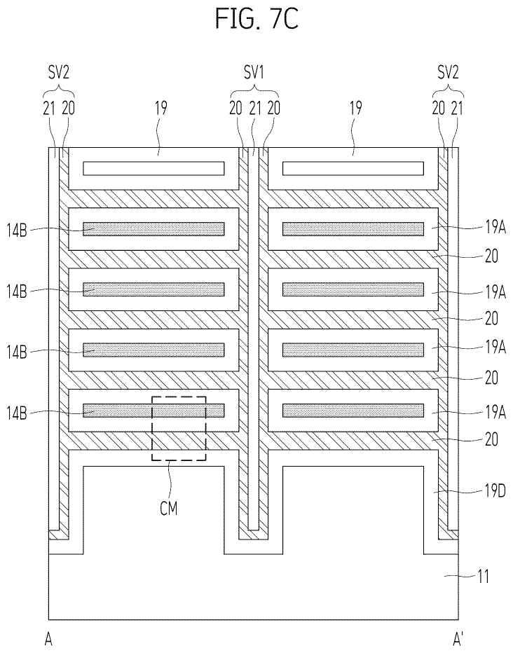

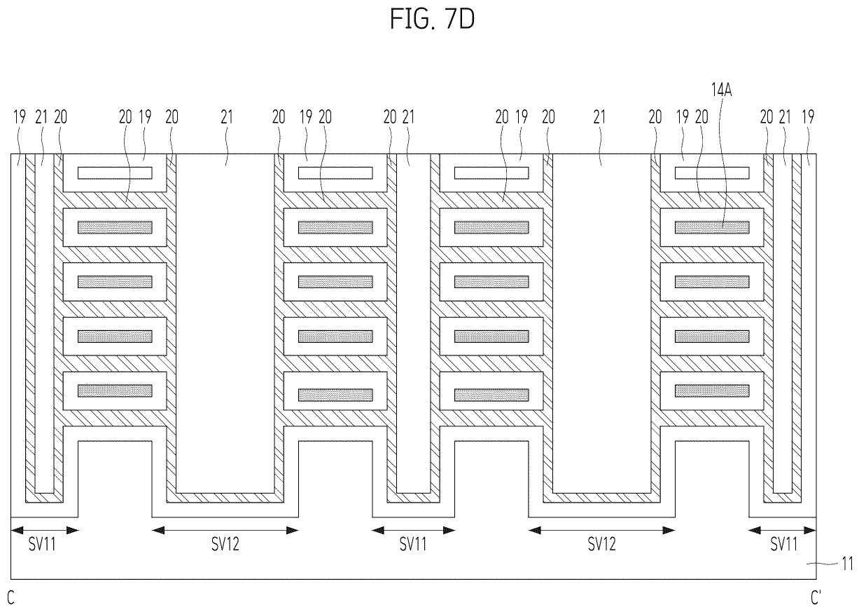

FIG. 7A is a plan view illustrating a method for forming preliminary horizontal layers 14A, a first dielectric layer 19, and a second dielectric layer 20, and FIGS. 7B and 7C are cross-sectional views taken along a line A-A′ shown in FIG. 7A. FIG. 7D is a cross-sectional view taken along a line C-C′ shown in FIG. 7A.

Referring to FIGS. 7A to 7D, a portion of the hard mask layer pattern 17 may be trimmed (see a reference numeral ‘17T’).

The first and third layers 12A and 12B may be selectively removed from the first region R1, the second region R2, and the third region R3 by using the trimmed hard mask layer pattern 17 as a barrier. The first and third layers 12A and 12B may be selectively removed through the sacrificial vertical openings V1′ and V2′ from the first region R1. The first and third layers 12A and 12B may be selectively removed through the pad isolation openings V11′ and V12′ from the second and third regions R2 and R3. The first layers 12A and the third layers 12B may be selectively removed based on the difference between the etch selectivity of the second and fourth layers 13 and 14 and the etch selectivity of the first and third layers 12A and 12B. The first layers 12A and the third layers 12B may be removed by a wet etching process or a dry etching process. For example, when the first layers 12A and the third layers 12B include a silicon germanium layer and the second layers 13 and the fourth layers 14 include a mono crystalline silicon layer, the silicon germanium layers may be etched by using an etchant or an etching gas having a selectivity with respect to the mono crystalline silicon layers.

The second layers 13 and the fourth layers 14 may be recessed. The second layers 13 and the fourth layers 14 may be recessed by a wet etching process or a dry etching process. According to this embodiment of the present disclosure, the fourth layers 14 may be partially etched while the second layers 13 are removed. As a result, the second layers 13 may be removed, and the fourth layers 14 may become thin, as indicated by a reference numeral ‘14A’. The recess process for forming the thin fourth layer 14A, i.e., the preliminary horizontal layers 14A, may be referred to as a thinning process or a trimming process of the fourth layers 14. The preliminary horizontal layers 14A may be formed by recessing the top surface, bottom surface and side surfaces of the fourth layers 14. The preliminary horizontal layers 14A may be referred to as a thin-body active layer. The preliminary horizontal layers 14A may include a mono crystalline silicon layer. The recess process for forming the preliminary horizontal layers 14A may use, for example, HSC1 (Hot SC-1). HSC1 may include a solution of ammonium hydroxide (NH₄OH), hydrogen peroxide (H₂O₂), and water (H₂O) that are mixed at a ratio of approximately 1:4:20. The second layers 13 and the fourth layers 14 may be selectively etched by using HSC1.

The preliminary horizontal layers 14A may be formed by a recess process for the fourth layers 14 as described above, and horizontal recesses 18 may be formed between the preliminary horizontal layers 14A. Each of the top and bottom surfaces of the preliminary horizontal layers 14A may include a flat surface. The preliminary horizontal layers 14A may extend horizontally from the first region R1 to the second and third regions R2 and R3. The preliminary horizontal layers 14A and the horizontal recesses 18 may be formed in the first region R1, the second region R2, and the third region R3.

From the perspective of a top view, the preliminary horizontal layers 14A of the first region R1 may have a cross-shape. The side surfaces of the preliminary horizontal layers 14A may have a bent shape or a rounded shape. The preliminary horizontal layers 14A of the second and third regions R2 and R3 may have a flat shape.

After the preliminary horizontal layers 14A are formed, the first sacrificial vertical openings V1′, the second sacrificial vertical openings V2′ and the pad isolation openings V11′ and V12′ may be expanded as indicated by reference numerals V1, V2, V11, and V12, respectively. The first sacrificial vertical openings V1 and the second sacrificial vertical openings V2 may have the same size. The preliminary horizontal layers 14A may be spaced apart from each other by the first and second sacrificial vertical openings V1 and V2 in the second direction D2. The preliminary horizontal layers 14A may have a shape in which a plurality of cross shapes are merged in the third direction D3.

While the preliminary horizontal layers 14A are formed, the surface of the lower structure 11 may be recessed to a predetermined depth. As a result, the depths of the first sacrificial vertical openings V1, the second sacrificial vertical openings V2, and the pad isolation openings V11 and V12 may be increased.

The first sacrificial vertical openings V1 and the second sacrificial vertical openings V2 may be alternately disposed between the preliminary horizontal layers 14A in the second direction D2. The first sacrificial vertical openings V1 may be disposed between the second sacrificial isolation layers 16B in the third direction D3, and the second sacrificial vertical openings V2 may be disposed between the first sacrificial isolation layers 16A in the third direction D3.

By the recess process described above, the preliminary horizontal layers 14A and the horizontal recesses 18 may be formed in the first region R2, the second region R2, and the third region R3. The process may be simplified by simultaneously removing the first layers 12A, the second layers 13, and the third layers 12B from the first region R1, the second region R2, and the third region R3. Also, no residues of the first layers 12A, the second layers 13, and the third layers 12B may remain at the boundary portion between the first region R1 and the second region R2 and at the boundary portion between the first region R1 and the third region R3. Since the line-shaped pad isolation openings V11 and the hole-shaped pad isolation openings V12 are formed, it may be advantageous for simultaneously removing the first layers 12A, the second layers 13 and the third layers 12B from the first region R1, the second region R2, and the third region R3. By the combination of the line-shaped pad isolation openings V11 and the hole-shaped pad isolation openings V12, the first layers 12A, the second layers 13, and the third layers 12B may be easily removed from the second and third regions R2 and R3 without residues.

After the preliminary horizontal layers 14A are formed, referring back to FIG. 7C, the first dielectric layers 19 covering the preliminary horizontal layers 14A may be formed. The first dielectric layers 19 may include silicon nitride. The first dielectric layers 19 may fully cover the top surface, bottom surface, and side surfaces of the preliminary horizontal layers 14A.

While the first dielectric layers 19 are formed, a dummy dielectric layer 19D may be formed on the surface of the lower structure 11. A portion of the first dielectric layers 19 may fully cover the top surface, bottom surface, and side surfaces of the hard mask layer pattern 17.

Subsequently, the second dielectric layer 20 may be formed over the first dielectric layers 19. The second dielectric layer 20 may fill between the vertically neighboring first dielectric layers 19. The second dielectric layer 20 may include, for example, silicon oxide. Portions of the second dielectric layer 20 may be conformally formed on the surfaces of the first and second sacrificial vertical openings V1 and V2. The horizontal recesses (see the reference numeral ‘18’ shown in FIGS. 6B to 6C) may be filled with the first dielectric layer 19 and the second dielectric layer 20.

Sacrificial pillars 21 may be formed over the second dielectric layer 20 which is disposed in the first and second sacrificial vertical openings V1 and V2. The sacrificial pillars 21 may include amorphous carbon as a sacrificial material. According to another embodiment of the present disclosure, a pillar capping layer may be further formed over the sacrificial pillars 21. The pillar capping layer may include a metal-based material. The pillar capping layer may include titanium nitride. Forming the sacrificial pillars 21 may include depositing a sacrificial material and planarizing the sacrificial material. The planarization process for forming the sacrificial pillars 21 may be performed until the uppermost-level first dielectric layer 19 is exposed. Subsequently, the uppermost-level second dielectric layer may also be planarized until the uppermost-level first dielectric layer 19 is exposed. The sacrificial pillars 21 may not be formed between the vertically stacked first dielectric layers 19.

The second dielectric layer 20 and the sacrificial pillars 21 may form first and second sacrificial pillar structures SV1 and SV2 that fill the first and second sacrificial vertical openings V1 and V2. The first sacrificial pillar structures SV1 may fill the first sacrificial vertical openings V1, and the second sacrificial pillar structure SV2 may fill the second sacrificial vertical openings V2. According to another embodiment of the present disclosure, the first and second sacrificial pillar structures SV1 and SV2 may include a dielectric material, a carbon-containing material, a metal-based material, or a combination thereof. According to another embodiment of the present disclosure, the first and second sacrificial pillar structures SV1 and SV2 may include, for example, silicon oxide, silicon nitride, titanium nitride, amorphous carbon, or a combination thereof. From the perspective of a top view, the first sacrificial pillar structure SV1 and the second sacrificial pillar structure SV2 may be hole-shaped sacrificial pillars.

Portions of the first dielectric layer 19 may be conformally formed on the surfaces of the first and second sacrificial vertical openings V1 and V2, and accordingly the first and second sacrificial pillar structures SV1 and SV2 may further include portions of the first dielectric layer 19.

The pad isolation openings V11 and V12 may also be filled with the first and second dielectric layers 19 and 20. The sacrificial pillars 21 may be formed over the second dielectric layer 20 disposed in the pad isolation openings V11 and V12.

The second dielectric layer 20 and the sacrificial pillars 21 may form pad isolation structures SV11 and SV12 that fill the pad isolation openings V11 and V12. The pad isolation structures SV11 and SV12 may include a line-shaped pad isolation structure SV11 and a pillar-shaped pad isolation structure SV12. The line-shaped pad isolation structure SV11 may fill the line-shaped pad isolation openings V11, and the pillar-shaped pad isolation structure SV12 may fill the hole-shaped pad isolation openings V12. According to another embodiment of the present disclosure, the line-shaped pad isolation structure SV11 and the pillar-shaped pad isolation structure SV12 may include a dielectric material, a carbon-containing material, a metal-based material, or a combination thereof. According to another embodiment of the present disclosure, the line-shaped pad isolation structure SV11 and the pillar-shaped pad isolation structure SV12 may include, for example, silicon oxide, silicon nitride, titanium nitride, amorphous carbon, or a combination thereof.

Portions of the first dielectric layer 19 may be conformally formed on the surfaces of the pad isolation openings V11 and V12, and thereby the line-shaped pad isolation structure SV11 and the pillar-shaped pad isolation structure SV12 may further include portions of the first dielectric layer 19.

The first sacrificial pillar structure SV1 and the second sacrificial pillar structure SV2 may be formed in the first region R1, and the line-shaped pad isolation structure SV11 and the pillar-shaped pad isolation structure SV12 may be formed in the second and third regions R2 and R3.

The preliminary horizontal layers 14A may be formed between the first sacrificial isolation layers 16A and the second sacrificial isolation layers 16B that are disposed in the second direction D2, and the first dielectric layer Layers 19 may be formed between the preliminary horizontal layers 14A, and the second dielectric layers 20 may be disposed inside the first dielectric layers 19. The first dielectric layers 19 may surround the second dielectric layers 20. The first dielectric layers 19 may include a first surrounding portion and a second surrounding portion, wherein the first surrounding portion may surround the preliminary horizontal layers 14A in the A-A′ direction, and the second surrounding portion may surround the second dielectric layers 20 between the first sacrificial isolation layers 16A and the second sacrificial isolation layers 16B that are disposed in the second direction D2.

As described above, as the preliminary horizontal layers 14A, the first dielectric layers 19, and the second dielectric layers 20 are formed, a cell mold structure may be formed in the first region R1. The cell mold structure may include a plurality of cell molds CM. Each of the cell molds CM may include a plurality of mold layers. The mold layers may refer to the preliminary horizontal layers 14A, the first dielectric layers 19, and the second dielectric layers 20. Each of the cell molds CM may include an Oxide-Nitride-Silicon-Nitride (ONSN) stack. Here, the ONSN stack may refer to a structure in which silicon oxide, a first silicon nitride, a mono crystalline silicon layer, and a second silicon nitride are sequentially stacked. The silicon oxide may correspond to the second dielectric layers 20, and the first and second silicon nitrides may correspond to the first dielectric layers 19, and the mono crystalline silicon layer may correspond to the preliminary horizontal layers 14A. A cell mold structure including a plurality of cell molds CM may be referred to as a vertical stack. From another perspective, the cell mold structure may include an Oxide-Nitride-Silicon-Nitride-Oxide (ONSNO) stack. Here, the ONSNO stack may refer to a structure in which a first silicon oxide, a first silicon nitride, a mono crystalline silicon layer, a second silicon nitride, and a second silicon oxide are sequentially stacked.

As described above, the sub-stacks of the stack body SB may be replaced with cell molds through a series of the processes according to FIGS. 4A to 7D. The first layers 12A, the second layers 13, and the third layers 12B may be replaced with the first dielectric layers 19 and the second dielectric layers 20. The fourth layers 14 may become the preliminary horizontal layer 14A through a recess process. The first dielectric layers 19 may be referred to as a trimming target layer.

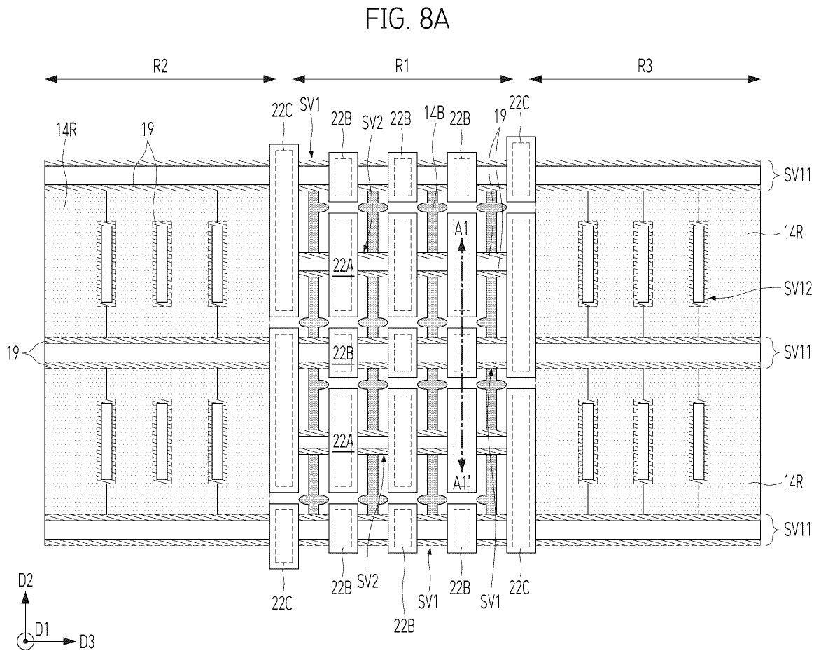

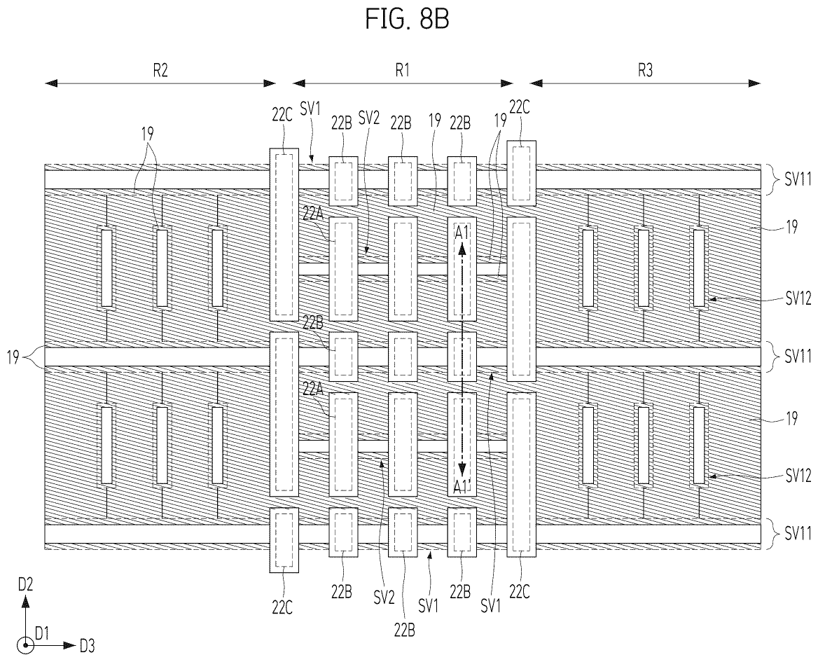

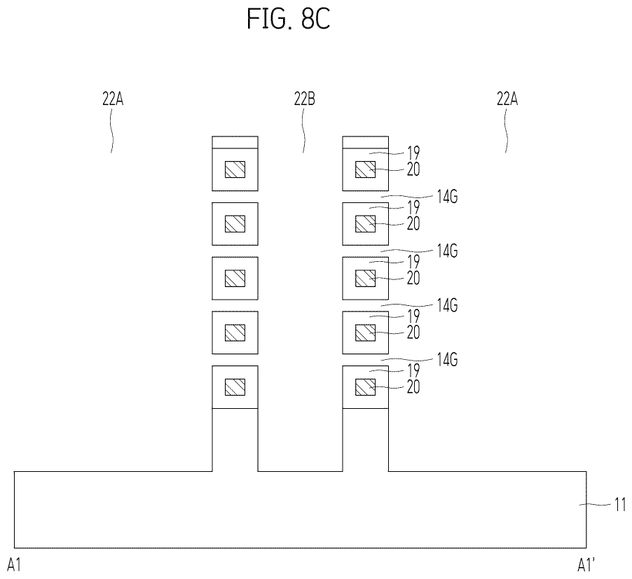

FIGS. 8A and 8B are plan views illustrating a method for forming cell isolation openings 22A and 22B and the horizontal layers 14B, and FIG. 8C is a cross-sectional view taken along a line A1-A1′ shown in FIGS. 8A and 8B. FIG. 8A is a plan view at the level of the horizontal layer 14B, and FIG. 8B is a plan view at the level of the first dielectric layer 19.

Referring to FIGS. 8A to 8C, the first and second sacrificial isolation layers 16A and 16B may be removed to form cell isolation openings 22A and 22B in the first region R1. The cell isolation openings 22A and 22B may include first cell isolation openings 22A and second cell isolation openings 22B. The first cell isolation openings 22A may be formed by removing the first sacrificial isolation layers 16A. The second cell isolation openings 22B may be formed by removing the second sacrificial isolation layers 16B. While the first and second sacrificial isolation layers 16A and 16B are removed, the first and second sacrificial pillar structures SV1 and SV2 may be covered by a mask layer (not shown). The first and second cell isolation openings 22A and 22B may expose the side surfaces of the preliminary horizontal layers 14A and the first dielectric layers 19 in the A1-A1′ direction.

While the first and second sacrificial isolation layers 16A and 16B are removed, the edge sacrificial isolation layers 16C may be removed. As a result, edge isolation openings 22C may be formed at the boundary portion between the first region R1 and the second region R2 and at the boundary portion between the first region R1 and the third region R3.

The side surfaces of the preliminary horizontal layers 14A may be trimmed in the second direction D2 and the third direction D3 through the first and second cell isolation openings 22A and 22B. As a result, trimmed horizontal layers 14B may be formed. Horizontal layer-level gaps 14G may be formed on the side surfaces of the horizontal layers 14B. The horizontal layer-level gaps 14G and the horizontal layers 14B may be disposed between the first dielectric layers 19. The horizontal layers 14B may be referred to as ‘trimmed horizontal layer patterns’.

While the horizontal layers 14B are formed, the surface of the lower structure 11, for example, the bottom surface of the first and second cell isolation openings 22A and 22B, may be expanded.

The horizontal layers 14B may be disposed between the first sacrificial pillar structure SV1 and the second sacrificial pillar structure SV2 in the second direction D2. From the perspective of a top view, the horizontal layers 14B may have a cross-shape. The horizontal layers 14B may have a cross shape whose size is smaller than the that of the preliminary horizontal layers 14A. The preliminary horizontal layers 14A may have a shape in which a plurality of cross shapes are merged, and the horizontal layers 14B may have a shape in which the cross shapes are individually separated in the third direction D3. A horizontal layer-level gap 14G may be formed between the horizontal layers 14B that are disposed in the third direction D3. The first and second sacrificial pillar structures SV1 and SV2 may be disposed between the horizontal layers 14B in the second direction D2.

The side surfaces of the preliminary horizontal layers 14A may be trimmed in the second direction D2 and the third direction D3 through the edge isolation openings 22C. As a result, trimmed horizontal layers 14B may be formed in the first region R1, and pad-level horizontal layers 14R may be formed in the second region R2. The pad-level horizontal layers 14R and the horizontal layers 14B may be spaced apart from each other. The pad-level horizontal layers 14R may be referred to as pad level semiconductor layers.

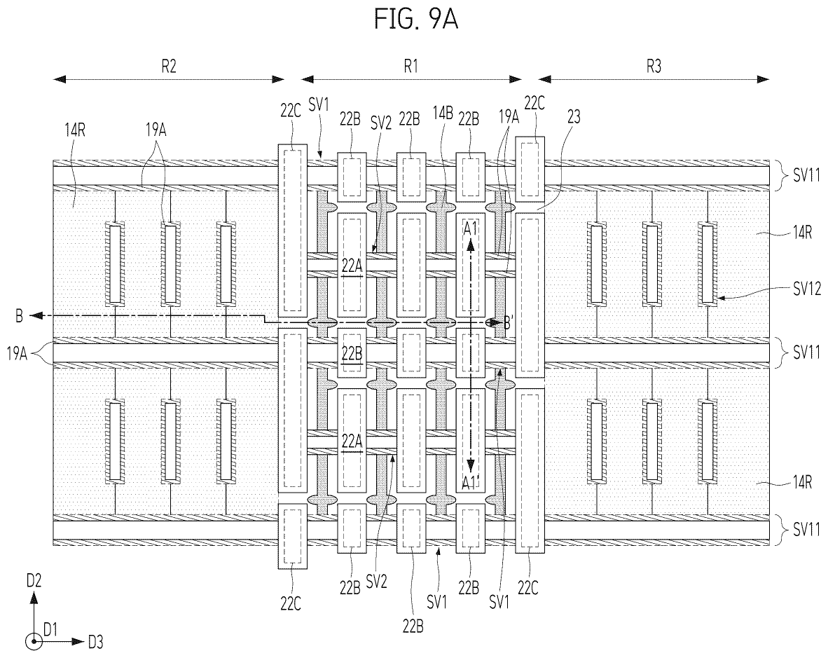

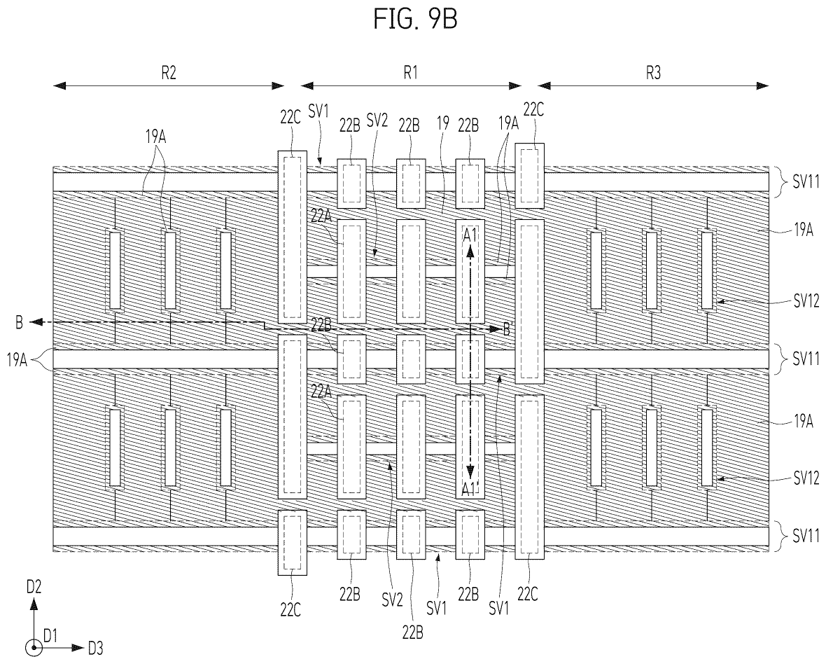

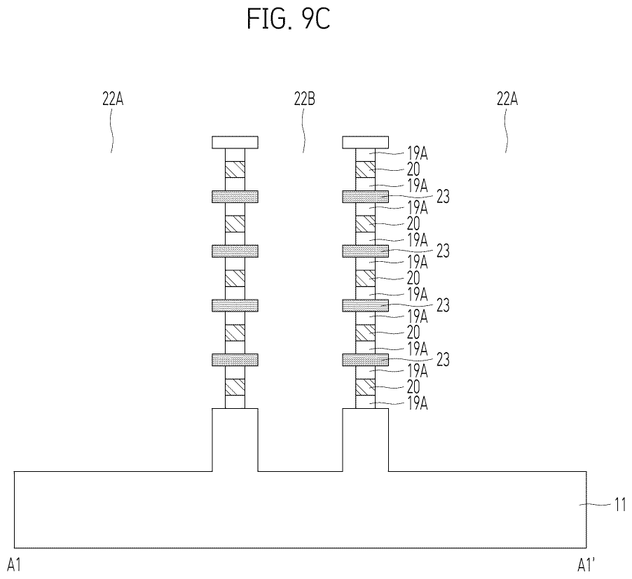

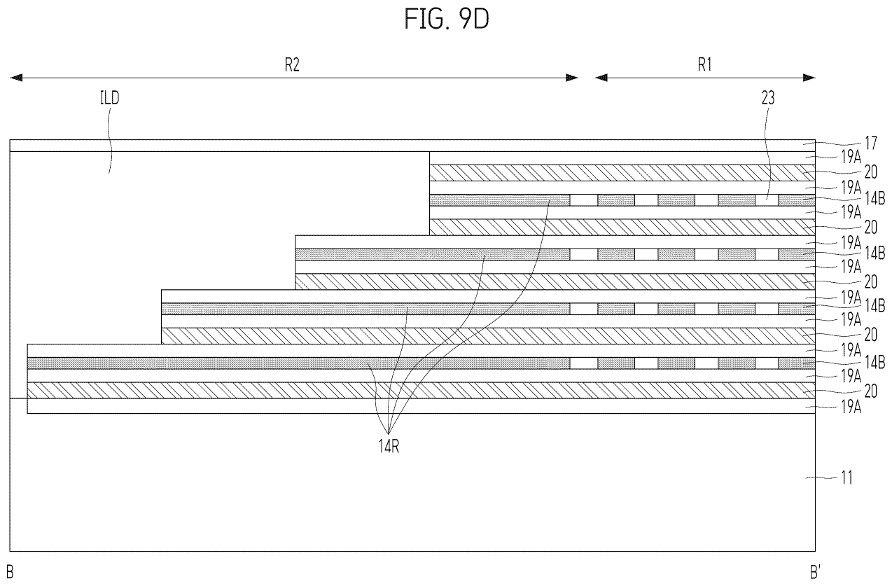

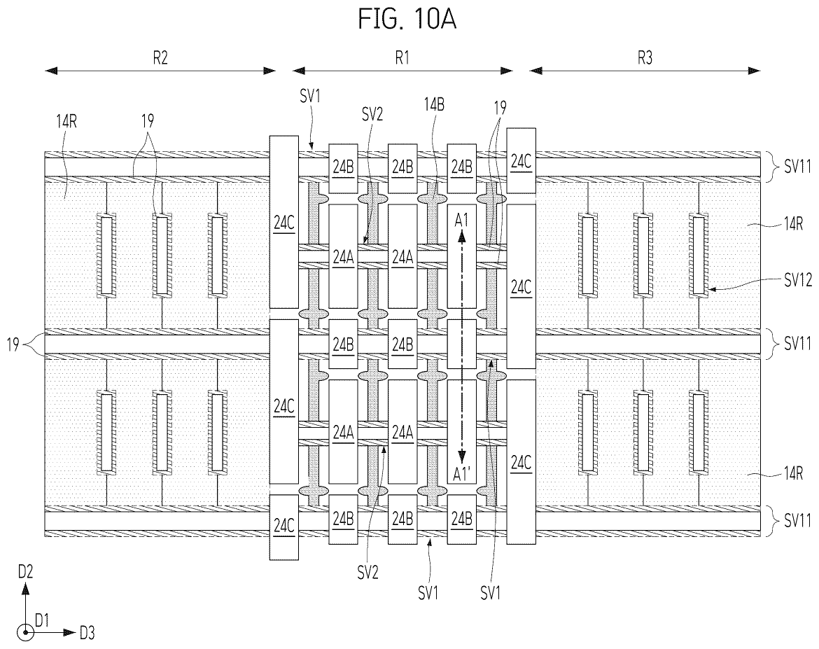

FIGS. 9A and 9B are plan views illustrating a method for forming horizontal layer-level spacers 23 and the first dielectric layers 19A, and FIG. 9C is a cross-sectional view taken along a line A1-A1′ shown in FIGS. 9A and 9B. FIG. 9D is a cross-sectional view taken along a line B-B′ shown in FIG. 9A. FIG. 9A is a plan view at the level of the horizontal layer 14B, and FIG. 9B is a plan view at the level of the first dielectric layer 19A.

Referring to FIGS. 9A to 9D, horizontal layer-level spacers 23 may be formed on the side surfaces of the horizontal layers 14B. Forming the horizontal layer-level spacers 23 may include forming a spacer material on the side surfaces of the horizontal layers 14B and etching the spacer material. The horizontal layer-level spacers 23 may include a dielectric material, for example, silicon oxide. The horizontal layer-level spacers 23 may fill the horizontal layer-level gaps 14G and may separate the horizontal layers 14B disposed in the third direction D3 from each other.

A portion of the first dielectric layers 19 may be trimmed horizontally through the first and second cell isolation openings 22A and 22B. After the trimming process, the first dielectric layers 19 may remain as indicated by a reference numeral ‘19A’. Accordingly, from the perspective of the line A1-A1′, a pair of the first dielectric layers 19A may be disposed between the horizontal layers 14B, and a second dielectric layer 20 may be disposed between the first dielectric layers 19A of the pair.

According to FIGS. 9A to 9D, the width of the first dielectric layers 19A in the third direction D3 may be greater than the width of the horizontal layers 14B between the first cell isolation openings 22A and between the second cell isolation openings 22B. To sum up, the trimming depth of the first dielectric layers 19 in the third direction D3 may be smaller than the trimming depth of the preliminary horizontal layers 14A.

A pair of the first dielectric layers 19A may vertically overlap with one horizontal layer 14B. The trimmed first dielectric layers 19A may be referred to as trimmed first dielectric layers.

Referring back to FIG. 9D, the horizontal layers 14B may be disposed in the first region R1, and the pad-level horizontal layers 14R may be disposed in the second and third regions R2 and R3. The pad-level horizontal layers 14R may be vertically stacked in a staircase structure, and the horizontal lengths of the pad-level horizontal layers 14R may be different from each other.

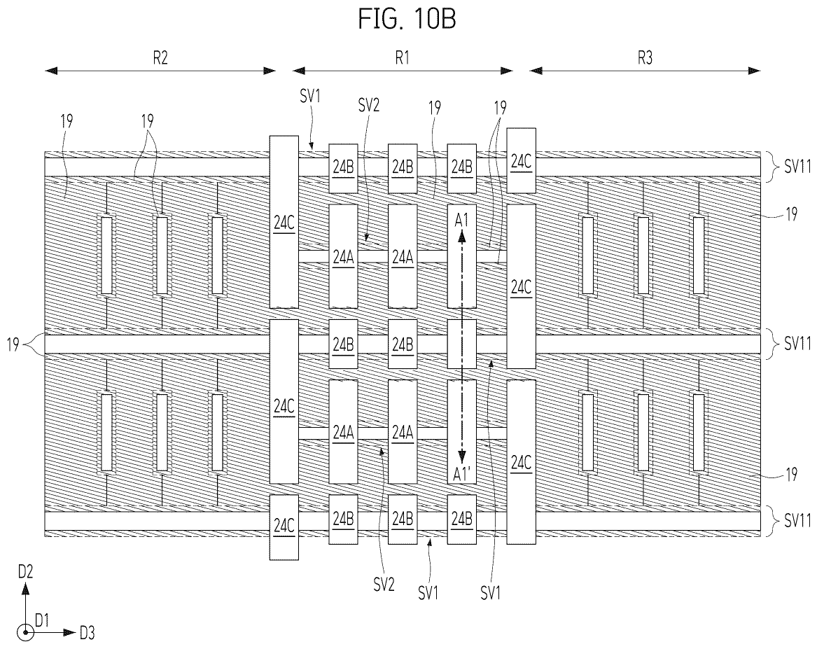

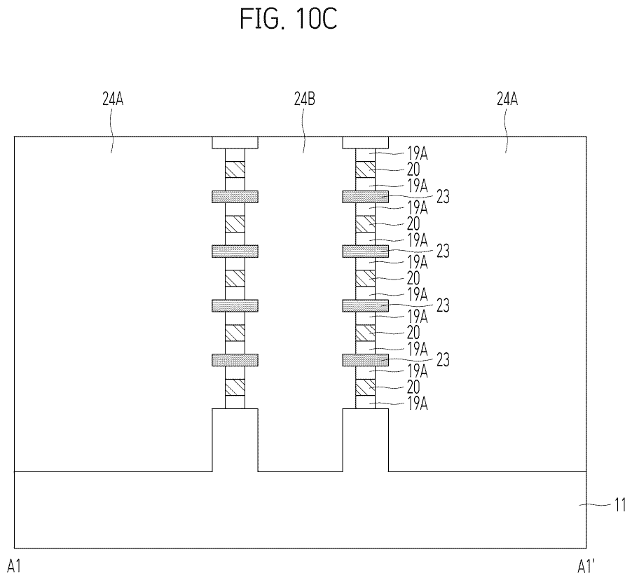

FIGS. 10A and 10B are plan views illustrating a method for forming cell isolation layers 24A and 24B, and FIG. 10C is a cross-sectional view taken along a line A1-A1′ shown in FIGS. 10A and 10B. FIG. 10A is a plan view at the level of the horizontal layer 14B illustrating a method for forming the cell isolation layers 24A and 24B, and FIG. 10B is a plan view at the level of the first dielectric layer 19A illustrating a method for forming the cell isolation layers 24A and 24B.

Referring to FIGS. 10A to 10C, cell isolation layers 24A and 24B may be formed to fill the first and second cell isolation openings 22A and 22B. The cell isolation layers 24A and 24B may include first cell isolation layers 24A and second cell isolation layers 24B. The first cell isolation layers 24A and the second cell isolation layers 24B may include the same material. The first cell isolation layers 24A and the second cell isolation layers 24B may be formed of a dielectric material. For example, the first cell isolation layers 24A and the second cell isolation layers 24B may include, for example, silicon oxide, silicon nitride, silicon carbon oxide, silicon carbon nitride, or a combination thereof. From the perspective of a top view, the outermost material of the first cell isolation layers 24A and the second cell isolation layers 24B may include, for example, silicon oxide.

Forming the first cell isolation layers 24A and the second cell isolation layers 24B may include forming a cell isolation material filling the cell isolation openings 22A and 22B and planarizing the cell isolation material and the uppermost first dielectric layer 19A to expose the surface of the hard mask layer pattern 17. The first cell isolation layers 24A and the second cell isolation layers 24B may have different sizes or different volumes. The first cell isolation layers 24A and the second cell isolation layers 24B may include a dual structure of silicon oxide and silicon carbon oxide. For example, silicon carbon oxide may be deposited after silicon oxide is deposited. According to another embodiment of the present disclosure, the first and second cell isolation layers 24A and 24B may include an embedded air gap, and the embedded air gap may be provided while silicon carbon oxide is deposited. The second sacrificial pillar structure SV2 may be disposed between the first cell isolation layers 24A in the third direction D3, and the first sacrificial pillar structure SV1 may be disposed between the second cell isolation layers 24B in the third direction D3. The first and second cell isolation layers 24A and 24B may extend vertically in the first direction D1.

The first and second cell isolation layers 24A and 24B may correspond to the cell isolation layers ISOA and ISOB that are illustrated in FIGS. 2A and 2B. Each of the first and second cell isolation layers 24A and 24B may include a stack of a cell isolation liner layer and a cell isolation gap-fill layer. The cell isolation liner layers may include, for example, silicon oxide, and the cell isolation gap-fill layers may include silicon carbon oxide. According to another embodiment of the present disclosure, the first and second cell isolation layers 24A and 24B may include an embedded air gap, and the embedded air gap may be provided while the cell isolation gap-fill layers are formed.

The first and second cell isolation layers 24A and 24B and the first dielectric layers 19A may directly contact each other. The horizontal layer-level spacer 23 may be disposed between the horizontal layers 14B and the first and second cell isolation layers 24A and 24B.

Subsequently, a method for forming memory cells, that is, vertical conductive lines, horizontal layers, double horizontal conductive lines, and data storage elements, will be described.

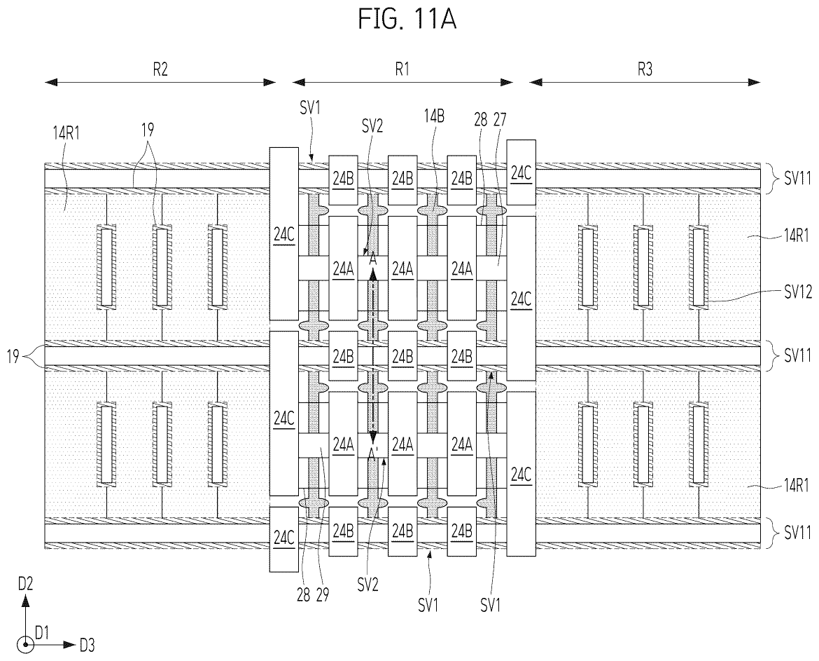

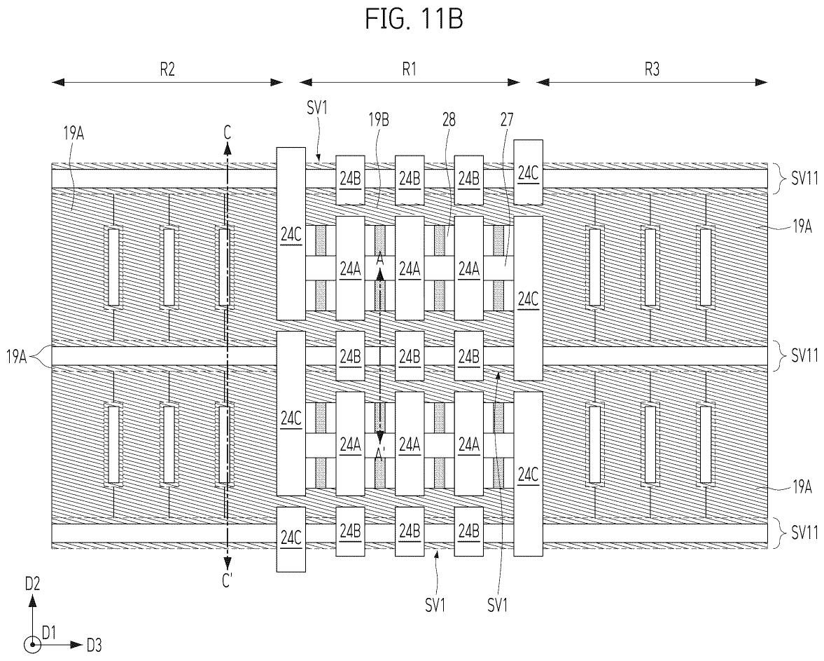

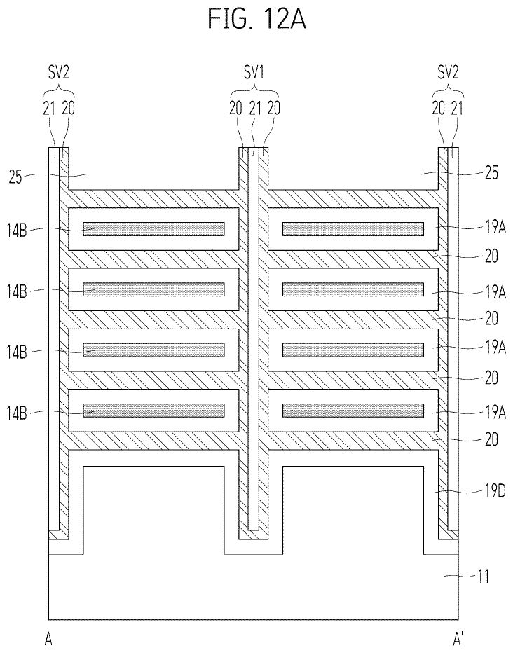

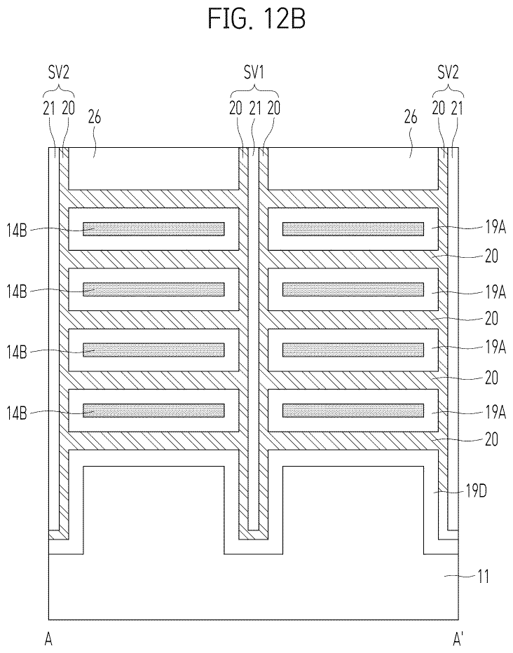

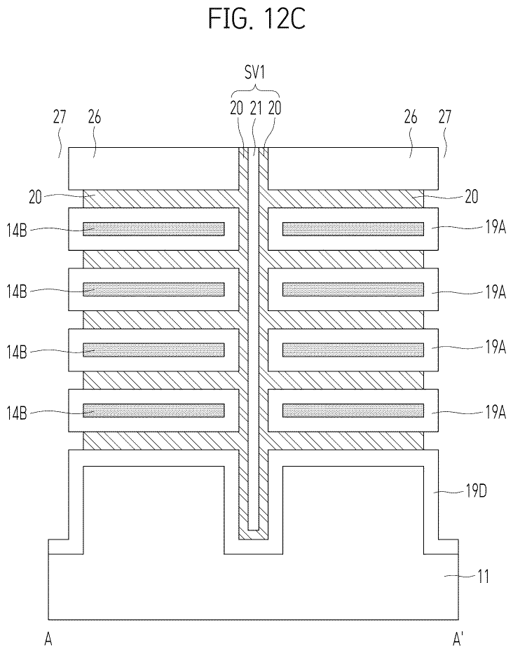

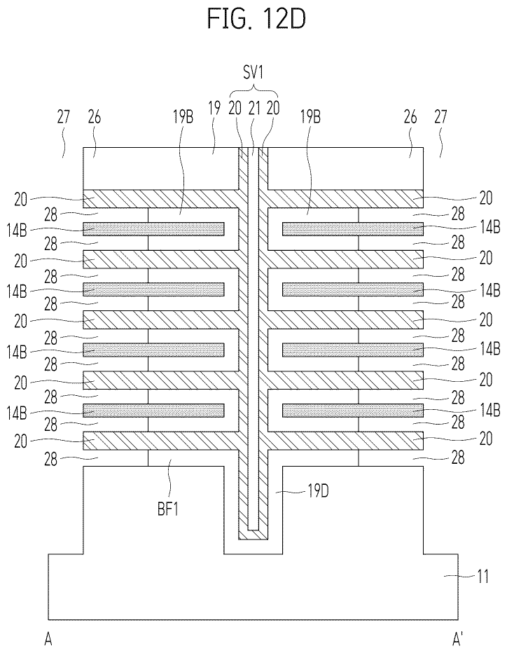

FIGS. 11A and 11B are plan views illustrating a method for forming the first dielectric layer patterns 19B, and FIGS. 12A to 12D are cross-sectional views taken along a line A-A′ shown in FIGS. 11A and 11B illustrating a method for forming the first dielectric layer patterns 19B. FIG. 11A is a plan view at the level of the horizontal layer 14B, and FIG. 11B is a plan view at the level of the first dielectric layer pattern 19B.

First, referring to FIG. 12A, the hard mask layer 17 and the uppermost-level first dielectric layer 19A may be removed to form the hard mask layer-level recess 25.

Referring to FIG. 12B, a top dielectric layer 26 that fills the hard mask layer-level recess 25 may be formed. The top dielectric layer 26 may include, for example, silicon oxide.

Referring to FIG. 12C, initial vertical openings 27 may be formed by removing the first sacrificial pillar structures SV1.

Subsequently, the second dielectric layers 20 may be horizontally recessed. As a result, the first dielectric layers 19A and the dummy dielectric layer 19D may be exposed through the initial vertical openings 27.

Referring to FIG. 12D, the first dielectric layers 19A and the dummy dielectric layer 19D may be selectively recessed horizontally. As a result, the first dielectric layer patterns 19B and dielectric layer-level recesses 28 may be formed. Portions of the horizontal layers 14B may be exposed by the dielectric layer-level recesses 28.

The first dielectric layer patterns 19B and the dielectric layer-level recesses 28 may be formed in the first region R1. The first dielectric layers 19A may remain in the second and third regions R2 and R3.

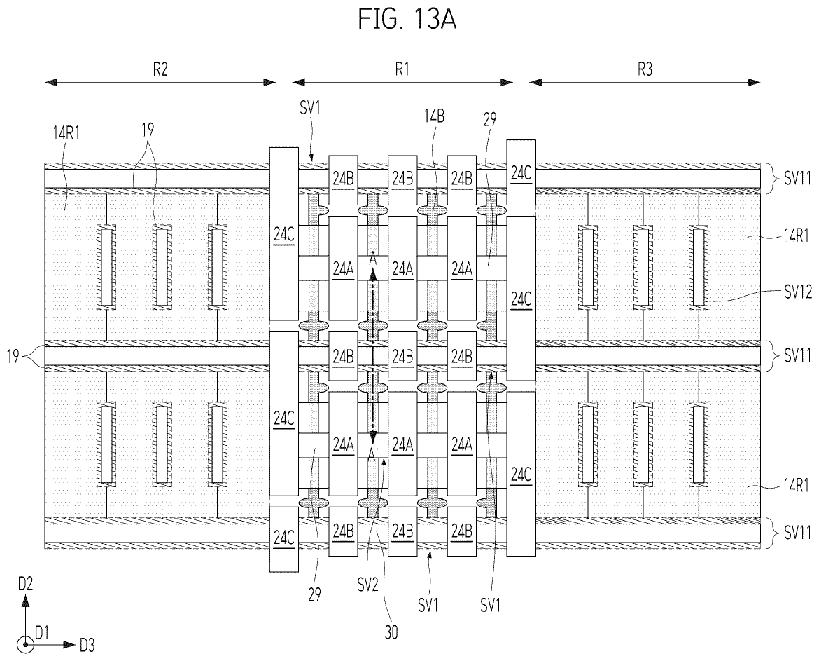

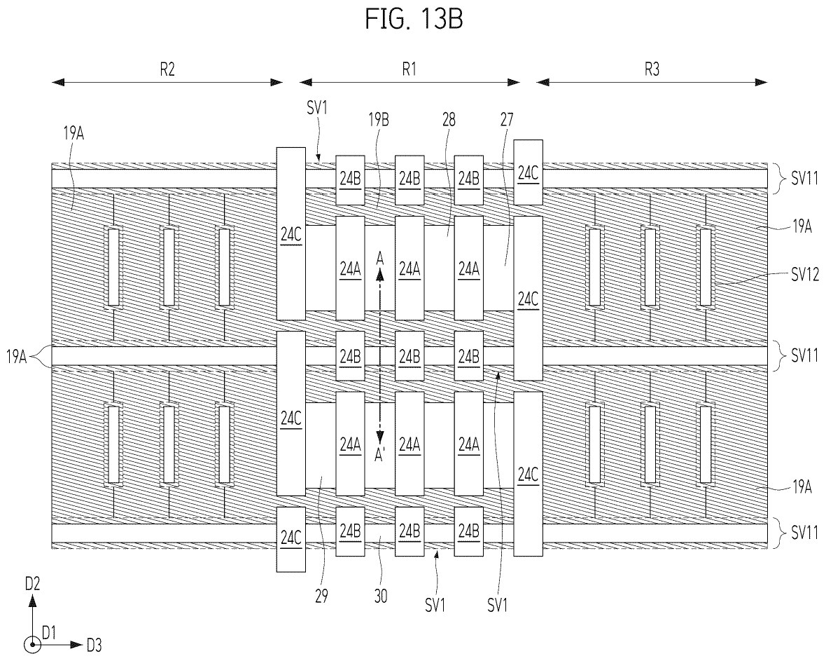

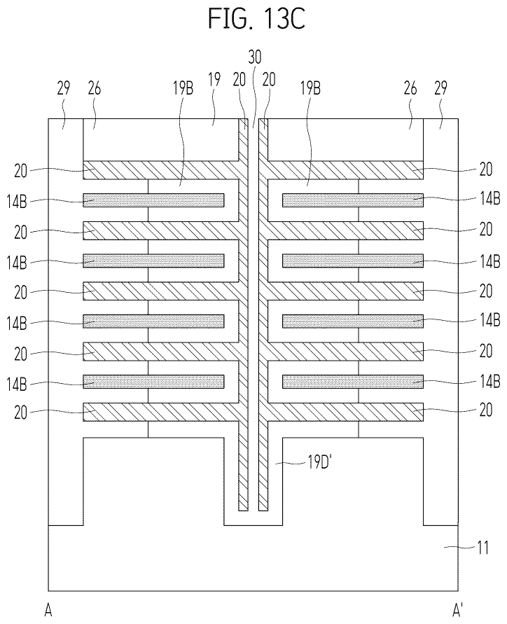

FIGS. 13A and 13B are plan views illustrating a method for forming vertical sacrificial structures 29 and a vertical level path 30, and FIG. 13C is a cross-sectional view taken along a line A-A′ shown in FIGS. 13A and 13B. FIG. 13A is a plan view at the level of the horizontal layer 14B, and FIG. 13B is a plan view at the level of the first dielectric layer pattern 19B.

Referring to FIGS. 13A to 13C, vertical sacrificial structures 29 may be formed to fill the dielectric layer-level recesses 28 and the initial vertical openings 27. The vertical sacrificial structures 29 may include a sacrificial material. The vertical sacrificial structures 29 may include, for example, silicon oxide, silicon nitride, titanium nitride, amorphous carbon, or a combination thereof.

The vertical level path 30 may be formed by removing the sacrificial pillars 21 of the first sacrificial pillar structure SV1.

The lower-level gap 19D′ may be formed by removing the dummy dielectric layer 19D below the vertical level path 30.

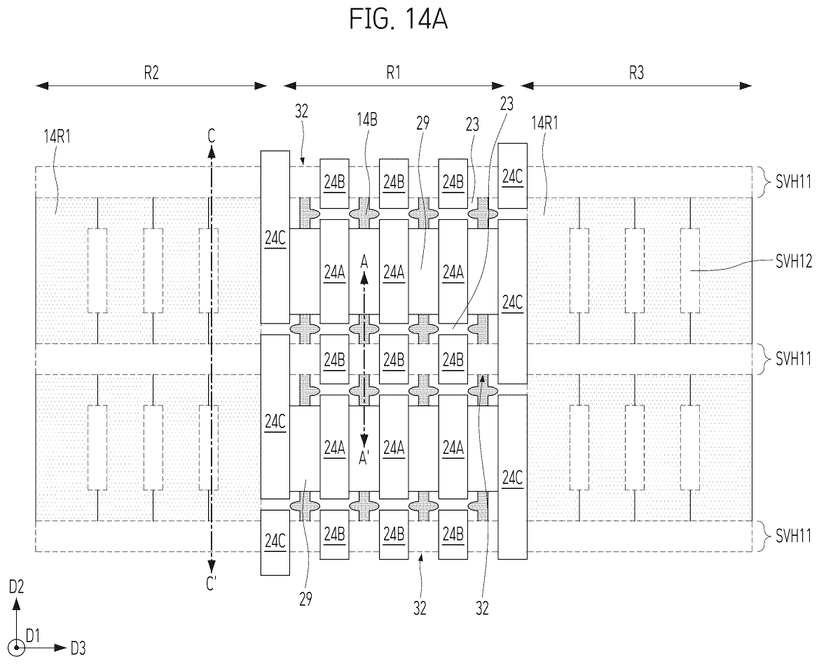

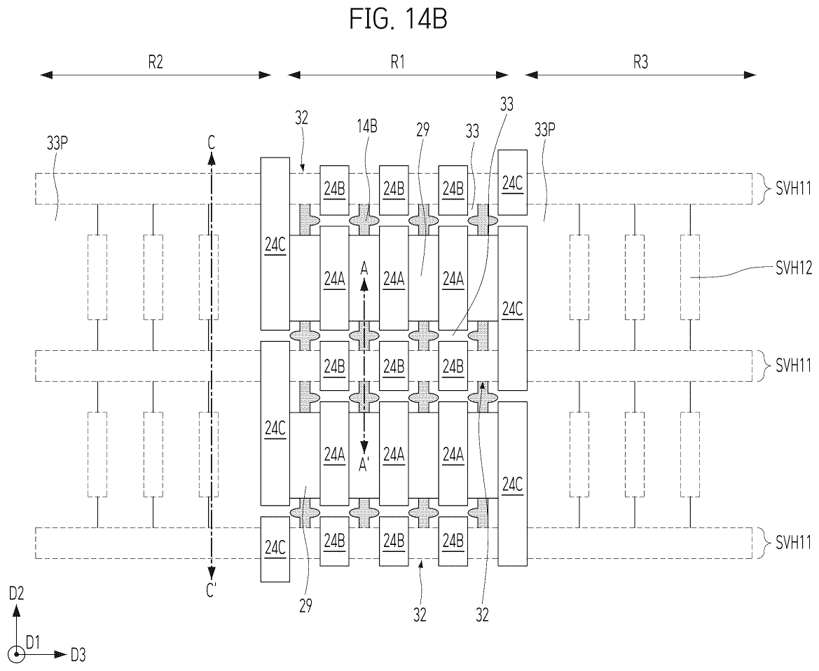

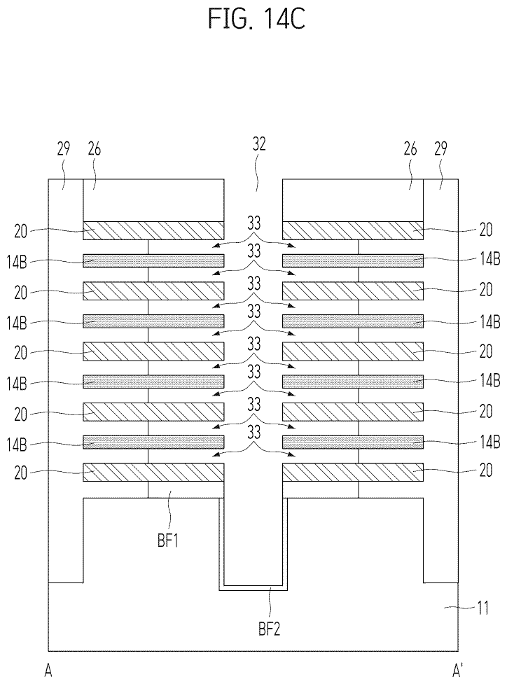

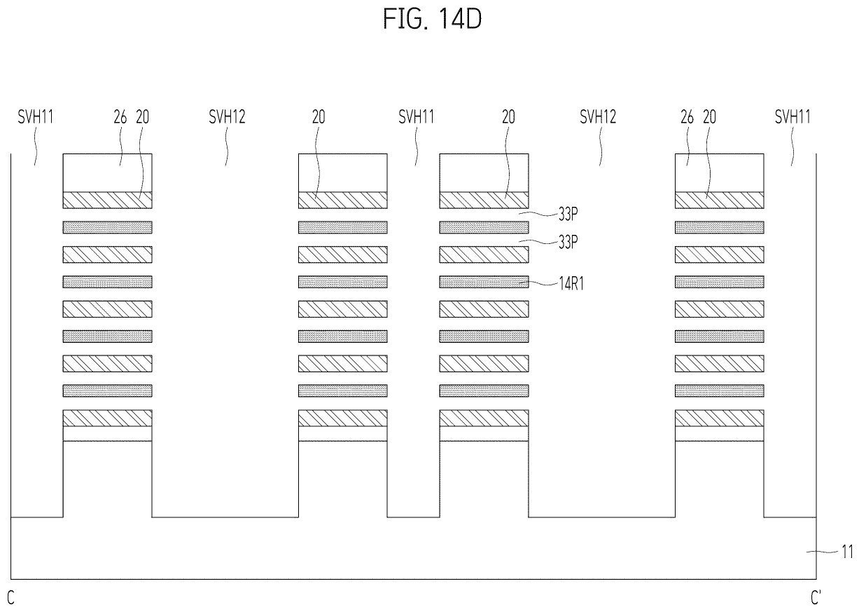

FIGS. 14A and 14B are plan views illustrating a method for forming horizontal-level recesses 33, and FIG. 14C is a cross-sectional view taken along a line A-A′ shown in FIGS. 14A and 14B. FIG. 14D is a cross-sectional view taken along a line C-C′ shown in FIGS. 14A and 14B. FIG. 14A is a plan view at the level of the horizontal layer 14B, and FIG. 14B is a plan view at the level of the horizontal-level recesses 33.

Referring to FIGS. 14A to 14D, first hole-shaped vertical openings 32 may be formed in the first region R1 by cutting the second dielectric layers 20 through the vertical level path 30. While the first hole-shaped vertical openings 32 are formed, isolation trenches SVH11 and SVH12 may be formed in the second and third regions R2 and R3.

A first passivation layer BF1 may be formed to fill the lower-level gap 19D′. The first passivation layer BF1 may include, for example, silicon oxide. Forming the first passivation layer BF1 may include depositing silicon oxide to fill the lower-level gap 19D′ and etching the silicon oxide.

A second passivation layer BF2 may be formed in the lower area of the first hole-shaped vertical openings 32. For example, the surface of the lower structure 11 may be oxidized to form the second passivation layer BF2.

To form the horizontal-level recesses 33 in the first region R1, the first dielectric layer patterns 19B may be removed through the first hole-shaped vertical openings 32. Portions of the horizontal layers 14B may be exposed by the horizontal-level recesses 33. The horizontal-level recesses 33 may be disposed between the second dielectric layer 20 and the horizontal layer 14B. Two horizontal-level recesses 33 may face each other with one horizontal layer 14B interposed between them.

To form pad-level recesses 33P in the second and third regions R2 and R3, the first dielectric layer patterns 19B may be removed through the isolation trenches SVH11 and SVH12. The pad-level recesses 33P may expose the top and bottom surfaces of the pad-level horizontal layers 14R1. The pad-level recesses 33P may be disposed between the second dielectric layer 20 and the pad-level horizontal layer 14R1. Two pad-level recesses 33P may face each other with one pad-level horizontal layer 14R1 interposed between them.

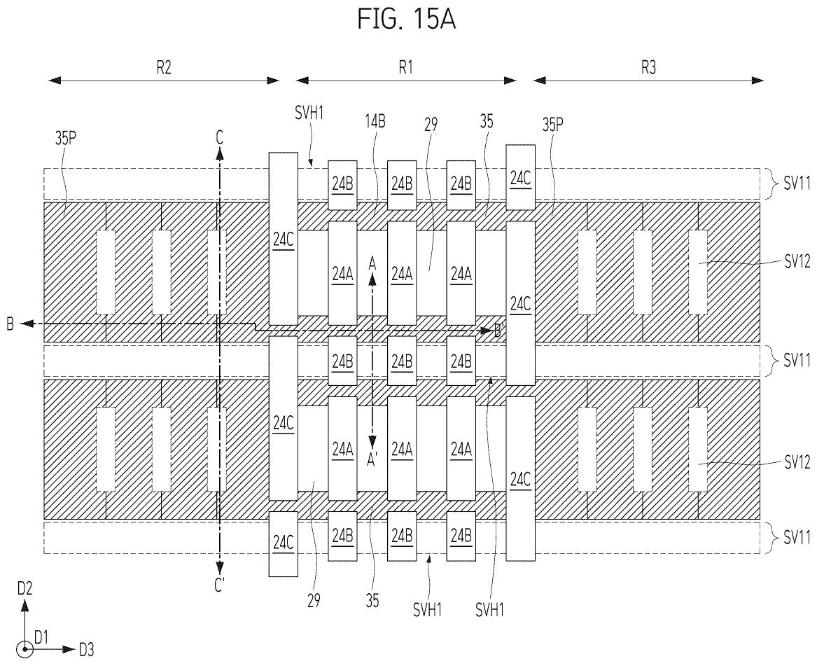

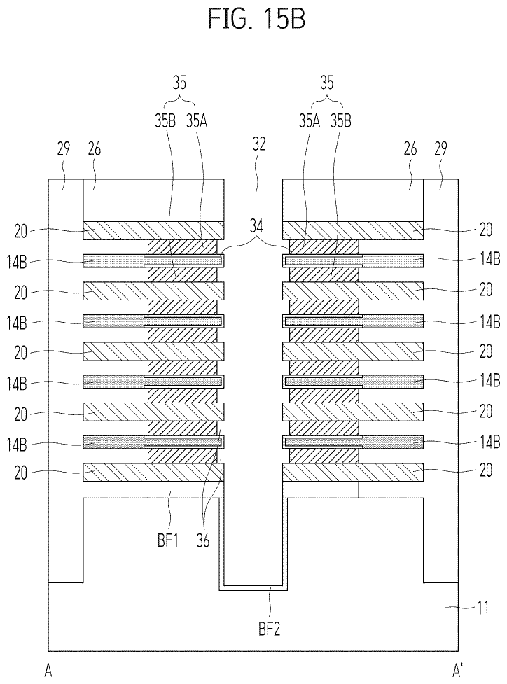

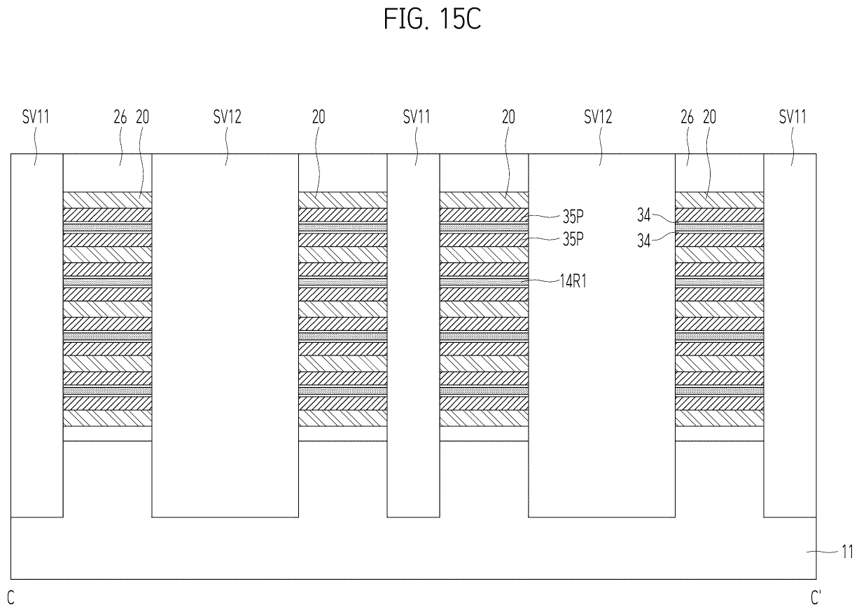

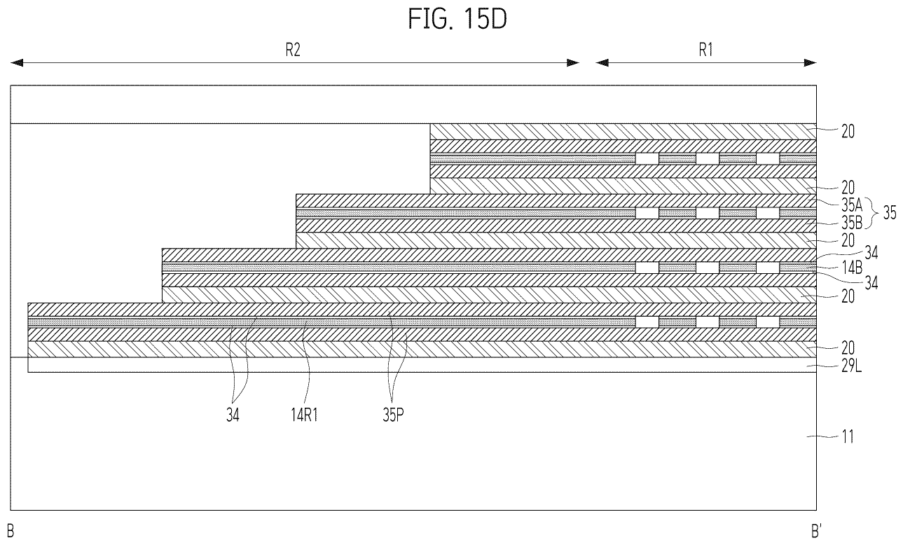

FIG. 15A is a plan view illustrating a method for forming horizontal conductive lines 35, and FIG. 15B is a cross-sectional view taken along a line A-A′ shown in FIG. 15A. FIG. 15C is a cross-sectional view taken along a line C-C′ shown in FIG. 15A. FIG. 15D is a cross-sectional view taken along a line B-B′ shown in FIG. 15A.

Referring to FIGS. 15A to 15D, an inter-level dielectric layer 34 may be formed over the exposed portions of the horizontal layers 14B. The inter-level dielectric layer 34 may be referred to as a gate dielectric layer. The inter-level dielectric layer 34 may correspond to the inter-level dielectric layer GD as illustrated in FIGS. 1A to 3B.

The inter-level dielectric layer 34 may be formed by oxidizing the surfaces of the horizontal layers 14B. According to another embodiment of the present disclosure, the inter-level dielectric layer 34 may be formed by a deposition process of silicon oxide. The inter-level dielectric layer 34 may include, for example, silicon oxide, silicon nitride, a metal oxide, a metal oxynitride, a metal silicate, a high-k material, a ferroelectric material, an anti-ferroelectric material or a combination thereof. The inter-level dielectric layer 34 may include, for example, silicon SiO₂, Si₃N₄, HfO₂, Al₂O₃, ZrO₂, AlON, HfON, HfSiO, HfSiON, or a combination thereof.

A horizontal conductive line 35 filling the horizontal-level recesses 33 may be formed over the inter-level dielectric layer 34. Forming the horizontal conductive line 35 may include depositing a conductive material filling the horizontal-level recesses 33 over the inter-level dielectric layer 34 and etching back the conductive material. The horizontal conductive line 35 may include a pair of first and second horizontal conductive lines 35A and 35B that are facing each other with the horizontal layer 14B between them. The first and second horizontal conductive lines 35A and 35B may include a metal-based material, a semiconductor material, or a combination thereof. The first and second horizontal conductive lines 35A and 35B may include titanium nitride, tungsten, polysilicon, or a combination thereof. For example, the first and second horizontal conductive lines 35A and 35B may include a TiN/W stack in which titanium nitride and tungsten are sequentially stacked. The first and second horizontal conductive lines 35A and 35B may include an N-type work function material or a P-type work function material. The N-type work function material may have a low work function of approximately 4.5 eV or less, and the P-type work function material may have a high work function of approximately 4.5 eV or more.

The horizontal conductive line 35 may correspond to the second conductive line DWL as illustrated in FIGS. 1A to 1D, and the first and second horizontal conductive lines 35A and 35B may correspond to the upper and lower horizontal lines G1 and G2. Referring to FIGS. 1A to 1D, each of the first and second horizontal conductive lines 35A and 35B may have a cross shape and may include a channel overlapping portion WLP and a channel non-overlapping portion NOL.

The horizontal conductive line 35 may be formed in the first region R1 and may extend to be disposed in the second and third regions R2 and R3. The horizontal conductive line 35 may be formed in the horizontal-level recesses 33 in the first region R1 and formed in the pad-level recesses 33P in the second and third regions R2 and R3. The inter-level dielectric layers 34 may also be formed in the first to third regions R1, R2, and R3, respectively.

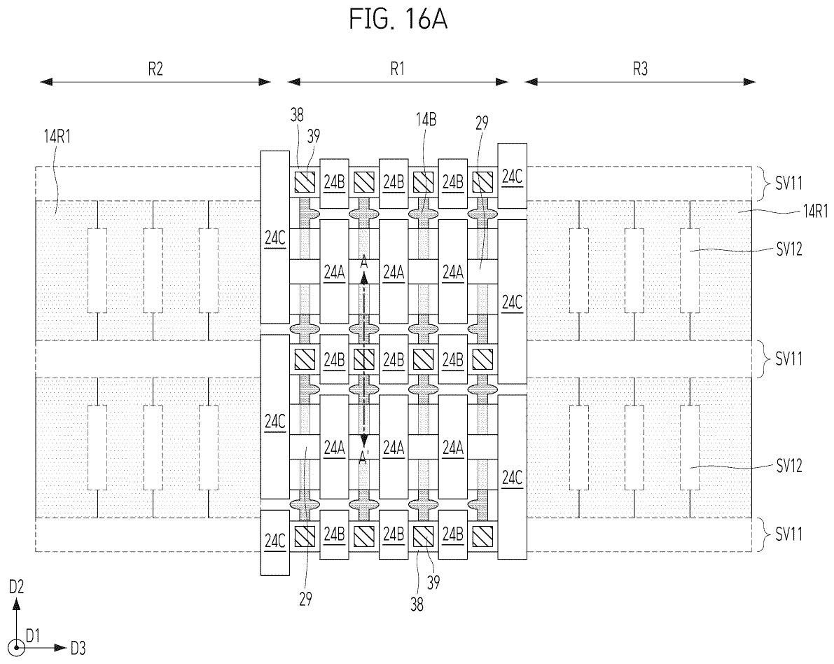

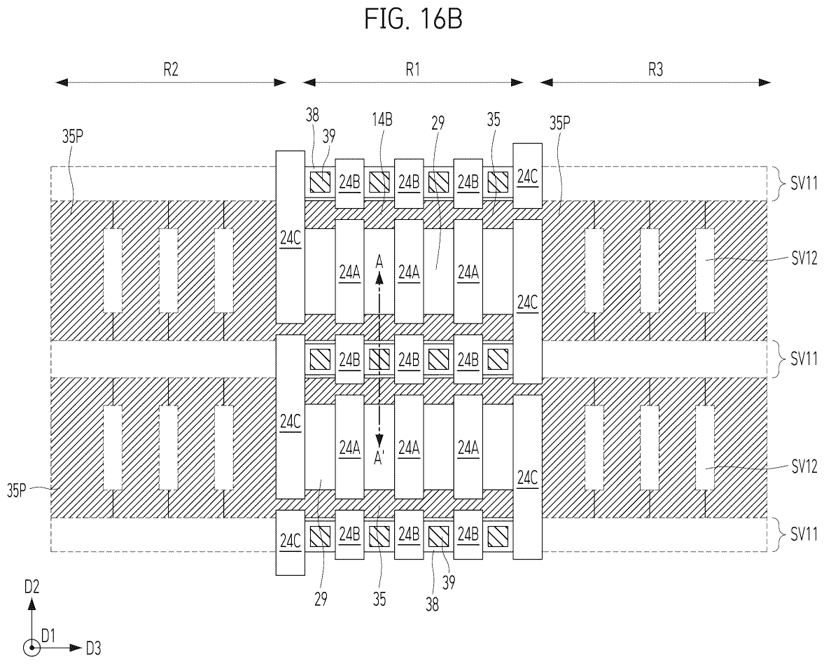

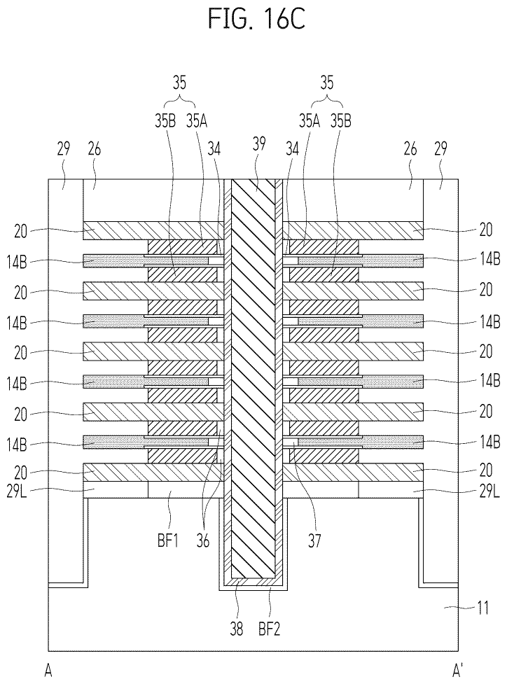

FIGS. 16A and 16B are plan views illustrating a method for forming the vertical conductive lines 39, and FIG. 16C is a cross-sectional view taken along a line A-A′ shown in FIGS. 16A and 16B.

Referring to FIGS. 16A to 16C, a first capping layer 36 may be formed on a first side of the horizontal conductive line 35. The first capping layer 36 may include, for example, silicon oxide, silicon nitride, silicon carbon oxide, an embedded air gap, or a combination thereof. The first capping layer 36 may be formed by depositing a capping material and performing an etch-back process. While the first capping layer 36 is formed or after the first capping layer 36 is formed, a portion of the inter-level dielectric layer 34 may be removed to expose a first edge portion of each of the horizontal layers 14B.

A vertical conductive line 39 coupled to the first edge portion of each of the horizontal layers 14B may be formed. The vertical conductive line 39 may fill the first hole-shaped vertical openings 32. The vertical conductive line 39 may be commonly coupled to the horizontal layers 14B that are disposed in the first direction D1. The vertical conductive lines 39 may include titanium nitride, tungsten, or a combination thereof. The vertical conductive line 39 may be referred to as a bit line or a vertical bit line.

Before the vertical conductive line 39 is formed, the first doped region 37 and the first contact node 38 may be formed. The first doped region 37 may be formed in the first edge portion of the horizontal layers 14B. Forming the first doped region 37 may include depositing polysilicon that is doped with an N-type impurity, performing a heat treatment, and removing the doped polysilicon. The first doped region 37 may include an impurity that is diffused from the doped polysilicon. According to another embodiment of the present disclosure, the first doped region 37 may be formed by a doping process with an impurity.

The first contact node 38 may include doped polysilicon. The first doped region 37 may include an impurity diffused from the first contact node 38. A metal silicide layer may be further formed between the vertical conductive line 39 and the first contact node 38.

The vertical conductive line 39 may correspond to the first conductive line BL as illustrated in FIGS. 1A to 3C.

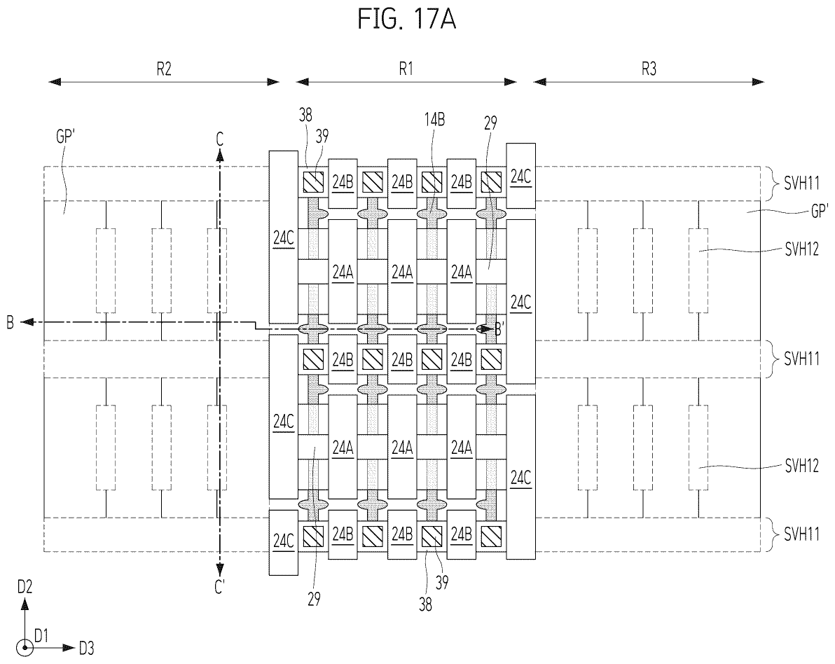

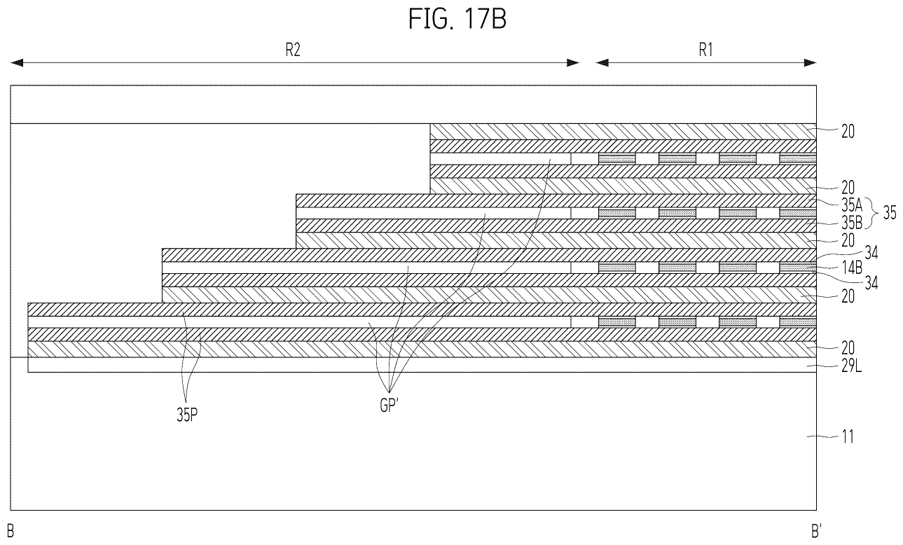

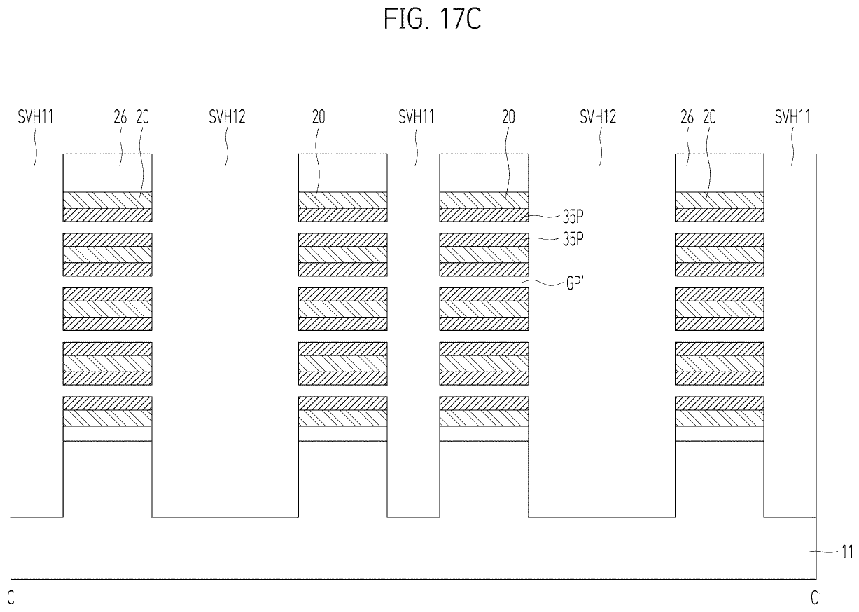

FIG. 17A is a plan view illustrating a method for forming a pad-level gap GP′, and FIG. 17B is a cross-sectional view taken along a line B-B′ shown in FIG. 17A. FIG. 17C is a cross-sectional view taken along a line C-C′ shown in FIG. 17A.

Referring to FIGS. 17A to 17C, a horizontal layer pattern 14B and a horizontal conductive line 35 may be formed in the first region R1, and the pad-level horizontal layer 14R1 and the horizontal conductive line 35 may be formed in the second and third regions R2 and R3. The first and second horizontal conductive lines 35A and 35B of the horizontal conductive line 35 may face each other vertically with the horizontal layer pattern 14B interposed between them and may include edge portions extending to overlap with the pad-level horizontal layer 14R1.

The edge portions of the horizontal conductive line 35 may be disposed in the second and third regions R2 and R3.

The edge portions of the horizontal conductive line 35 may be formed in a staircase structure, as illustrated in FIG. 5C.

All of the pad-level horizontal layer 14R1 may be removed from the second and third regions R2 and R3. As a result, the pad-level gap GP′ may be formed between the horizontal conductive lines 35. The pad-level gaps GP′ may be disposed in a staircase structure.

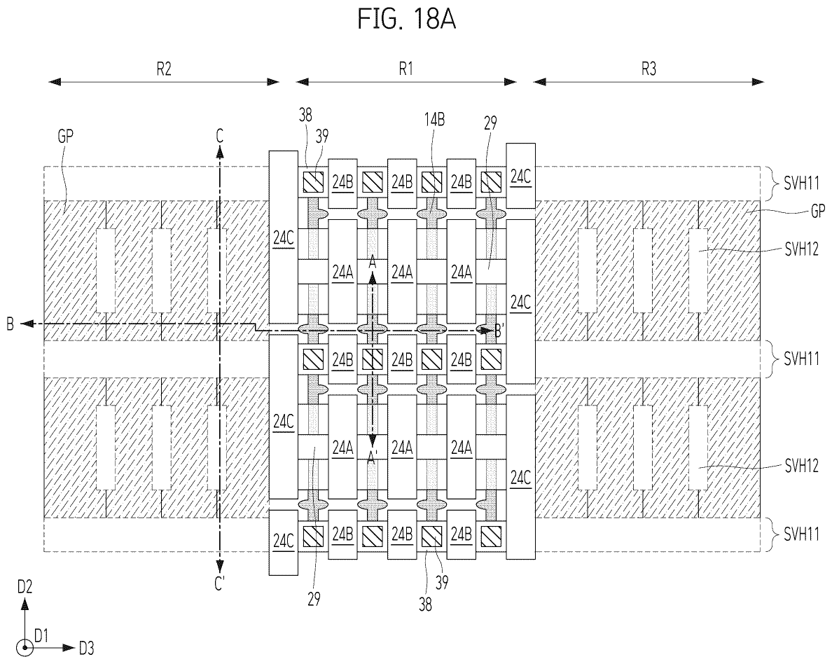

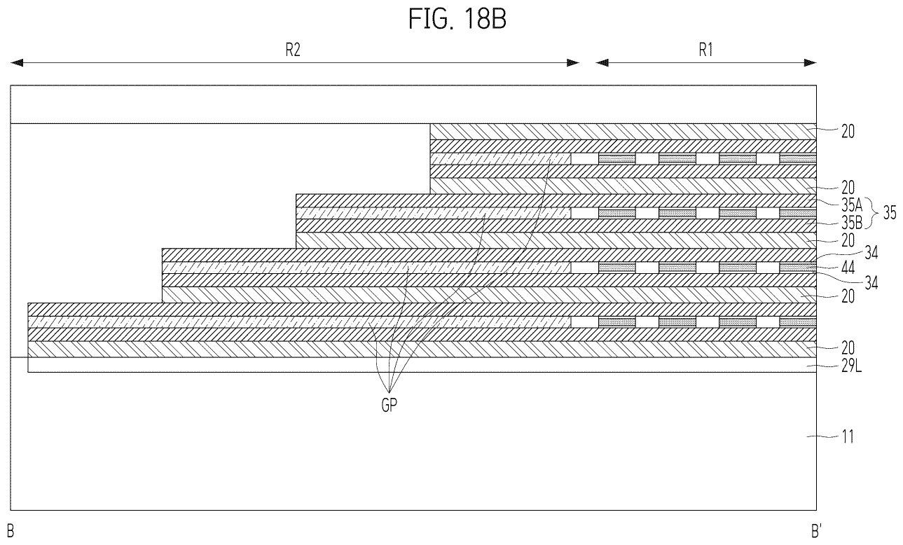

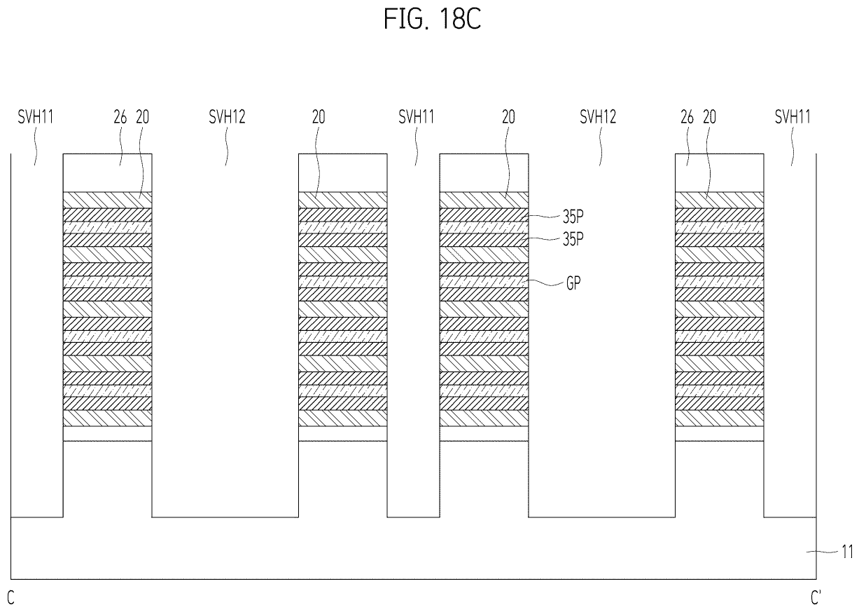

FIG. 18A is a plan view illustrating a method for forming a pad portion GP, and FIG. 18B is a cross-sectional view taken along a line B-B′ shown in FIG. 18A. FIG. 18C is a cross-sectional view taken along a line C-C′ shown in FIG. 18A.

Referring to FIGS. 18A to 18C, a pad portion GP may be formed to fill the pad-level gaps GP′. The pad portion GP may couple the first horizontal conductive line G1 and the second horizontal conductive line G2 to each other. The pad portion GP, the first horizontal conductive line G1, and the second horizontal conductive line G2 may include the same material.

The process of forming the pad portion GP described above may be performed after the vertical conductive line 39 is formed. For example, after the vertical conductive line 39 is formed in the first region R1, exposing the second and third regions R2 and R3 and masking the first region R1, removing the pad-level horizontal layer 14R1 from the second and third regions R2 and R3, and forming the pad portion GP may be sequentially performed.

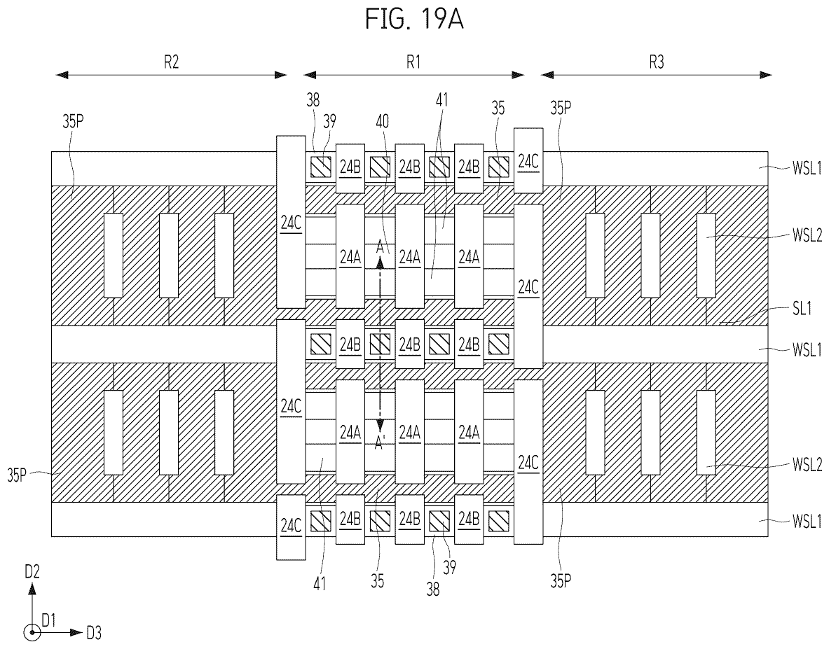

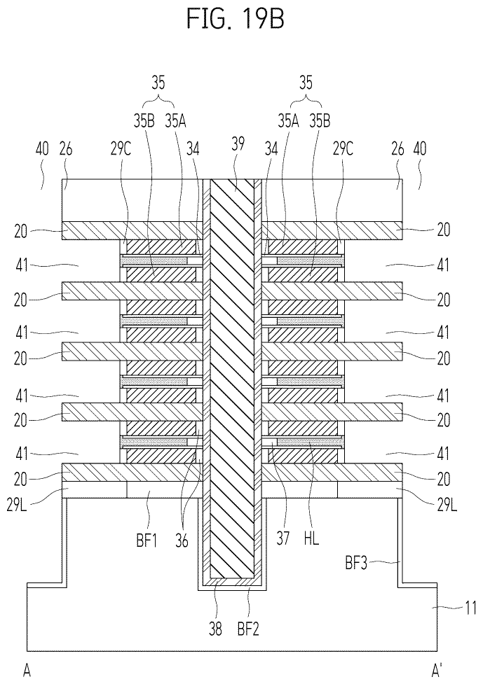

FIG. 19A is a plan view illustrating a method for forming storage openings 41, and FIG. 19B is a cross-sectional view taken along a line A-A′ shown in FIG. 19A.

Referring to FIGS. 19A and 19B, a portion of the vertical sacrificial structure 29 may be removed to form second hole-shaped vertical openings 40. First side surfaces of the horizontal layers 14B, that is, a second edge portion, may be exposed by the second hole-shaped vertical openings 40. After the second hole-shaped vertical openings 40 are formed, a portion of the vertical sacrificial structure 29 may be removed to form a lowermost level dielectric layer 29L on a side of the first passivation layers BF1.

A third passivation layer BF3 may be formed on the surface of the lower structure 11. The third passivation layer BF3 may include, for example, silicon oxide.

The second edge portion of the horizontal layers 14B may be horizontally recessed in the second direction D2. As a result, the horizontal layers remain as indicated by reference symbol ‘HL’.

After the horizontal layers HL are formed, the vertical sacrificial structures 29 may be selectively recessed to form the second capping layers 29C. The second capping layers 29C may include, for example, silicon oxide, silicon nitride, or a combination thereof.

After the second capping layers 29C are formed, storage openings 41 extending horizontally from the second hole-shaped vertical openings 40 may be formed. The storage openings 41 may be referred to as capacitor openings.

The horizontal layers HL may include a first edge and a second edge. The first edge may refer to a portion that is coupled to the first contact node 38 and the vertical conductive line 39, and the second edge may refer to a portion exposed by the storage openings 41.

The storage openings 41 may be disposed between the second dielectric layers 20. The second capping layers 29C may be disposed on the upper and lower portions of the horizontal layers HL, respectively.

As described above, forming the horizontal layers HL and the storage openings 41 may include forming the second hole-shaped vertical openings 40, recessing the horizontal layers 14B, and forming a second capping layer 29C.

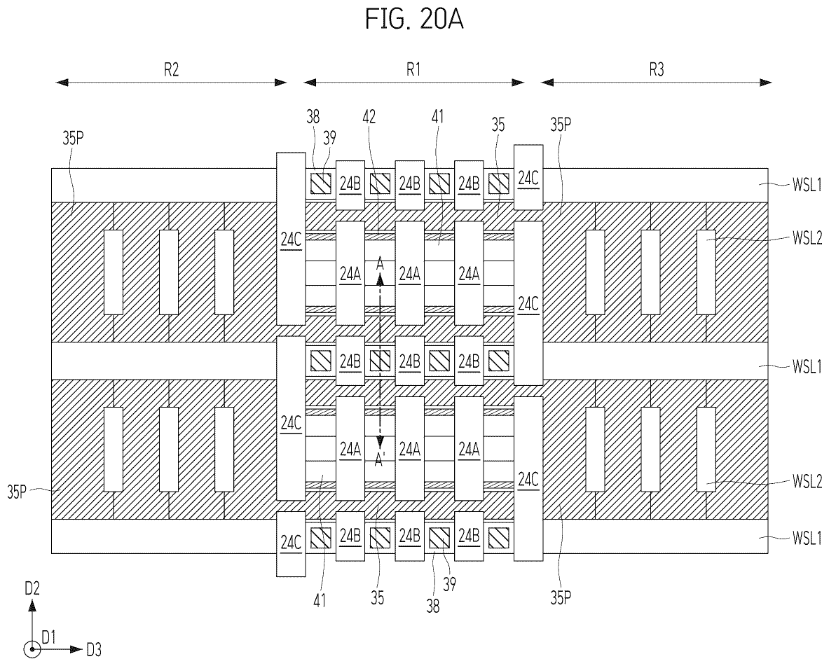

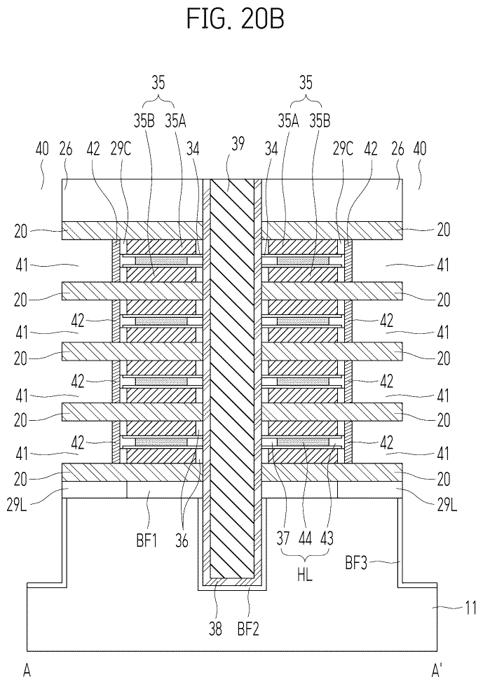

FIG. 20A is a plan view illustrating a method for forming the second contact nodes 42, and FIG. 20B is a cross-sectional view taken along a line A-A′ shown in FIG. 20A.

Referring to FIGS. 20A and 20B, second doped regions 43 may be formed in the second edges of the horizontal layers HL, respectively. Forming the second doped regions 43 may include depositing polysilicon that is doped with an N-type impurity, performing a heat treatment, and removing the doped polysilicon. The second doped regions 43 may include an impurity diffused from the doped polysilicon. According to another embodiment of the present disclosure, after the heat treatment is performed, the doped polysilicon may remain.

The second contact nodes 42 may be formed over the second edges of the horizontal layers HL. The second contact nodes 42 may include doped polysilicon. The second doped regions 43 may include an impurity diffused from the second contact nodes 42.

Each horizontal layer HL may include a first doped region 37, a second doped region 43, and a channel 44 that are arranged horizontally in the second direction D2. The channels 44 may be defined between the first doped regions 37 and the second doped regions 43. The channels 44 may vertically overlap with the horizontal conductive lines 35. As illustrated in FIGS. 1A to 1D, the horizontal layers HL may have a cross shape, and the channels 44 may also have a cross shape.

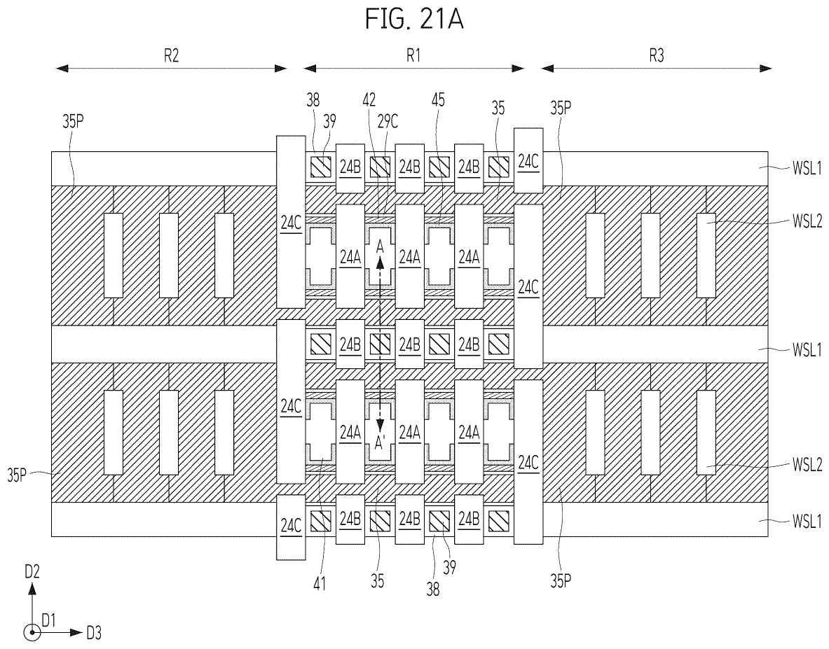

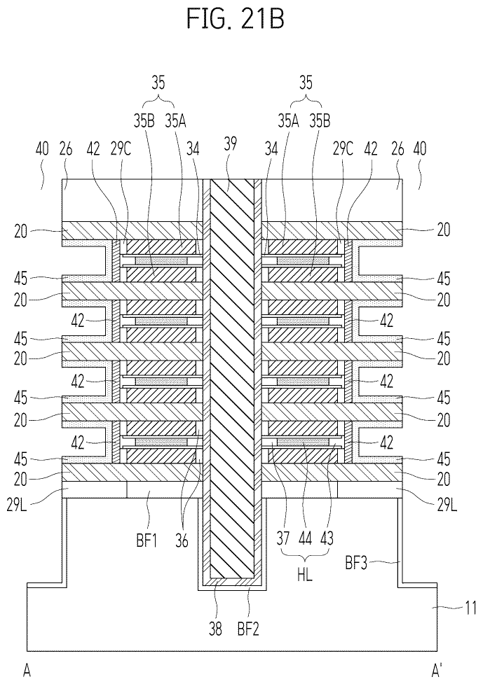

FIG. 21A is a plan view illustrating a method for forming first electrodes 45, and FIG. 21B is a cross-sectional view taken along a line A-A′ shown in FIG. 21A.

Referring to FIGS. 21A and 21B, the first electrodes 45 of the data storage element may be formed over the second contact nodes 42. The first electrodes 45 may have a horizontally oriented cylindrical shape. The first electrodes 45 may be respectively disposed in the storage openings 41. The first electrodes 45 disposed adjacent to each other in the second direction D2 may be disposed spaced apart from each other by the second hole-shaped vertical openings 40. The first electrodes 45 disposed adjacent to each other in the third direction D3 may be spaced apart from each other by the second cell isolation layers 24A.

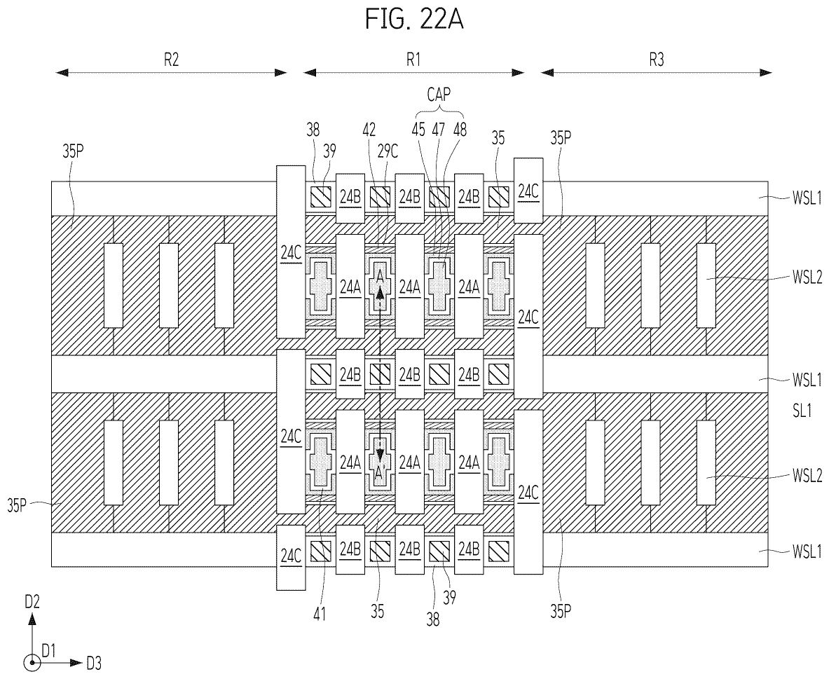

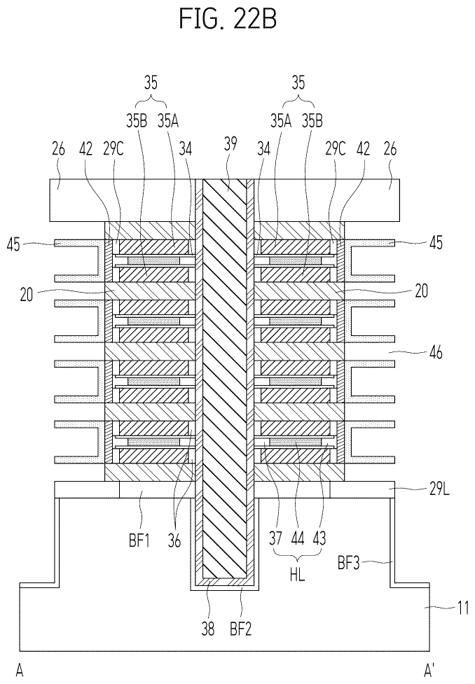

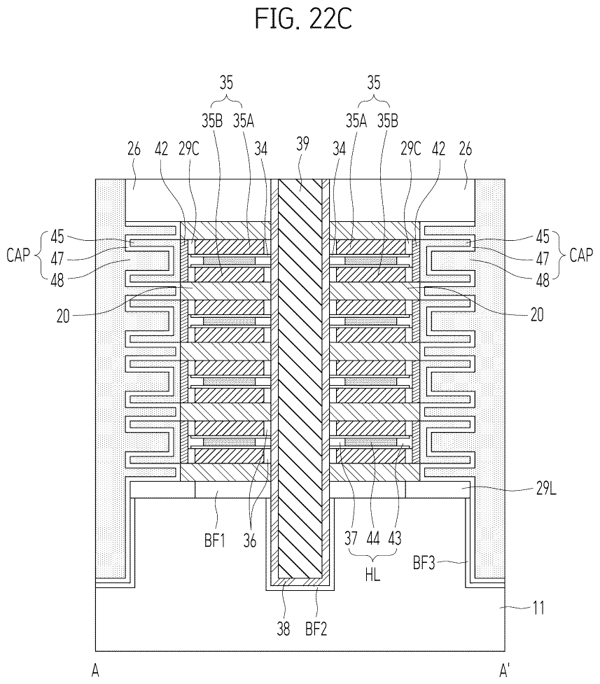

FIG. 22A is a plan view illustrating a method for forming a dielectric layer 47 and a second electrode 48, and FIGS. 22B and 22C are cross-sectional views taken along a line A-A′ shown in FIG. 22A.

Referring to FIGS. 22A and 22B, the second dielectric layers may be horizontally recessed (see a reference numeral ‘46’). As a result, the outer walls of the first electrodes 45 may be exposed. The recessed second dielectric layers 20 may correspond to the inter-cell dielectric layer IL as illustrated in FIG. 3B.

Referring to FIGS. 22A and 22C, the dielectric layer 47 and the second electrode 48 may be sequentially formed over the first electrodes 45. The first electrode 45, the dielectric layer 47 and the second electrode 48 may be a data storage element CAP.

Each first electrode 45 may include an inner space and a plurality of outer surfaces, and the inner space of the first electrode may include a plurality of inner surfaces. The outer surfaces of the first electrode 45 may include a vertical outer surface and a plurality of horizontal outer surfaces. The vertical outer surface of the first electrode 45 may extend vertically in the first direction D1, and the horizontal outer surfaces of the first electrode 45 may extend horizontally in the second direction D2 or the third direction D3. The inner space of the first electrode 45 may be a three-dimensional space. The dielectric layer 47 may conformally cover the inner and outer surfaces of the first electrode 45. The second electrode 48 may be disposed in the inner space of the first electrode 45 over the dielectric layer 47. Some of the outer surfaces of the first electrode may be electrically connected to the second doped region 43 of the horizontal layer HL.

The first electrode 45 may have a cylindrical shape. The cylindrical shape of the first electrode 45 may include cylindrical inner surfaces and cylindrical outer surfaces. Some of the cylindrical outer surfaces of the first electrode 45 may be electrically connected to the second doped region 43 of the horizontal layer HL. The dielectric layer 47 and the second electrode 48 may be disposed on the cylindrical inner surfaces of the first electrode 45. The second electrode 48 may extend vertically in the first direction D1.

The first electrode 45 and the second electrode 48 may include a metal, a noble metal, a metal nitride, a conductive metal oxide, a conductive noble metal oxide, a metal carbide, a metal silicide, or a combination thereof. For example, the first electrode 45 and the second electrode 48 may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof.

The second electrode 48 may include a combination of a metal-based material and a silicon-based material. For example, the second electrode 48 may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material that fills the inner space of the first electrode 45, and titanium nitride (TiN) may serve as the second electrode 48 of the data storage element CAP, and tungsten nitride may be a low-resistance material.

The dielectric layer 47 may be referred to as a capacitor dielectric layer or a memory layer. The dielectric layer 47 may include, for example, silicon oxide, silicon nitride, a high-k material, a ferroelectric material, an anti-ferroelectric material, or a combination thereof. The dielectric layer 47 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). The dielectric layer 45 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, an HA (HfO₂/Al₂O₃) stack, an HAH (HfO₂/Al₂O₃/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack.

According to another embodiment of the present disclosure, an interface control layer for reducing the leakage current may be further formed between the first electrode 45 and the dielectric layer 47. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 45 and the dielectric layer 47.

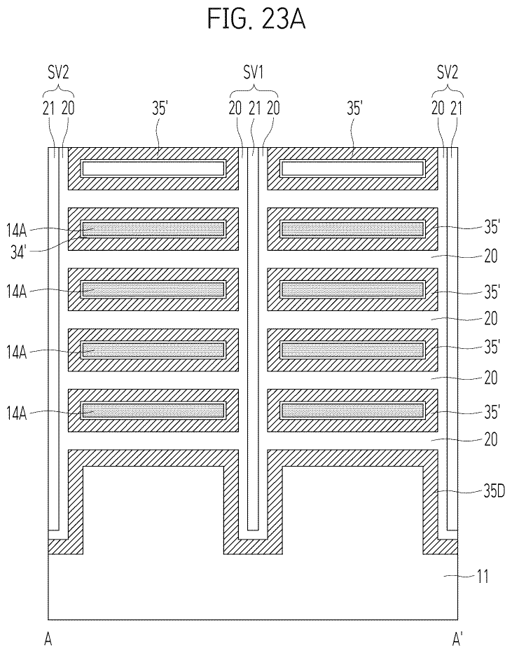

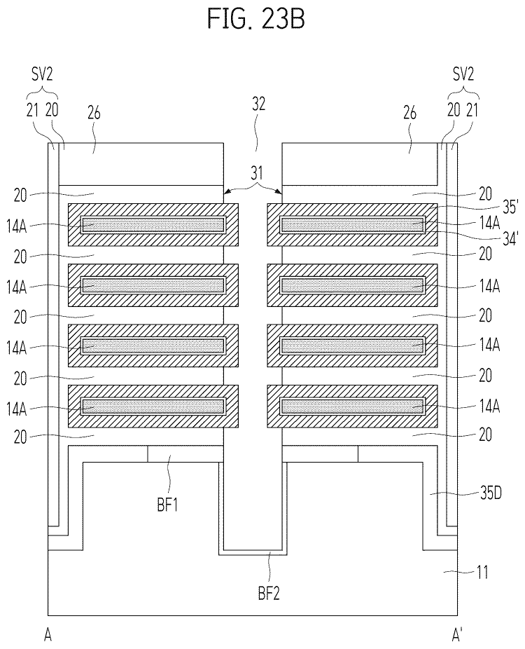

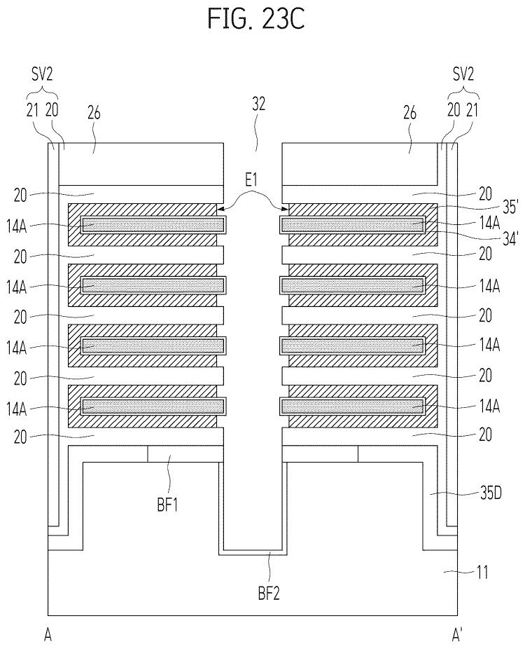

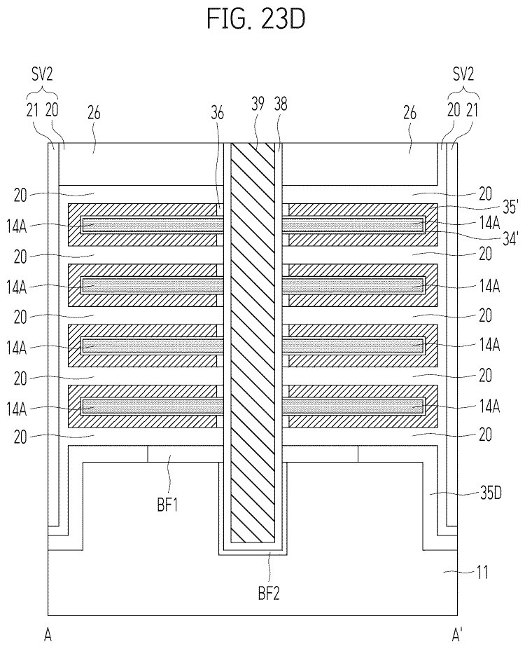

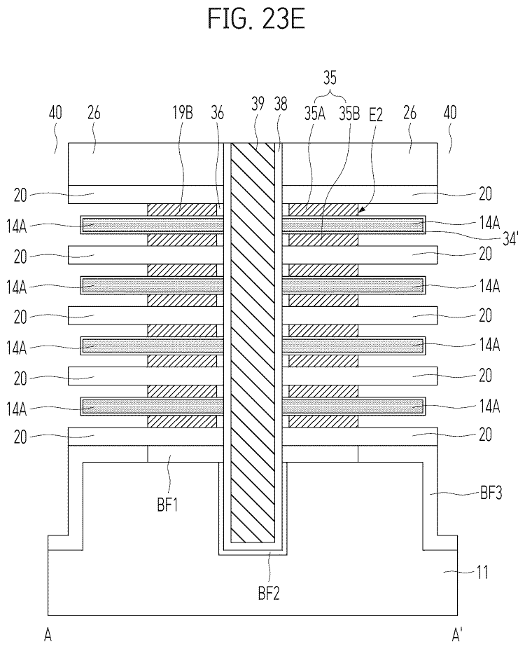

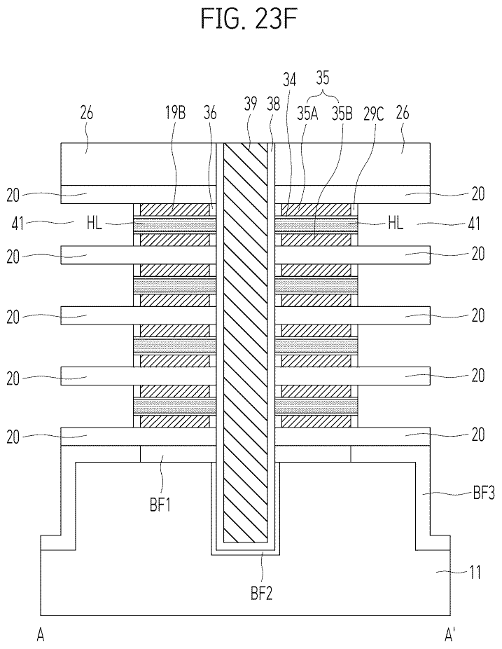

FIGS. 23A to 23F are cross-sectional views illustrating a method for fabricating a semiconductor device in accordance with another embodiment of the present disclosure.

Preliminary horizontal layers 14A may be formed by performing a series of the processes as illustrated in FIGS. 4A to 7B.

Subsequently, referring to FIG. 23A, inter-level dielectric layers 34′ that fully cover the preliminary horizontal layers 14A may be formed.

Subsequently, conductive layers 35′ respectively surrounding the preliminary horizontal layers 14A may be formed over the inter-level dielectric layers 34′. While the conductive layers 35′ are formed, dummy conductive layers 35D may be formed on the surface of the lower structure 11.

Second dielectric layer 20 may be formed over the conductive layers 35′. Sacrificial pillars 21 may be formed over the second dielectric layers 20. The second dielectric layers 20 and the sacrificial pillars 21 may form first and second sacrificial pillar structures SV1 and SV2.

Referring to FIG. 23B, to form a first hole-shaped vertical opening 32, the sacrificial pillar 21 of the first sacrificial pillar structure SV1 may be removed. Subsequently, the second dielectric layers 20 may be cut (see a reference numeral ‘31’).

After a portion of the dummy conductive layer 35D′ is removed, a first buffer layer BF1 may be formed. The first buffer layer BF1 may include, for example, silicon oxide. The surface of the lower structure 11 may be oxidized to form a second buffer layer BF2.

Referring to FIG. 23C, a first recess process may be performed onto the conductive layers 35′.

Referring to FIG. 23D, a first contact node 38 and a vertical conductive line 39 may be formed to fill the first hole-shaped vertical opening 32. Before the first contact node 38 is formed, a first capping layer 36 may be formed. After the first capping layer 36 is formed, a first doped region 37 may be formed.

Referring to FIG. 23E, in order to form second hole-shaped vertical openings 40, a portion of each of the second sacrificial pillar structures SV2 may be removed.

Subsequently, a second recess process may be performed onto the conductive layers 35′.

As a result, a double horizontal conductive line 35 of the first horizontal conductive line 35A and the second horizontal conductive line 35B may be formed. A first edge portion of the horizontal conductive line 35 may be defined by the first recess process (see FIG. 23C), and a second edge portion E2 of the horizontal conductive line 35 may be defined by the second recess process (see FIG. 23E).

Referring to FIG. 23F, a second capping layer 29C may be formed. The second capping layer 29C may be disposed between the second dielectric layers 20. The second capping layers 29C may be disposed on second side surfaces of the first and second horizontal conductive lines 35A and 35B.

The horizontal layer patterns 14B may be horizontally recessed. As a result, a horizontal layer HL may be formed. Storage openings 41 may be formed by forming the second capping layer 29C and the horizontal layer HL. The storage openings 41 may expose the end of a second side of the horizontal layer HL. The storage openings 41 may be disposed between the second dielectric layers 20.

Subsequently, referring to in FIGS. 21A to 22B, a data storage element CAP including a second doped region 43, a second contact node 42, a first electrode 45, a dielectric layer 47, and a second electrode 48 may be formed.

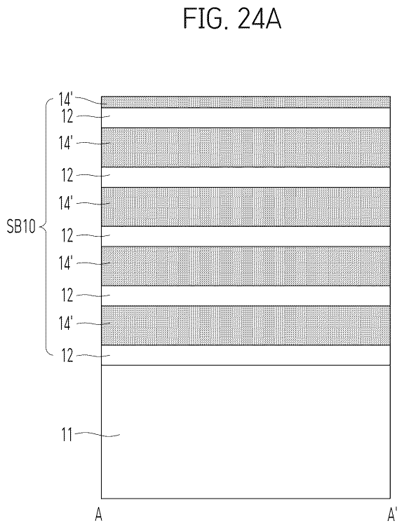

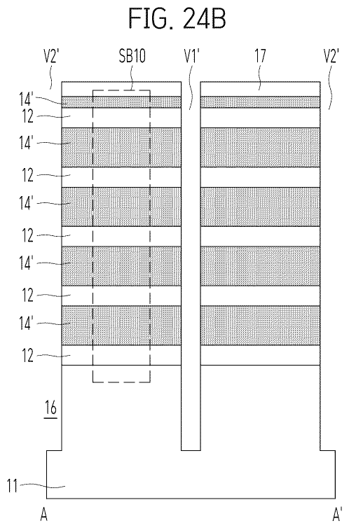

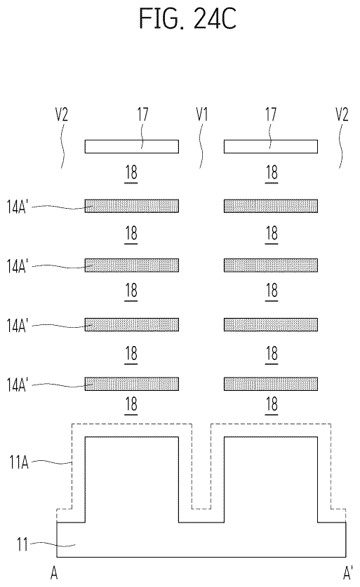

FIGS. 24A to 24C are cross-sectional views illustrating a method for fabricating a semiconductor device in accordance with another embodiment of the present disclosure.

Referring to FIG. 24A, a stack body SB10 may be formed over the lower structure 11. The stack body SB10 may include an alternating stack of first semiconductor layers and second semiconductor layers. For example, the alternating stack may include a plurality of silicon germanium layers 12 and a plurality of mono crystalline silicon layers 14′ that are alternately stacked by an epitaxial growth process. The silicon germanium layers 12 may be sacrificial layers, and the mono crystalline silicon layers 14′ may be recess target layers. The silicon germanium layers 12 may correspond to the first layers 12A or the third layers 12B of FIG. 4B, and the mono crystalline silicon layers 14′ may correspond to the fourth layers 14 of FIG. 4B. Unlike the stack body SB of FIG. 4B, the stack body SB10 may include an alternating stack of the silicon germanium layers 12 and the mono crystalline silicon layers 14′.

Subsequently, a series of the processes illustrated in FIGS. 4A to 5C may be performed. For example, sacrificial isolation openings 15A and 15B and sacrificial isolation layers 16A and 16B may be formed in the stack body SB10. The sacrificial isolation layers 16A and 16B may include a blocking layer L1, a sacrificial liner layer L2, a sacrificial gap-fill layer L3, and a sacrificial capping layer L4.

Subsequently, referring to FIG. 24B, a hard mask layer pattern 17 may be formed over the stack body SB10.

Subsequently, the stack body SB may be etched by using the hard mask layer pattern 17 as an etch barrier. As a result, a plurality of first and second sacrificial vertical openings V1′ and V2′ may be formed in the stack body SB10.

Referring to FIG. 24C, preliminary horizontal layers 14A′ and horizontal recesses 18 may be formed. The preliminary horizontal layers 14A′ and the horizontal recesses 18 may be formed by a process of recessing the silicon germanium layers 12 and the mono crystalline silicon layers 14′ shown in FIG. 24B. After the silicon germanium layers 12 is removed, a process of recessing the mono crystalline silicon layers 14′ may be performed. The preliminary horizontal layers 14A′ may correspond to the preliminary horizontal layers 14A shown in FIG. 7B.

The silicon germanium layers 12 may be recessed by a wet etching process or a dry etching process. The silicon germanium layers 12 may be etched by using an etchant or an etching gas having a selectivity with respect to the mono crystalline silicon layers 14′.

The recess process of the mono crystalline silicon layers 14′ to form the preliminary horizontal layers 14A′ may use, for example, HSC1 (Hot SC-1). HSC1 may include a solution of ammonium hydroxide (NH₄OH), hydrogen peroxide (H₂O₂), and water (H₂O) that are mixed at a ratio of approximately 1:4:20. The mono crystalline silicon layers 14′ may be selectively etched by using HSC1.

After the preliminary horizontal layers 14A′ are formed, the first and second sacrificial vertical openings may be expanded as indicated by reference numerals ‘V1’ and ‘V2’. The preliminary horizontal layers 14A′ may be disposed to be spaced apart from each other by the first and second sacrificial vertical openings V1 and V2 in the second direction D2. The preliminary horizontal layers 14A′ may have a shape in which a plurality of cross shapes are merged in the third direction D3. While the preliminary horizontal layers 14A′ are formed, the surface of the lower structure 11 may be recessed to a predetermined depth (see a reference numeral ‘11A’). As a result, the depths of the first and second sacrificial vertical openings V1 and V2 may be increased.

Subsequently, a series of the processes shown in FIGS. 8A to 22C may be performed.

FIGS. 25 to 27 are perspective views illustrating memory cell arrays in accordance with other embodiments of the present disclosure. The memory cell arrays MCA100, MCA200, and MCA300 may be similar to the memory cell array MCA of FIG. 3A. Hereinafter, as for the detailed description on the constituent elements of FIGS. 25 to 27 also appearing in FIG. 3A, the above-described embodiments of the present disclosure may be referred to.

Referring to FIG. 25, the memory cell array MCA100 may include a plurality of memory cells MC10.

The memory cell array MCA100 may include a three-dimensional array of the memory cells MC10. The three-dimensional array of the memory cells MC10 may include a column array of memory cells MC10 and a row array of memory cells MC10. The column array of memory cells MC10 may include a plurality of memory cells MC10 that are stacked in the first direction D1, and the row array of memory cells MC10 may include a plurality of memory cells MC10 horizontally arranged in the second direction D2 and the third direction D3.

Each memory cell MC10 may include a first conductive line BL, a switching element TR, and a data storage element CAP. As for the detailed description on the first conductive line BL and the data storage element CAP, the above-described embodiments of the present disclosure may be referred to.

The switching element TR may include a horizontal layer HL and a second conductive line DWL. The horizontal layer HL may extend in the second direction D2. The second conductive line DWL may extend in the third direction D3.

The second conductive line DWL may have a double structure. For example, the second conductive line DWL may include an upper horizontal line G1 and a lower horizontal line G1 that are facing each other with the horizontal layer HL interposed therebetween. As illustrated in FIG. 3B, an inter-level dielectric layer GD may be formed on the top and bottom surfaces of the horizontal layer HL.

Each of the upper and lower horizontal lines G1 and G2 may include a pair of flat sidewall surfaces FS extending in the third direction D3. The flat sidewall surface FS may refer to a vertical sidewall surface. The flat sidewall surface FS may have a linear shape extending in the third direction D3.

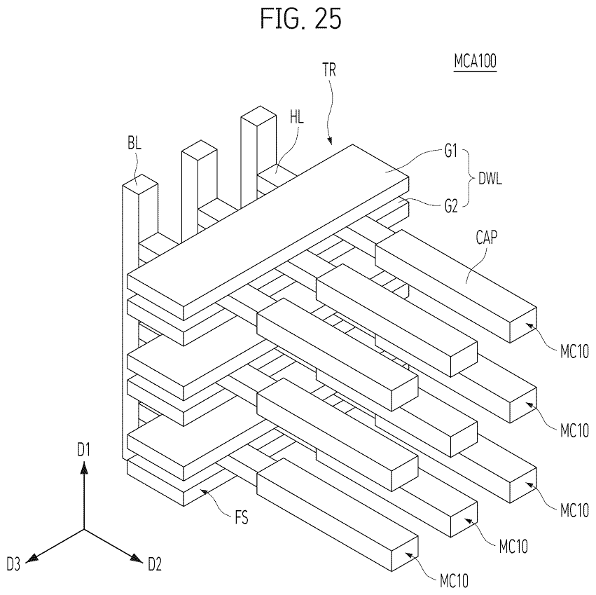

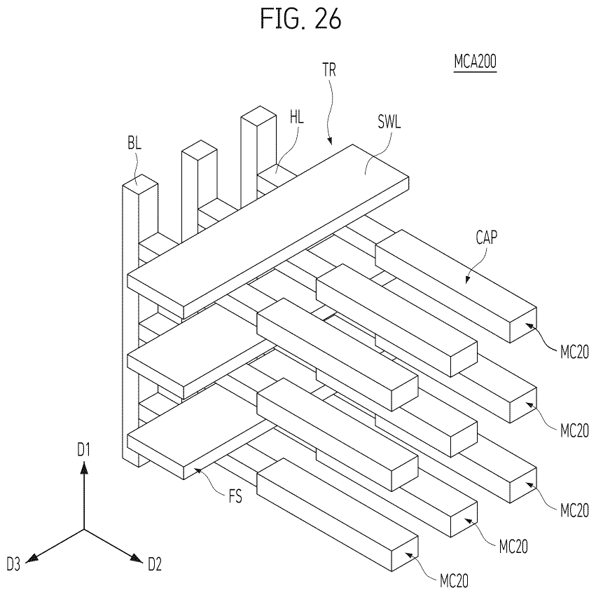

Referring to FIG. 26, a memory cell array MCA200 may include a plurality of memory cells MC20.

The memory cell array MCA200 may include a three-dimensional array of memory cells MC20. The three-dimensional array of memory cells MC20 may include a column array of memory cells MC20 and a row array of memory cells MC20. The column array of memory cells MC20 may include a plurality of memory cells MC20 that are stacked in the first direction D1, and the row array of memory cells MC20 may include a plurality of memory cells MC20 horizontally arranged in the second direction D2 and the third direction D3.

Each memory cell MC20 may include a first conductive line BL, a switching element TR, and a data storage element CAP. As for the detailed description on the first conductive line BL and the data storage element CAP, the above-described embodiments of the present disclosure may be referred to.

The switching element TR may include a horizontal layer HL and a second conductive line SWL. The horizontal layer HL may extend in the second direction D2. The second conductive line SWL may extend in the third direction D3.

The second conductive line SWL may have a single structure. For example, the second conductive line SWL may be disposed over the horizontal layer HL. As illustrated in FIG. 3B, an inter-level dielectric layer GD may be formed between the top surface of the horizontal layer HL and the second conductive line SWL. According to another embodiment of the present disclosure, the second conductive line SWL may be disposed below the horizontal layer HL.

The second conductive line SWL may include a pair of flat sidewall surfaces FS extending in the third direction D3. The flat sidewall FS may refer to a vertical sidewall.

According to another embodiment of the present disclosure, the second conductive line SWL may include a channel overlapping portion WLP and a channel non-overlapping portion NOL, as illustrated in FIG. 1C.

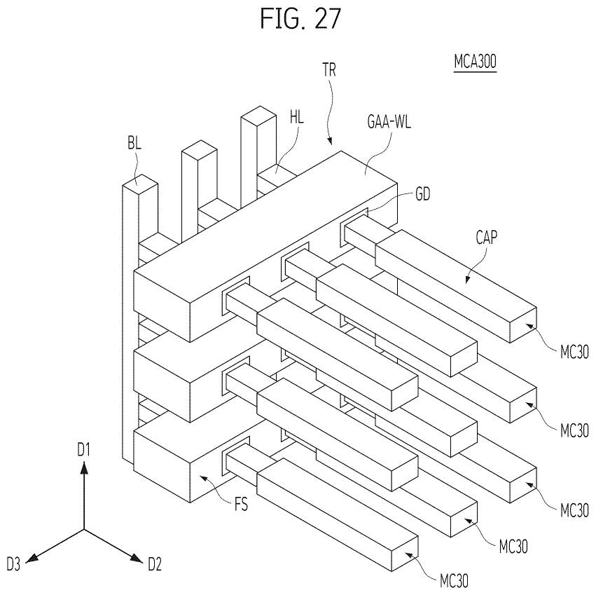

Referring to FIG. 27, a memory cell array MCA300 may include a plurality of memory cells MC30.

The memory cell array MCA300 may include a three-dimensional array of memory cells MC30. The three-dimensional array of memory cells MC30 may include a column array of memory cells MC30 and a row array of memory cells MC30. The column array of memory cells MC30 may include a plurality of memory cells MC30 that are stacked in the first direction D1, and the row array of memory cells MC30 may include a plurality of memory cells MC30 that are arranged horizontally in the second direction D2 and the third direction D3.

Each memory cell MC30 may include a first conductive line BL, a switching element TR, and a data storage element CAP. As for the detailed description on the first conductive line BL and the data storage element CAP, the above-described embodiments of the present disclosure may be referred to.

The switching element TR may include a horizontal layer HL and a second conductive line GAA-WL. The horizontal layer HL may extend in the second direction D2. The second conductive line GAA-WL may extend in the third direction D3.

The second conductive line GAA-WL may have a Gate-All-Around structure GAA. For example, the second conductive line GAA-WL may extend in the third direction D3 while surrounding the horizontal layers HL. An inter-level dielectric layer GD may be formed between the horizontal layer HL and the second conductive line GAA-WL. The inter-level dielectric layer GD may surround the individual horizontal layers HL.

The second conductive line GAA-WL may include a pair of flat sidewall surfaces FS extending in the third direction D3. The flat sidewall FS may refer to a vertical sidewall.

According to another embodiment of the present disclosure, the individual memory cells may include a first conductive line BL extending horizontally in the third direction D3, a second conductive line DWL vertically extending in the first direction D1, and a horizontal layer HL extending horizontally in the second direction D2. The second conductive line DWL may have a double structure or may be replaced with a single structure or a gate-all-around structure.

According to the embodiment of the present disclosure, the sacrificial layers are simultaneously removed from the cell array region and the connection region, thus, the process for removing the sacrificial layers may be minimized.

According to the embodiment of the present disclosure, low power consumption and high integration of 3D memory cells may be achieved.

While the embodiments of the present disclosure have been described with respect to the specific embodiments, it will be apparent to those skilled in the art that various changes and modifications may be made without departing from the spirit and scope of the disclosure as defined in the following claims. Furthermore, the embodiments may be combined to form additional embodiments.

What is claimed is:

1. A method for fabricating a semiconductor device, the method comprising:
forming a stack body including a first region and a second region by sequentially forming a first stack, a recess target layer, and a second stack over a lower structure;
forming sacrificial isolation layers in the first region;
forming a plurality of vertical openings in the first region;
forming a plurality of pad isolation openings in the second region;
removing the first stack and the second stack from the first region and the second region through the vertical openings and the pad isolation openings; and
forming a preliminary horizontal layer in each of the first region and the second region by recessing the recess target layer of the stack body.

2. The method of claim 1, further comprising:
after forming the preliminary horizontal layer,
forming a horizontal layer in the first region by patterning the preliminary horizontal layer;
forming a horizontal conductive line intersecting with the horizontal layer of the first region;
forming a vertical conductive line that is adjacent to the horizontal conductive line and coupled to a first-side edge portion of the horizontal layer;
cutting a second-side edge portion of the horizontal layer; and
forming a data storage element that is adjacent to the horizontal conductive line and coupled to the cut horizontal layer.

3. The method of claim 2, wherein the horizontal conductive line includes double horizontal conductive lines vertically facing each other with the horizontal layer interposed therebetween.

4. The method of claim 2, wherein the data storage element includes a capacitor.

5. The method of claim 1, further comprising:
after forming the preliminary horizontal layer,
forming a contact-level horizontal layer in the second region by patterning the preliminary horizontal layer;
forming first and second horizontal conductive lines vertically facing each other with the contact-level horizontal layer interposed therebetween;
forming a contact-level gap between the first horizontal conductive line and the second horizontal conductive line by removing the contact-level horizontal layer; and
forming a pad portion that fills the contact-level gap.

6. The method of claim 1, further comprising:
after forming the preliminary horizontal layer,
forming a horizontal layer in the first region and forming a contact-level horizontal layer in the second region by patterning the preliminary horizontal layer;
forming first and second horizontal conductive lines that vertically face each other with the horizontal layer interposed therebetween and include edge portions extending to overlap with the contact-level horizontal layer;
forming a contact-level gap between an edge portion of the first horizontal conductive line and an edge portion of the second horizontal conductive line by removing the contact-level horizontal layer; and
forming a pad portion that fills the contact-level gap.

7. The method of claim 6, wherein the edge portions of the first and second horizontal conductive lines include a staircase structure.

8. The method of claim 1, further comprising:
after forming the preliminary horizontal layer,
forming a first dielectric layer that covers each of top and bottom portions of the preliminary semiconductor layer;
forming a horizontal layer by patterning the preliminary semiconductor layer;
cutting both side surfaces of the first dielectric layer to produce cut first dielectric layers; and
replacing the cut first dielectric layers with horizontal conductive lines.

9. The method of claim 1, wherein the horizontal layer includes mono crystalline silicon.

10. The method of claim 1, wherein a cross-section of the horizontal layer has a cross shape.

11. The method of claim 1, wherein each of the first and second stacks is formed by sequentially stacking a first silicon germanium layer, a mono crystalline silicon layer, and a second silicon germanium layer.

12. The method of claim 1, wherein each of the first and second stacks is formed by sequentially stacking a first silicon germanium layer, a first mono crystalline silicon layer, and a second silicon germanium layer in a mentioned order, and
the recess target layer includes a second mono crystalline silicon layer, and
the second mono crystalline silicon layer is formed thicker than the first mono crystalline silicon layer.

13. A semiconductor device comprising:
a lower structure;
a vertical stack including horizontal conductive lines that are stacked vertically from the lower structure;
a staircase stack extending horizontally from the vertical stack and including edge portions of the horizontal conductive lines;
line-shaped pad isolation slits formed on both sidewall surfaces of the staircase stack; and
a hole-shaped pad isolation slit penetrating the staircase stack and extending vertically in a direction that the horizontal conductive lines are stacked.

14. The semiconductor device of claim 13, wherein the line-shaped pad isolation slits and the hole-shaped pad isolation slit include a dielectric material.

15. The semiconductor device of claim 13, wherein the vertical stack includes:
horizontal layers oriented horizontally in a direction intersecting with the horizontal conductive lines;
a vertical conductive line that is commonly coupled to first-side edge portions of the horizontal layers and extending vertically in a direction that the horizontal conductive lines are stacked; and
data storage elements respectively coupled to second-side edge portions of the horizontal layers.

16. The semiconductor device of claim 15, wherein the horizontal layers include mono crystalline silicon, polysilicon, an oxide semiconductor material, or a combination thereof.

17. The semiconductor device of claim 15, further comprising:
a first contact node between the horizontal layers and the vertical conductive line;
a first doped region that is coupled to the first contact node and disposed in the first-side edge portions of the horizontal layers;
a second contact node between the horizontal layers and the data storage elements;
a second doped region that is coupled to the second contact node and disposed in the second-side edge portions of the horizontal layers; and
a channel disposed between the first doped region and the second doped region in the horizontal layers.

18. The semiconductor device of claim 13, wherein each of the horizontal conductive lines includes a double structure in which an upper horizontal line and a lower horizontal line are disposed vertically.

19. The semiconductor device of claim 18, wherein each of the edge portions of the horizontal conductive lines of the staircase stack, and
a double structure in which the upper horizontal line and the lower horizontal line are disposed vertically; and
a pad portion disposed between the upper horizontal line and the lower horizontal line.
